(19) United States
(12) Patent Application Publication
(10) Pub. No.: US 2025/0212675 A1
(43) Pub. Date: Jun. 26, 2025

(54) METHOD FOR MANUFACTURING LIGHT-EMITTING DEVICE

(71) Applicant: SEMICONDUCTOR ENERGY LABORATORY CO., LTD., Atsugi-shi, Kanagawa-ken (JP)

(72) Inventors: Toshiki SASAKI, Kawasaki, Kanagawa (JP); Nobuharu OHSAWA, Zama, Kanagawa (JP); Shinya FUKUZAKI, Atsugi, Kanagawa (JP)

(21) Appl. No.: 18/851,992

(22) PCT Filed: Mar. 20, 2023
(86) PCT No.: PCT/IB2023/052698

§ 371 Date: Sep. 27, 2024

(30) Foreign Application Priority Data
Mar. 31, 2022 (JP) 2022-059150

(51) Int. Cl. H10K 71/40; H10K 50/19; H10K 59/12; H10K 71/20

(52) U.S. Cl. CPC H10K 71/40; H10K 50/19; H10K 71/233; H10K 59/1201

(57) ABSTRACT

Provided is a high-definition and high-efficiency display device. Provided is a method for manufacturing a light-emitting device including the steps of: forming a first electrode; forming an organic compound layer including an intermediate layer including an alkali metal or an alkali metal compound layer between a first light-emitting layer and a second light-emitting layer over the first electrode; processing the organic compound layer by a lithography method and performing heat treatment; and forming a second electrode to cover the first electrode and the organic compound layer.

### TECHNICAL FIELD

One embodiment of the present invention relates to a method for manufacturing a light-emitting device.

Note that one embodiment of the present invention is not limited to the above technical field. Examples of the technical field of one embodiment of the present invention include a light-emitting device, a semiconductor device, a display device, a display module, a light-emitting apparatus, a power storage device, a memory device, an electronic device, a lighting device, an input device (e.g., a touch sensor), an input/output device (e.g., a touch panel), a method for driving any of then, and a method for manufacturing any of them.

### BACKGROUND ART

Recent display devices have been expected to be applied to a variety of uses. Usage examples of large-sized display devices include a television device for home use (also referred to as TV or television receiver), digital signage, and a PID (Public Information Display). In addition, a smartphone and a tablet terminal each including a touch panel, and the like, are being developed as portable information terminals.

Furthermore, higher-resolution display devices have been required. As devices requiring high-resolution display devices, for example, devices for virtual reality (VR), augmented reality (AR), substitutional reality (SR), or mixed reality (MR) have been actively developed.

Light-emitting apparatuses including light-emitting devices (also referred to as light-emitting elements) have been developed as display devices, for example. Light-emitting devices utilizing an electroluminescence (hereinafter referred to as EL) phenomenon (also referred to as EL devices or EL elements) have features such as ease of reduction in thickness and weight, high-speed response to input signals, and driving with a constant DC voltage power source, and have been used in display devices.

Patent Document 1 discloses a display device using an organic EL device (also referred to as organic EL element) for VR Patent Document 2 discloses a light-emitting device with a low driving voltage and favorable reliability in which a mixed film of a transition metal and an organic compound including an unshared electron pair is used as an electron-injection layer.

### REFERENCES

### Patent Documents

[Patent Document 1] PCT International Publication No. 2018/087625
[Patent Document 2] Japanese Published Patent Application No. 2018-201012

### SUMMARY OF THE INVENTION

### Problems to be Solved by the Invention

One object of one embodiment of the present invention is to provide a method for manufacturing a light-emitting device that can be used in a display device with high display quality. Another object of one embodiment of the present invention is to provide a method for manufacturing a light-emitting device that can be used in a high-definition display device. Another object of one embodiment of the present invention is to provide a method for manufacturing a light-emitting device that can be used in a high-resolution display device. Another object of one embodiment of the present invention is to provide a method for manufacturing a light-emitting device that can be used in a highly reliable display device. Another object of one embodiment of the present invention is to provide a method for manufacturing a light-emitting device that can be used in a novel display device that is highly convenient, useful, or reliable. Another object of one embodiment of the present invention is to provide a method for manufacturing a novel display module that is highly convenient, useful, or reliable. Another object is to provide a method for manufacturing a novel electronic device that is highly convenient, useful, or reliable. Another object is to provide a method for manufacturing a novel light-emitting device, a novel display device, a novel display module, a novel electronic device, or a novel semiconductor device.

Note that the description of these objects does not preclude the existence of other objects. One embodiment of the present invention does not necessarily need to achieve all of these objects. Other objects can be derived from the description of the specification, the drawings, and the claims.

### Means for Solving the Problems

One embodiment of the present invention is a method for manufacturing a light-emitting device, including the following steps: forming a first electrode; over the first electrode, forming an organic compound layer including an intermediate layer including an alkali metal or an alkali metal compound between a first light-emitting layer and a second light-emitting layer; processing the organic compound layer by a lithography method and performing heat treatment; and forming a second electrode to cover the first electrode and the organic compound layer.

Another embodiment of the present invention is a method for manufacturing a light-emitting device, including the following steps: forming a first electrode; forming, over the first electrode, an organic compound layer including an intermediate layer including an alkali metal or an alkali metal compound between a first light-emitting layer and a second light-emitting layer; forming a sacrificial layer over the organic compound layer; forming a mask over the sacrificial layer using a resist; processing the organic compound layer by a lithography method; removing at least part of the sacrificial layer and performing heat treatment; and forming a second electrode to cover the first electrode and the organic compound layer.

Another embodiment of the present invention is a method for manufacturing a light-emitting device, including the following steps: forming a first electrode; forming, over the first electrode, an organic compound layer including an intermediate layer including an alkali metal or an alkali metal compound between a first light-emitting layer and a second light-emitting layer; forming a sacrificial layer over the organic compound layer; forming a mask over the sacrificial layer using a resist; processing the organic compound layer by a lithography method; forming an insulating layer covering side surfaces of the organic compound layer; removing at least part of the sacrificial layer and performing heat treatment; and forming a second electrode to cover the first electrode and the organic compound layer.

Another embodiment of the present invention is a method for manufacturing a light-emitting device with each of the above structures, in which the heat treatment is performed at a temperature higher than or equal to 100° C.

Another embodiment of the present invention is a method for manufacturing a light-emitting device with each of the above structures, in which the heat treatment is performed at a temperature higher than or equal to 100° C. and lower than or equal to 120° C.

Another embodiment of the present invention is the method for manufacturing a light-emitting device with any of the above structures, in which the heat treatment is performed at a temperature higher than or equal to 100° C. and lower than the glass transition temperature of the organic compound included in the top surface of the organic compound layer.

### Effect of the Invention

One embodiment of the present invention can provide a method for manufacturing a light-emitting device that can be used for a display device with high display quality. Another embodiment of the present invention can provide a method for manufacturing a light-emitting device that can be used in a high-definition display device. Another embodiment of the present invention can provide a method for manufacturing a light-emitting device that can be used in a high-resolution display device. Another embodiment of the present invention can provide a method for manufacturing a light-emitting device that can be used in a highly reliable display device. Another embodiment of the present invention can provide a method for manufacturing a novel light-emitting device that is highly convenient, useful, or reliable. Another embodiment of the present invention can provide a method for manufacturing a novel display module that is highly convenient, useful, or reliable. Alternatively, a method for manufacturing a novel electronic device that is highly convenient, useful, or reliable can be provided. Alternatively, a method for manufacturing a light-emitting device that can be used for a novel display device, a novel display module, a novel electronic device, or a novel semiconductor device can be provided.

Note that the description of these effects does not preclude the existence of other effects. One embodiment of the present invention does not necessarily need to have all of these effects. Other effects can be derived from the description of the specification, the drawings, and the claims.

### BRIEF DESCRIPTION OF THE DRAWINGS

FIG. 1A and FIG. 1B are diagrams illustrating a light-emitting device.

FIG. 2A to FIG. 2D are cross-sectional views illustrating an example of a method for manufacturing a light-emitting device.

FIG. 3A to FIG. 3D are cross-sectional views illustrating an example of a method for manufacturing a light-emitting device.

FIG. 4A to FIG. 4D are cross-sectional views illustrating an example of a method for manufacturing a light-emitting device.

FIG. 5A to FIG. 5C are cross-sectional views illustrating an example of a method for manufacturing a light-emitting device.

FIG. 6A and FIG. 6B are a top view and a cross-sectional view of a light-emitting apparatus.

FIG. 7A to FIG. 7D are diagrams each illustrating a light-emitting device.

FIG. 8A to FIG. 8E are cross-sectional views illustrating an example of a method for manufacturing a display device.

FIG. 9A to FIG. 9D are cross-sectional views illustrating an example of a method for manufacturing a display device.

FIG. 10A to FIG. 10D are cross-sectional views illustrating an example of a method for manufacturing a display device.

FIG. 11A to FIG. 11C are cross-sectional views illustrating an example of a method for manufacturing a display device.

FIG. 12A to FIG. 12C are cross-sectional views illustrating an example of a method for manufacturing a display device.

FIG. 13A to FIG. 13C are cross-sectional views illustrating an example of a method for manufacturing a display device.

FIG. 14A and FIG. 14B are perspective views each illustrating a structure example of a display module.

FIG. 15A and FIG. 15B are cross-sectional views each illustrating a structure example of a display device.

FIG. 16A to FIG. 16D are diagrams each illustrating an example of an electronic device.

FIG. 17A to FIG. 17F are diagrams each illustrating an example of an electronic device.

FIG. 18 is a graph showing the luminance-current density characteristics of a light-emitting device 1 and a comparative light-emitting device 2.

FIG. 19 is a graph showing the luminance-voltage characteristics of the light-emitting device 1 and the comparative light-emitting device 2.

FIG. 20 is a graph showing the current efficiency-luminance characteristics of the light-emitting device 1 and the comparative light-emitting device 2.

FIG. 21 is a graph showing the current density-voltage characteristics of the light-emitting device 1 and the comparative light-emitting device 2.

FIG. 22 is a diagram showing current efficiency-current density characteristics of the light-emitting device 1 and the comparative light-emitting device 2.

FIG. 23 is a graph showing emission spectra of the light-emitting device 1 and the comparative light-emitting device 2.

FIG. 24 is a graph showing the luminance-current density characteristics of the reference light-emitting device 3 and a comparative light-emitting device 4.

FIG. 25 is a graph showing the luminance-voltage characteristics of the reference light-emitting device 3 and the comparative light-emitting device 4.

FIG. 26 is a graph showing the current efficiency-luminance characteristics of the light-emitting device 3 and the comparative light-emitting device 4.

FIG. 27 is a graph showing the current density-voltage characteristics of the reference light-emitting device 3 and the comparative light-emitting device 4.

FIG. 28 is a graph showing emission spectra of the reference light-emitting device 3 and the comparative light-emitting device 4.

FIG. 29 is a graph showing the TDS analysis results of Sample 1.

FIG. 30 is a graph showing the TDS analysis results of Comparative Sample 2.

FIG. 31 is a graph showing the TDS analysis results of Comparative Sample 3.

### MODE FOR CARRYING OUT THE INVENTION

Embodiments are described in detail with reference to the drawings. Note that the present invention is not limited to the following description, and it is readily understood by those skilled in the art that modes and details of the present invention can be changed in various ways without departing from the spirit and scope thereof. Thus, the present invention should not be interpreted as being limited to the description of the embodiments given below.

Note that in the structures of the invention described below, the same reference numerals are used in common for the same portions or portions having similar functions in different drawings, and repeated description thereof is omitted. The same hatch pattern is used for portions having similar functions, and the portions are not especially denoted by reference numerals in some cases.

The position, size, range, and the like of each component illustrated in drawings do not represent the actual position, size, range, and the like in some cases for easy understanding. Therefore, the disclosed invention is not necessarily limited to the position, size, range, and the like disclosed in the drawings.

Note that the term “film” and the term “layer” can be interchanged with each other depending on the case or circumstances. For example, the term “conductive layer” can be replaced with the term “conductive film”. As another example, the term “insulating film” can be replaced with the term “insulating layer”.

In this specification and the like, a device manufactured using a metal mask or an FMM (a fine metal mask, a high-resolution metal mask) may be referred to as a device having an MM (a metal mask) structure. In this specification and the like, a device formed without using a metal mask or an FMM may be referred to as a device having an MML (metal maskless) structure.

In this specification and the like, a hole or an electron is sometimes referred to as a “carrier”. Specifically, a hole-injection layer or an electron-injection layer may be referred to as a “carrier-injection layer”, a hole-transport layer or an electron-transport layer may be referred to as a “carrier-transport layer”, and a hole-blocking layer or an electron-blocking layer may be referred to as a “carrier-blocking layer”. Note that the above-described carrier-injection layer, carrier-transport layer, and carrier-blocking layer cannot be clearly distinguished from each other on the basis of the cross-sectional shape, properties, or the like in some cases. One layer may have two or three functions of the carrier-injection layer, the carrier-transport layer, and the carrier-blocking layer in some cases.

In this specification and the like, a light-emitting device (also referred to as a light-emitting element) includes an EL layer between a pair of electrodes. The EL layer includes at least a light-emitting layer. In this specification and the like, a light-receiving device (also referred to as a light-receiving element) includes at least an active layer functioning as a photoelectric conversion layer between a pair of electrodes. In this specification and the like, one of the pair of electrodes may be referred to as a pixel electrode and the other may be referred to as a common electrode.

In this specification and the like, a tapered shape indicates a shape in which at least part of a side surface of a component is inclined to a substrate surface. For example, a tapered shape preferably includes a region where the angle between the inclined side surface and the substrate surface (such an angle is also referred to as a taper angle) is less than 90°. Note that the side surface of the component and the substrate surface are not necessarily completely flat and may be substantially flat with a slight curvature or substantially flat with slight unevenness.

### Embodiment 1

As a method for forming an organic semiconductor film in a predetermined shape, a vacuum evaporation method with a metal mask (mask vapor deposition) is widely used. However, in these days of higher density and higher resolution, mask vapor deposition has come close to the limit of increasing the resolution for various reasons such as the alignment accuracy and the distance between the mask and the substrate. Meanwhile, shape processing of an organic semiconductor film by a lithography method enables the formation of a finer pattern. The processing of an organic semiconductor film by a lithography method can also achieve an increase in area easily and thus has been actively researched.

An organic EL element includes an organic compound layer containing a light-emitting substance (corresponding to the above organic semiconductor film) between electrodes (between a first electrode and a second electrode), and energy generated by recombination of carriers (holes and electrons) injected to the organic compound layer from the electrodes causes light emission.

Here, a high voltage was required for directly injecting carriers, especially electrons, from the electrodes into the organic compound layer where in general electricity is unlikely to flow because of a high energy barrier. Therefore, the voltage is reduced by using an alkali metal such as lithium (Li) or a compound of the alkali metal in an electron-injection layer in contact with the cathode under the existing circumstances.

However, in the case where the above-described lithography method is employed to manufacture a light-emitting device including an organic semiconductor layer including the alkali metal or the compound of the alkali metal described above, oxygen or water in the air and a chemical solution or water used during the processing have caused a significant increase in driving voltage or a significant reduction in current efficiency.

As a means for solving the above-described problem, there is a method of performing a lithography process halfway through a process of forming an organic compound layer of a light-emitting device (before forming a layer including an alkali metal or a compound of the alkali metal). In other words, lithography for processing the organic compound layer is performed prior to the formation of the electron-injection layer, and then the step for the electron-injection layer and the later steps are performed, whereby degradation of characteristics can be avoided in this method.

However, for a tandem light-emitting element, the above solving way cannot be employed and performing a lithography process has inevitably caused a significant degradation of characteristics.

This is because the tandem light-emitting device includes an organic semiconductor layer with a structure where a plurality of light-emitting layers are stacked in series with an intermediate layer therebetween, and the intermediate layer includes a layer including an alkali metal or a compound of the alkali metal so that electrons can be injected into a light-emitting layer of the anode side of the intermediate layer. Since the intermediate layer is provided between the light-emitting layers, the intermediate layer is inevitably exposed to a lithography process when the light-emitting layer is processed by a lithography method.

Accordingly, like exposure of the electron-injection layer to a lithography process, the exposure of the layer including an alkali metal or a compound of the alkali metal in the intermediate layer to the lithography process has caused a significant increase in driving voltage and a significant decrease in current efficiency of the light-emitting device.

The present inventors have found that the layer including an alkali metal or an alkali metal compound has a property of easily adsorbing water in the air, which causes a significant increase in driving voltage and a significant decrease in current efficiency of the light-emitting device due to exposure of the layer to a lithography step, and that a step of adequately removing water from the layer enables a tandem light-emitting device with favorable characteristics to be manufactured even when the layer is exposed to a lithography step.

In view of this, in the method for manufacturing a light-emitting device of one embodiment of the present invention, heat treatment is performed after a step of processing an organic compound layer including an alkali metal or an alkali metal compound by a lithography method.

When the light-emitting device is manufactured by such a method, water can be sufficiently removed from the organic compound layer including an alkali metal or an alkali metal compound. Accordingly, a significant increase in driving voltage of the light-emitting device can be inhibited and a decrease in current efficiency can be prevented. Consequently, a light-emitting device having favorable characteristics can be obtained. In addition, a display device that can perform high-definition display sufficient for VR and AR use, and the like and has favorable characteristics can be provided.

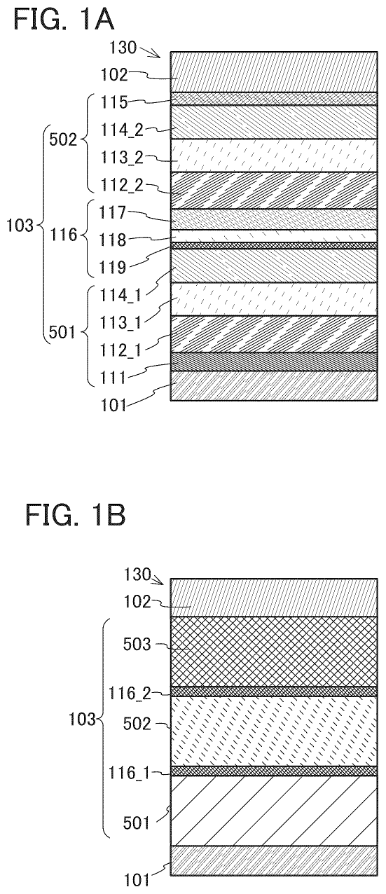

FIG. 1A illustrates a light-emitting device 130 that is an example of a light-emitting device that can be manufactured by the method for manufacturing a light-emitting device of one embodiment of the present invention. The light-emitting device 130 is a tandem light-emitting device including an organic compound layer 103 that includes a plurality of light-emitting units between a first electrode 101 that includes an anode and the second electrode 102 that includes a cathode. The light-emitting device 130 includes a first light-emitting unit 501 including a first light-emitting layer 113_1, a second light-emitting unit 502 including a second light-emitting layer 113_2, and an intermediate layer 116, as the organic compound layer 103.

Note that in this embodiment, the method for manufacturing the light-emitting device of one embodiment of the present invention is described using the light-emitting device including one intermediate layer 116 and two light-emitting units as an example of the organic compound layer 103; meanwhile, with the method for manufacturing the light-emitting device of one embodiment of the present invention, the light-emitting device including n (n is an integer greater than or equal to 1) intermediate layers (also referred to as charge-generation layers) and n+1 light-emitting units can also be manufactured as the organic compound layer 103. For example, the light-emitting device 130 illustrated in FIG. 1B is an example of a tandem light-emitting device with n=2 that includes, as the organic compound layer 103, the first light-emitting unit 501, a first intermediate layer 116_1, the second light-emitting unit 502, a second intermediate layer 116_2, and a third light-emitting unit 503. The color gamut of light emitted by a light-emitting layer in one light-emitting unit may be the same as or different from that of light emitted by a light-emitting layer in another light-emitting unit. In addition, the light-emitting layer may have a single-layer structure or a stacked-layer structure. For example, white light emission can be achieved with a structure in which the first light-emitting unit and the third light-emitting unit emit light in a blue region and light-emitting layers in a stacked-layer structure of the second light-emitting unit emit light in a red region and light in a green region.

The light-emitting device 130 is a light-emitting device manufactured by the method for manufacturing the light-emitting device of one embodiment of the present invention using a lithography method, and at least the second light-emitting layer 113_2 and the layers that are closer to the first electrode 101 than the second light-emitting layer 113_2 in the organic compound layer 103 are processed at the same time; thus, end portions of the layers are substantially aligned in the perpendicular direction.

In the light-emitting device 130, the intermediate layer 116 is a layer including at least an alkali metal or an alkali metal compound. Specifically, the intermediate layer 116 is a layer including an N-type layer 119 and a P-type layer 117, and the N-type layer 119 preferably includes an alkali metal or an alkali metal compound. Specific examples of the alkali metals include lithium, sodium, potassium, rubidium, cesium, and francium. Specific examples of the alkali metal compounds include compounds of the above alkali metals, such as lithium compounds (lithium oxide etc.). The N-type layer 119 may include an organic compound having an electron-transport property in addition to an alkali metal or an alkali metal compound.

The P-type layer 117 is positioned closer to the second electrode 102 than the N-type layer 119. Between the N-type layer 119 and the P-type layer 117, an electron-relay layer 118 for smooth donation and acceptance of electrons between the two layers may be provided.

The first light-emitting unit 501 and the second light-emitting unit 502 may include a functional layer in addition to the light-emitting layer. Although FIG. 1A illustrates the structure in which the first light-emitting unit 501 includes a hole-injection layer 111, a first hole-transport layer 112_1, and a first electron-transport layer 114_1 in addition to the first light-emitting layer 113_1 and the second light-emitting unit 502 includes a second hole-transport layer 112_2, a second electron-transport layer 114_2, and an electron-injection layer 115 in addition to the second light-emitting layer 113_2, the structure of the organic compound layer 103 in the present invention is not limited thereto and any of the layers may be omitted or other layers may be added. Typical examples of the other layers include a carrier-blocking layer and an exciton-blocking layer.

Since the N-type layer 119 is included in the intermediate layer 116, the N-type layer 119 serves as an electron-injection layer in the light-emitting unit on the anode side. Thus, an electron-injection layer is not necessarily included in the light-emitting unit on the anode side (the first light-emitting unit 501 in FIG. 1A). Similarly, since the P-type layer 117 is included in the intermediate layer 116, the P-type layer 117 serves as a hole-injection layer in the light-emitting unit on the cathode side. Thus, a hole-injection layer is not necessarily included in the light-emitting unit on the cathode side (the second light-emitting unit 502 in FIG. 1A).

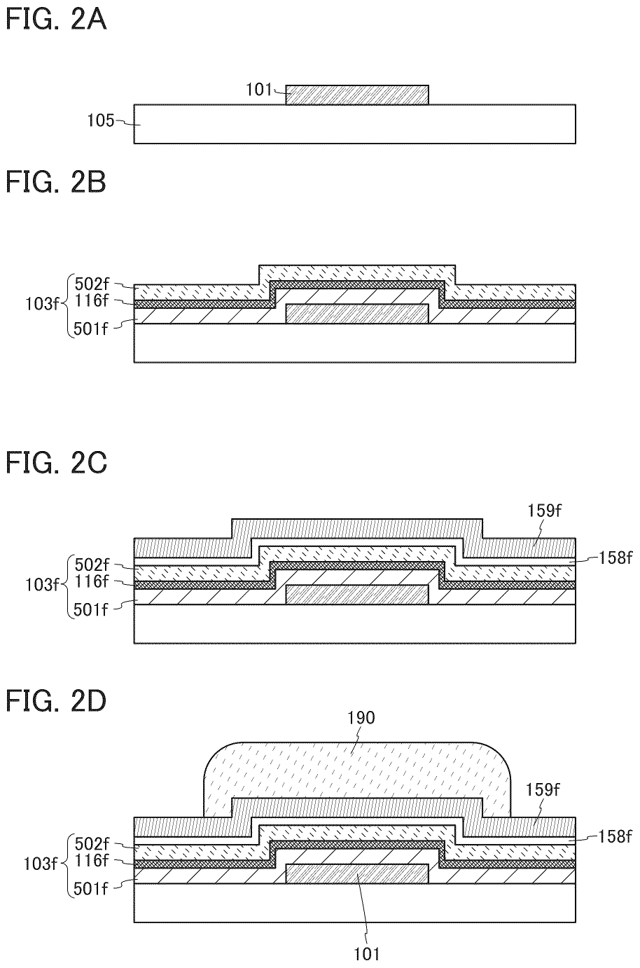

Next, the method for manufacturing a light-emitting device of one embodiment of the present invention will be described with reference to FIG. 2 to FIG. 5.

First, as illustrated in FIG. 2A, the first electrode 101 is formed over the substrate 105.

The first electrode 101 can be formed by a photolithography method, for example. Specifically, a resist mask is formed over the conductive film formed over the substrate 105, and then part of the conductive film is removed by an etching method. Part of the conductive film can be removed by a wet etching method, for example. Part of the conductive film may be removed by a dry etching method.

Next, as illustrated in FIG. 2B, an organic compound film 103f to be the organic compound layer 103 later is formed over the substrate 105 and the first electrode 101. Note that for simplification of the figures, FIG. 2 to FIG. 5 illustrate only the organic compound film 501f, the intermediate film 116f, and the organic compound film 502f among the films included in the organic compound film 103f. Note that the organic compound film 501f is a film to be the first light-emitting unit 501 later, the intermediate film 116f is a film to be the intermediate layer 116 later, and the organic compound film 502f is a film to be the second light-emitting unit 502 later.

The intermediate film 116f included in the organic compound film 103f includes at least an alkali metal or an alkali metal compound. Specifically, it is preferable that the intermediate film 116f be a film including an N-type film and a P-type film, and the N-type film include an alkali metal or an alkali metal compound. Specific examples of the alkali metal include lithium, sodium, potassium, rubidium, cesium, and francium. Specific examples of the alkali metal compound include compounds of the above alkali metals, such as lithium compounds (lithium oxide etc.). The N-type film may include an organic compound having an electron-transport property in addition an alkali metal or an alkali metal compound.

The organic compound film 103f can be formed by an evaporation method, specifically a vacuum evaporation method, for example. The organic compound film 103f may be formed by a transfer method, a printing method, an inkjet method, a coating method, or the like.

Then, as illustrated in FIG. 2C, a sacrificial film 158f to be a sacrificial layer 158 later and a mask film 159f to be a mask layer 159 later are sequentially formed over the organic compound film 103f. Specific examples of the formation method of the sacrificial film 158f and the mask film 159f can be referred to for the formation method of a sacrificial film 158Rf and a mask film 159Rf described in detail in a later embodiment.

Next, as illustrated in FIG. 2D, a resist mask 190 is formed over the mask film 159f in a position overlapping with the first electrode 101. The resist mask 190 can be formed by application of a photosensitive material (photoresist), light exposure, and development. Note that the resist mask 190 may be formed using either a positive resist material or a negative resist material.

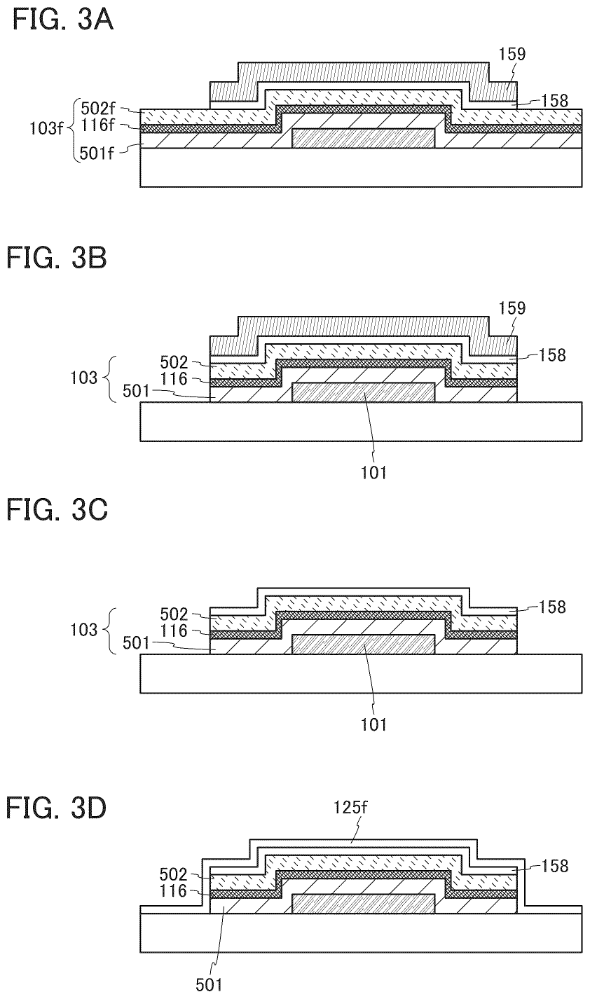

Next, part of the mask film 159f is removed with the use of the resist mask 190, so that the mask layer 159 is formed. After that, the resist mask 190 is removed. Then, part of the sacrificial film 158f is removed using the mask layer 159 as a mask (also referred to as a hard mask), whereby the sacrificial layer 158 is formed (see FIG. 3A).

For specific processing method of the sacrificial film 158f and the mask film 159f, the processing method of the sacrificial film 158Rf and the mask film 159Rf described in detail in a later embodiment can be referred to. For a specific method for removing the resist mask 190R, the method for removing the resist mask 190R described in detail in a later embodiment can be referred to.

Next, as illustrated in FIG. 3B, the organic compound film 103f (the organic compound film 501f, the intermediate film 116f, and the organic compound film 502f) is processed to form the organic compound layer 103 (the first light-emitting unit 501, the intermediate layer 116, and the second light-emitting unit 502). For example, part of the organic compound film 103f is removed using the mask layer 159 and the sacrificial layer 158 as a hard mask to form the organic compound layer 103. For a specific processing method of the organic compound film 103f, the method for processing the organic compound film 103Rf described in detail in a later embodiment can be referred to.

As described above, in one embodiment of the present invention, the mask layer 159 is formed in the following manner: the resist mask 190 is formed over the mask film 159f, and part of the mask film 159f is removed using the resist mask 190. After that, part of the organic compound film 103f is removed using the mask layer 159 as a hard mask, so that the organic compound layer 103 is formed. In other words, the organic compound layer 103 can be formed by processing the organic compound film 103f by a photolithography method. The organic compound film 103f includes the intermediate film 116f, and the intermediate film 116f includes at least an alkali metal or an alkali metal compound. Thus, it can be said that the organic compound layer 103 including an alkali metal or an alkali metal compound is formed by processing the organic compound film 103f including an alkali metal or an alkali metal compound by a lithography method. Note that part of the organic compound film 103f may be removed using the resist mask 190. Then, the resist mask 190 may be removed.

Next, as illustrated in FIG. 3C, the mask layer 159 is preferably removed. The step of removing the mask layers 159 can be performed by a method similar to that for the step of processing the mask film 159f. A method for removing the mask layer 159 will be described in detail in a later embodiment.

After the mask layer is removed, heat treatment may be performed. For example, heat treatment in an inert gas atmosphere or a reduced-pressure atmosphere can be performed. The heat treatment can be performed at a substrate temperature higher than or equal to 50° C. and lower than or equal to 200° C., preferably higher than or equal to 60° C. and lower than or equal to 150° C., further preferably higher than or equal to 70° C. and lower than or equal to 120° C. A reduced-pressure atmosphere is preferable because drying at a lower temperature is possible.

By the heat treatment, water included in the organic compound layer 103 and water adsorbed onto the surface of the organic compound layer 103, in particular, water included in the intermediate layer 116 that is a layer including an alkali metal or an alkali metal compound, can be removed. This can prevent a significant increase in driving voltage and a significant decrease in current efficiency of the light-emitting device even when the intermediate layer 116, which is a layer including an alkali metal or an alkali metal compound, is exposed to a lithography process.

Next, as illustrated in FIG. 3D, an inorganic insulating film 125f to be an inorganic insulating layer 125 later is formed to cover the organic compound layer 103 and the sacrificial layer 158. A specific method for forming the inorganic insulating film 125f will be described in detail in a later embodiment.

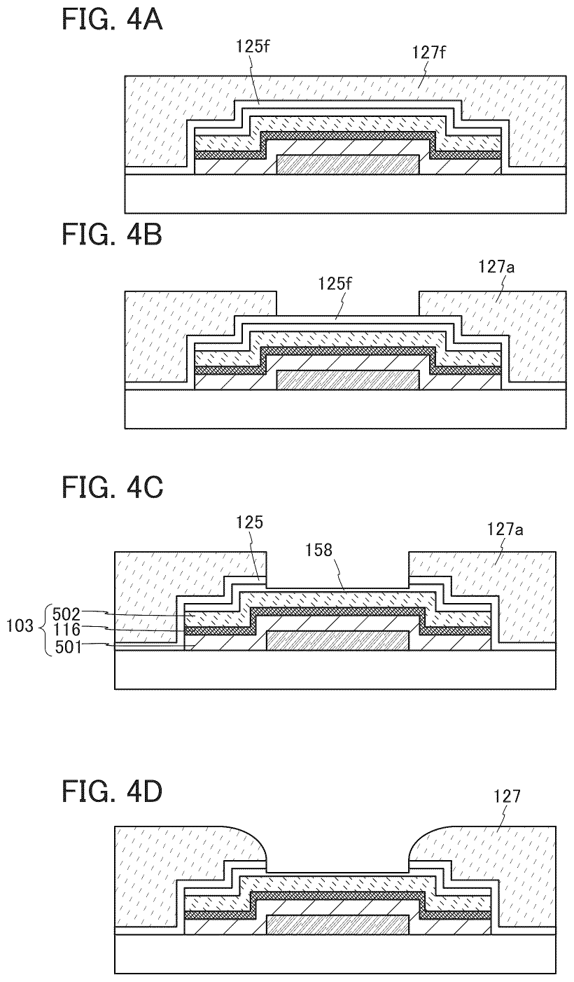

Then, as illustrated in FIG. 4A, an insulating film 127f to be an insulating layer 127 later is formed over the inorganic insulating film 125f. The insulating film 127f is preferably formed by spin coating using a photosensitive material, for example, and preferably formed using specifically a photosensitive resin composition containing an acrylic resin. A specific method for forming the insulating film 127f will be described in detail in a later embodiment.

Then, part of the insulating film 127f is exposed to visible light or ultraviolet rays. Here, when a positive photosensitive resin composition containing an acrylic resin is used for the insulating film 127f, a region that is over the first electrode 101 and in which the insulating layer 127 is not formed in a later step is irradiated with visible light or ultraviolet rays. Note that when a negative photosensitive material is used for the insulating film 127f, the region where the insulating layer 127 is to be formed is irradiated with visible light or ultraviolet rays. A specific method for exposure of the insulating film 127f will be described in detail in a later embodiment.

Next, as illustrated in FIG. 4B, development is performed to remove the exposed region of the insulating film 127f, so that an insulating layer 127a is formed. The insulating layer 127a is formed in a region not overlapping with the first electrode 101. A specific method for forming the insulating layer 127a will be described in detail in a later embodiment.

Next, as illustrated in FIG. 4C, etching treatment is performed using the insulating layer 127a as a mask to remove part of the inorganic insulating film 125f, so that the sacrificial layer 158 is partly thinned. Thus, the inorganic insulating layer 125 is formed under the insulating layer 127a. In addition, the surface of the thinned portion of the sacrificial layer 158 is exposed. The sacrificial layer 158 is made to remain over the organic compound layer 103 in this manner, whereby the organic compound layer 103 can be prevented from being damaged by treatment in a later step. Thus, a highly reliable light-emitting device can be manufactured.

A specific method for the etching treatment using the insulating layer 127a as a mask is described in detail in a later embodiment. The effect of remaining the sacrificial layer 158 will be described in detail in a later embodiment.

Subsequently, heat treatment is performed. The heat treatment can change the shape of the insulating layer 127a to have a tapered side surface and form the insulating layer 127 (FIG. 4D). The heat treatment is performed at a temperature lower than the upper temperature limit of the organic compound layer. The heat treatment can be performed at a substrate temperature higher than or equal to 50° C. and lower than or equal to 200° C., preferably higher than or equal to 60° C. and lower than or equal to 150° C., further preferably higher than or equal to 70° C. and lower than or equal to 130° C. The heating atmosphere may be either an air atmosphere or an inert gas atmosphere. Alternatively, the heating atmosphere may be either an atmospheric pressure atmosphere or a reduced-pressure atmosphere. The details of the heat treatment after the etching treatment using the insulating layer 127a as a mask are described in detail in the following embodiments.

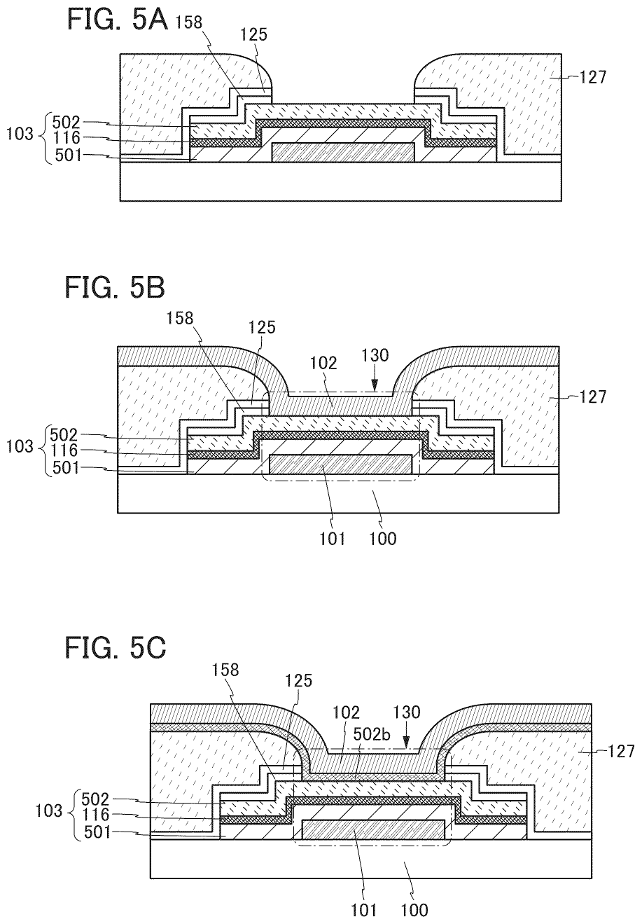

Next, as illustrated in FIG. 5A, etching treatment is performed using the insulating layer 127 as a mask to remove part of the sacrificial layer 158 (also referred to as the thin portion of the sacrificial layer 158). Note that part of the inorganic insulating layer 125 is also removed in some cases. Accordingly, an opening is formed in the sacrificial layer 158, and part of the top surface of the organic compound layer 103 is exposed.

The sacrificial layer 158 is partly removed by etching treatment using the insulating layer 127 as a mask by wet etching. The use of a wet etching method can reduce more damage to the organic compound layer 103 than the use of a dry etching method. A specific method for removing part of the sacrificial layer 158 by the etching treatment using the insulating layer 127 as a mask will be described in detail in a later embodiment.

After part of the top surface of the organic compound layer 103 is exposed, heat treatment is further performed. By the heat treatment, water included in the organic compound layer 103, water adsorbed onto the surface of the organic compound layer 103, water included in the intermediate layer 116 that is a layer including an alkali metal or an alkali metal compound, and the like can be removed. Note that the heat treatment changes the shape of the insulating layer 127 in some cases. Specifically, the insulating layer 127 may be extended to cover at least one of an end portion of the inorganic insulating layer 125, an end portion of the sacrificial layer 158, and the top surface of the organic compound layer 103.

When the temperature of the heat treatment is too low, water included in the organic compound layer 103, water adsorbed onto the surface of the organic compound layer 103, water included in the intermediate layer 116 that is a layer including an alkali metal or an alkali metal compound, and the like cannot be sufficiently removed. When the temperature of the heat treatment is too high, the organic compound layer 103 might deteriorate and the insulating layer 127 might change in shape excessively. Thus, the temperature of the heat treatment is preferably higher than the temperature at which water is released from the organic compound layer 103 and lower than the glass transition temperature of the organic compound included in the organic compound layer 103, further preferably lower than the glass transition temperature of the organic compound included in the top surface of the organic compound layer 103. Specifically, the heat treatment is preferably performed at a substrate temperature higher than or equal to 80° C. and lower than or equal to 130° C., preferably higher than or equal to 90° C. and lower than or equal to 120° C., further preferably higher than or equal to 100° C. and lower than or equal to 120° C., still further preferably higher than or equal to 100° C. and lower than or equal to 110° C. The heating atmosphere may be either an air atmosphere or an inert gas atmosphere. Although the heating atmosphere may be an atmospheric-pressure atmosphere or a reduced-pressure atmosphere, a reduced-pressure atmosphere is preferably employed to prevent re-adsorption of water released from the organic compound layer 103.

By the heat treatment, water contained in the organic compound layer 103, water adsorbed onto the surface of the organic compound layer 103, water included in the intermediate layer 116 that is a layer including an alkali metal or an alkali metal compound, and the like can be sufficiently removed without causing deterioration of the organic compound layer 103 and an excessive change in the shape of the insulating layer 127. This can prevent a significant increase in driving voltage and a significant decrease in current efficiency of the light-emitting device even when the intermediate layer 116, which is a layer containing an alkali metal or an alkali metal compound, is exposed to a lithography process.

Next, as illustrated in FIG. 5B, the second electrode 102 is formed over the organic compound layer 103 and the insulating layer 127. The second electrode 102 can be formed by a method such as a sputtering method or a vacuum evaporation method. Alternatively, the second electrode 102 may be formed in such a manner that a film formed by an evaporation method and a film formed by a sputtering method are stacked.

Through the above steps, the light-emitting device 130 can be manufactured.

After the heat treatment, the organic compound layer 502b and the second electrode 102 can be formed over the organic compound layer 103 as illustrated in FIG. 5C. Since the organic compound layer 502b is formed after the lithography step, a material that does not have high heat resistance can be selected as the material that can be used for the organic compound layer 502b, so that the range of choices for the material can be widened.

For the organic compound layer 502b, a material functioning as an electron-injection layer can be used in the light-emitting device 130, for example. Specifically, as the organic compound layer 502b, a layer containing an alkali metal or an alkali metal compound can be formed. Forming the layer containing an alkali metal or an alkali metal compound after a lithography step can prevent a significant increase in driving voltage or a significant decrease in current efficiency of the light-emitting device. Note that in the case where the organic compound layer 502b is provided, a stack of the organic compound layer 103 and the organic compound layer 502b corresponds to the organic compound layer 103 described in Embodiment 1.

As described above, in the method for manufacturing a light-emitting device of this embodiment, the island-shaped organic compound layer 103 is formed not by using a fine metal mask but by processing a film formed on the entire surface; thus, the island-shaped layers can have a uniform thickness. Consequently, a light-emitting device that enables realization of a high-definition display device or a display device with a high aperture ratio can be manufactured. A tandem light-emitting device formed by a lithography method can have favorable characteristics.

This embodiment can be combined with the other embodiments or an example as appropriate. In this specification, in the case where a plurality of structure examples are described in one embodiment, the structure examples can be combined as appropriate.

### Embodiment 2

In this embodiment, materials that can be used for the layers of the light-emitting device 130 described in Embodiment 1 are described.

First, a material that can be used for the intermediate layer 116 is described. The intermediate film 116f is a film containing at least an alkali metal or an alkali metal compound. Specifically, it is preferable that the intermediate film 116f be a film including an N-type film and a P-type film, and the N-type film include an alkali metal or an alkali metal compound. Specific examples of the alkali metal include lithium, sodium, potassium, rubidium, cesium, and francium. Specific examples of the alkali metal compounds include compounds of the above alkali metals, e.g., lithium compounds such as lithium oxide. The N-type layer may include an organic compound having an electron-transport property in addition to the organic compound of one embodiment of the present invention, an alkali metal, or an alkali metal compound.

Lithium or a lithium compound is further preferably used as the alkali metal or the alkali metal compound, and specifically, lithium, a lithium complex, a lithium compound, a lithium alloy, or the like can be used. Specific examples include lithium, lithium oxide, lithium nitride, lithium carbonate, lithium fluoride, 8-quinolinolato-lithium (abbreviation: Liq), and a lithium complex including an alkyl group such as 2-methyl-8-quinolinolato-lithium (abbreviation: Li-mq).

The organic compound having an electron-transport property that can be used for the N-type layer 119 is preferably a substance having an electron mobility higher than or equal to 1×10⁻⁷ cm²/Vs, further preferably higher than or equal to 1×10⁻⁶ cm²/Vs in the case where the square root of the electric field strength [V/cm] is 600. Note that any other substance can also be used as long as the substance has an electron-transport property higher than a hole-transport property. An organic compound having a π-electron deficient heteroaromatic ring is preferable as the above organic compound. The organic compound having a π-electron deficient heteroaromatic ring is preferably one or more of an organic compound having a heteroaromatic ring having a polyazole skeleton, an organic compound having a heteroaromatic ring having a pyridine skeleton, an organic compound having a heteroaromatic ring having a diazine skeleton, and an organic compound having a heteroaromatic ring having a triazine skeleton.

Specific examples of the organic compound having an electron-transport property that can be used for the N-type layer 119 include an organic compound having an azole skeleton, such as 2-(4-biphenylyl)-5-(4-tert-butylphenyl)-1,3,4-oxadiazole (abbreviation: PBD), 3-(4-biphenylyl)-4-phenyl-5-(4-tert-butylphenyl)-1,2,4-triazole (abbreviation: TAZ), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: CO11), 2,2′,2″-(1,3,5-benzenetriyl)tris(1-phenyl-1H-benzimidazole) (abbreviation: TPBI), 2-[3-(dibenzothiophen-4-yl)phenyl]-1-phenyl-1H-benzimidazole (abbreviation: mDBTBIm-II), or 4,4′-bis(5-methylbenzoxazol-2-yl)stilbene (abbreviation: BzOs); an organic compound having a heteroaromatic ring having a pyridine skeleton, such as 3,5-bis[3-(9H-carbazol-9-yl)phenyl]pyridine (abbreviation: 35DCzPPy), 1,3,5-tri[3-(3-pyridyl)phenyl]benzene (abbreviation: TmPyPB), bathophenanthroline (abbreviation: Bphen), bathocuproine (abbreviation: BCP), 2,9-di(naphthalen-2-yl)-4,7-diphenyl-1,10-phenanthroline (abbreviation: NBphen), or 2,2′-(1,3-phenylene)bis(9-phenyl-1,10-phenanthroline) (abbreviation: mPPhen2P); an organic compound having a diazine skeleton, such as 2-[3-(dibenzothiophen-4-yl)phenyl]dibenzo[f,h]quinoxaline (abbreviation: 2mDBTPDBq-II), 2-[3-(3′-dibenzothiophen-4-yl)biphenyl]dibenzo[f,h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 2-[4′-(9-phenyl-9H-carbazol-3-yl)-3,1′-biphenyl-1-yl]dibenzo[f,h]quinoxaline (abbreviation: 2mpPCBPDBq), 2-[4-(3,6-diphenyl-9H-carbazol-9-yl)phenyl]dibenzo[f,h]quinoxaline (abbreviation: 2CzPDBq-III), 7-[3-(dibenzothiophen-4-yl)phenyl]dibenzo[f,h]quinoxaline (abbreviation: 7mDBTPDBq-II), 6-[3-(dibenzothiophen-4-yl)phenyl]dibenzo[f,h]quinoxaline (abbreviation: 6mDBTPDBq-II), 9-[3′-(dibenzothiophen-4-yl)biphenyl-3-yl]naphtho[1′,2′:4,5]furo[2,3-b]pyrazine (abbreviation: 9mDBtBPNfpr), 9-[(3′-dibenzothiophen-4-yl)biphenyl-4-yl]naphtho[1′,2′:4,5]furo[2,3-b]pyrazine (abbreviation: 9pmDBtBPNfpr), 4,6-bis[3-(phenanthren-9-yl)phenyl]pyrimidine (abbreviation: 4,6mPnP2Pm), 4,6-bis[3-(4-dibenzothienyl)phenyl]pyrimidine (abbreviation: 4,6mDBTP2Pm-II), 4,6-bis[3-(9H-carbazol-9-yl)phenyl]pyrimidine (abbreviation: 4,6mCzP2Pm), 9,9′-[pyrimidine-4,6-diylbis(biphenyl-3,3′-diyl)]bis(9H-carbazole) (abbreviation: 4,6mCzBP2Pm), 8-(1,1′-biphenyl-4-yl)-4-[3-(dibenzothiophen-4-yl)phenyl]-[1]benzofuro[3,2-d]pyrimidine (abbreviation: 8BP-4mDBtPBfpm), 3,8-bis[3-(dibenzothiophen-4-yl)phenyl]benzofuro[2,3-b]pyrazine (abbreviation: 3,8mDBtP2Bfpr), 4,8-bis[3-(dibenzothiophen-4-yl)phenyl]-[1]benzofuro[3,2-d]pyrimidine (abbreviation: 4,8mDBtP2Bfpm), 8-[3′-(dibenzothiophen-4-yl)biphenyl-3-yl]naphtho[1′,2′:4,5]furo[3,2-d]pyrimidine (abbreviation: 8mDBtBPNfpm), 8-[(2,2′-binaphthalen)-6-yl]-4-[3-(dibenzothiophen-4-yl)phenyl]-[1]benzofuro[3,2-d]pyrimidine (abbreviation: 8(βN2)-4mDBtPBfpm), 2,2′-(pyridine-2,6-diyl)bis(4-phenylbenzo[h]quinazoline) (abbreviation: 2,6(P-Bqn)2Py), 2,2′-(pyridine-2,6-diyl)bis{4-[4-(2-naphthyl)phenyl]-6-phenylpyrimidine} (abbreviation: 2,6(NP-PPm)2Py), 6-(biphenyl-3-yl)-4-[3,5-bis(9H-carbazol-9-yl)phenyl]-2-phenylpyrimidine (abbreviation: 6mBP-4Cz2PPm), 2,6-bis(4-naphthalen-1-ylphenyl)-4-[4-(3-pyridyl)phenyl]pyrimidine (abbreviation: 2,4NP-6PyPPm), 4-[3,5-bis(9H-carbazol-9-yl)phenyl]-2-phenyl-6-(biphenyl-4-yl)pyrimidine (abbreviation: 6BP-4Cz2PPm), or 7-[4-(9-phenyl-9H-carbazol-2-yl)quinazolin-2-yl]-7H-dibenzo[c,g]carbazole (abbreviation: PC-cgDBCzQz); and an organic compound having a triazine skeleton, such as 2-(biphenyl-4-yl)-4-phenyl-6-(9,9′-spirobi[9H-fluoren]-2-yl)-1,3,5-triazine (abbreviation: BP-SFTzn), 2-{3-[3-(benzo[b]naphtho[1,2-d]furan-8-yl)phenyl]phenyl}-4,6-diphenyl-1,3,5-triazine (abbreviation: mBnfBPTzn), 2-{3-[3-(benzo[b]naphtho[1,2-d]furan-6-yl)phenyl]phenyl}-4,6-diphenyl-1,3,5-triazine (abbreviation: mBnfBPTzn-02), 2-{4-[3-(N-phenyl-9H-carbazol-3-yl)-9H-carbazol-9-yl]phenyl}-4,6-diphenyl-1,3,5-triazine (abbreviation: PCCzPTzn), 9-[3-(4,6-diphenyl-1,3,5-triazin-2-yl)phenyl]-9′-phenyl-2,3′-bi-9H-carbazole (abbreviation: mPCCzPTzn-02), 2-[3′-(9,9-dimethyl-9H-fluoren-2-yl)biphenyl-3-yl]-4,6-diphenyl-1,3,5-triazine (abbreviation: mFBPTzn), 5-[3-(4,6-diphenyl-1,3,5-triazin-2-yl)phenyl]-7,7-dimethyl-5H,7H-indeno[2,1-b]carbazole (abbreviation: mINc(II)PTzn), 2-{3-[3-(dibenzothiophen-4-yl)phenyl]phenyl}-4,6-diphenyl-1,3,5-triazine (abbreviation: mDBtBPTzn), 2,4,6-tris(3′-(pyridin-3-yl)biphenyl-3-yl)-1,3,5-triazine (abbreviation: TmPPPyTz), 2-[3-(2,6-dimethyl-3-pyridinyl)-5-(9-phenanthrenyl)phenyl]-4,6-diphenyl-1,3,5-triazine (abbreviation: mPn-mDMePyPTzn), 11-[4-(biphenyl-4-yl)-6-phenyl-1,3,5-triazin-2-yl]-11,12-dihydro-12-phenylindolo[2,3-a]carbazole (abbreviation: BP-Icz(II)Tzn), 2-[3′-(triphenylen-2-yl)biphenyl-3-yl]-4,6-diphenyl-1,3,5-triazine (abbreviation: mTpBPTzn), 3-[9-(4,6-diphenyl-1,3,5-triazin-2-yl)-2-dibenzofuranyl]-9-phenyl-9H-carbazole (abbreviation: PCDBfTzn), or 2-(biphenyl-3-yl)-4-phenyl-6-{8-[(1,1′: 4′,1″-terphenyl)-4-yl]-1-dibenzofuranyl}-1,3,5-triazine (abbreviation: mBP-TPDBfTzn). In particular, organic compounds having a phenanthroline skeleton, such as Bphen, BCP, NBphen, and mPPhen2P, are preferred, and an organic compound having a phenanthroline dimeric structure, such as mPPhen2P, is further preferred because of its excellent stability.

The P-type layer 117 which is a charge generation layer is preferably formed using a composite material containing a material having an acceptor property and an organic compound having a hole-transport property. As the organic compound having a hole-transport property that is used in the composite material, any of a variety of organic compounds such as aromatic amine compounds, heteroaromatic compounds, aromatic hydrocarbons, and high molecular compounds (e.g., oligomers, dendrimers, or polymers) can be used. Note that the organic compound having a hole-transport property that is used in the composite material preferably has a hole mobility of 1×10⁻⁶ cm²/Vs or higher. The organic compound having a hole-transport property that is used in the composite material is preferably a compound having a condensed aromatic hydrocarbon ring or a π-electron rich heteroaromatic ring. As the condensed aromatic hydrocarbon ring, an anthracene ring, a naphthalene ring, or the like is preferable. As the π-electron rich heteroaromatic ring, a condensed aromatic ring having at least one of a pyrrole skeleton, a furan skeleton, and a thiophene skeleton in the ring is preferable; specifically, a carbazole ring, a dibenzothiophene ring, or a ring in which an aromatic ring or a heteroaromatic ring is further condensed to the carbazole ring or the dibenzothiophene ring is preferable.

Such an organic compound having a hole-transport property further preferably has any of a carbazole skeleton, a dibenzofuran skeleton, a dibenzothiophene skeleton, and an anthracene skeleton. In particular, an aromatic amine having a substituent that includes a dibenzofuran ring or a dibenzothiophene ring, an aromatic monoamine that includes a naphthalene ring, or an aromatic monoamine in which a 9-fluorenyl group is bonded to nitrogen of amine through an arylene group may be used. Note that the organic compound having a hole-transport property preferably has an N,N-bis(4-biphenyl)amino group because a light-emitting device having a long lifetime can be manufactured.

Specific examples of such an organic compound having a hole-transport property include N-(4-biphenyl)-6,N-diphenylbenzo[b]naphtho[1,2-d]furan-8-amine (abbreviation: BnfABP), N,N-bis(4-biphenyl)-6-phenylbenzo[b]naphtho[1,2-d]furan-8-amine (abbreviation: BBABnf), 4,4′-bis(6-phenylbenzo[b]naphtho[1,2-d]furan-8-yl)-4″-phenyltriphenylamine (abbreviation: BnfBB1BP), N,N-bis(4-biphenyl)benzo[b]naphtho[1,2-d]furan-6-amine (abbreviation: BBABnf(6)), N,N-bis(4-biphenyl)benzo[b]naphtho[1,2-d]furan-8-amine (abbreviation: BBABnf(8)), N,N-bis(4-biphenyl)benzo[b]naphtho[2,3-d]furan-4-amine (abbreviation: BBABnf(II)(4)), N,N-bis[4-(dibenzofuran-4-yl)phenyl]-4-amino-p-terphenyl (abbreviation: DBfBB1TP), N-[4-(dibenzothiophen-4-yl)phenyl]-N-phenyl-4-biphenylamine (abbreviation: ThBA1BP), 4-(2-naphthyl)-4′,4″-diphenyltriphenylamine (abbreviation: BBAβNB), 4-[4-(2-naphthyl)phenyl]-4′,4″-diphenyltriphenylamine (abbreviation: BBAβNBi), 4,4′-diphenyl-4″-(6;1′-binaphthyl-2-yl)triphenylamine (abbreviation: BBAαNβNB), 4,4′-diphenyl-4″-(7;1′-binaphthyl-2-yl)triphenylamine (abbreviation: BBAPβNB-03), 4,4′-diphenyl-4″-(7-phenyl)naphthyl-2-yltriphenylamine (abbreviation: BBAPβNB-03), 4,4′-diphenyl-4″-(6;2′-binaphthyl-2-yl)triphenylamine (abbreviation: BBA(βN2)B), 4,4′-diphenyl-4″-(7;2′-binaphthyl-2-yl)triphenylamine (abbreviation: BBA(βN2)B-03), 4,4′-diphenyl-4″-(4;2′-binaphthyl-1-yl)triphenylamine (abbreviation: BBAβNαNB), 4,4′-diphenyl-4″-(5;2′-binaphthyl-1-yl)triphenylamine (abbreviation: BBAβNαNB-02), 4-(4-biphenylyl)-4′-(2-naphthyl)-4″-phenyltriphenylamine (abbreviation: TPBiAβNB), 4-(3-biphenylyl)-4′-[4-(2-naphthyl)phenyl]-4″-phenyltriphenylamine (abbreviation: mTPBiAβNBi), 4-(4-biphenylyl)-4′-[4-(2-naphthyl)phenyl]-4″-phenyltriphenylamine (abbreviation: TPBiAβNBi), 4-phenyl-4′-(1-naphthyl)triphenylamine (abbreviation: αNBA1BP), 4,4′-bis(1-naphthyl)triphenylamine (abbreviation: αNBB1BP), 4,4′-diphenyl-4″-[4′-(carbazol-9-yl)biphenyl-4-yl]triphenylamine (abbreviation: YGTBi1BP), 4′-[4-(3-phenyl-9H-carbazol-9-yl)phenyl]tris(−biphenyl-4-yl)amine (abbreviation: YGTBi1BP-02), 4-[4′-(carbazol-9-yl)biphenyl-4-yl]-4′-(2-naphthyl)-4″-phenyltriphenylamine (abbreviation: YGTBiβNB), N-[4-(9-phenyl-9H-carbazol-3-yl)phenyl]-N-[4-(1-naphthyl)phenyl]-9,9′-spirobi[9H-fluoren]-2-amine (abbreviation: PCBNBSF), N,N-bis(biphenyl-4-yl)-9,9′-spirobi[9H-fluoren]-2-amine (abbreviation: BBASF), N,N-bis(biphenyl-4-yl)-9,9′-spirobi[9H-fluoren]-4-amine (abbreviation: BBASF(4)), N-(biphenyl-2-yl)-N-(9,9-dimethyl-9H-fluoren-2-yl)-9,9′-spirobi[9H-fluoren]-4-amine (abbreviation: oFBiSF), N-(biphenyl-4-yl)-N-(9,9-dimethyl-9H-fluoren-2-yl)dibenzofuran-4-amine (abbreviation: FrBiF), N-[4-(1-naphthyl)phenyl]-N-[3-(6-phenyldibenzofuran-4-yl)phenyl]-1-naphthylamine (abbreviation: mPDBfBNBN), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-[4-(9-phenylfluoren-9-yl)phenyl]triphenylamine (abbreviation: BPAFLBi), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), N-phenyl-N-[4-(9-phenyl-9H-carbazol-3-yl)phenyl]-9,9′-spirobi[9H-fluoren]-2-amine (abbreviation: PCBASF), N-(biphenyl-4-yl)-N-[4-(9-phenyl-9H-carbazol-3-yl)phenyl]-9,9-dimethyl-9H-fluoren-2-amine (abbreviation: PCBBiF), N,N-bis(9,9-dimethyl-9H-fluoren-2-yl)-9,9′-spirobi-9H-fluoren-4-amine, N,N-bis(9,9-dimethyl-9H-fluoren-2-yl)-9,9′-spirobi-9H-fluoren-3-amine, N,N-bis(9,9-dimethyl-9H-fluoren-2-yl)-9,9′-spirobi-9H-fluoren-2-amine, and N,N-bis(9,9-dimethyl-9H-fluoren-2-yl)-9,9′-spirobi-9H-fluoren-1-amine.

As the material having a hole-transport property, the following aromatic amine compounds can also be used: N,N′-di(p-tolyl)-N,N′-diphenyl-p-phenylenediamine (abbreviation: DTDPPA), 4,4′-bis[N-(4-diphenylaminophenyl)-N-phenylamino]biphenyl (abbreviation: DPAB), 4,4′-bis(N-{4-[N-(3-methylphenyl)-N′-phenylamino]phenyl}-N-phenylamino)biphenyl (abbreviation: DNTPD), and 1,3,5-tris[N-(4-diphenylaminophenyl)-N-phenylamino]benzene (abbreviation: DPA3B).

Examples of the substance having an acceptor property that is included in the P-type layer 117 include an organic compound having an electron-withdrawing group (a halogen group, a cyano group, or the like), such as 7,7,8,8-tetracyano-2,3,5,6-tetrafluoroquinodimethane (abbreviation: F4-TCNQ), chloranil, 2,3,6,7,10,11-hexacyano-1,4,5,8,9,12-hexaazatriphenylene (abbreviation: HAT-CN), 1,3,4,5,7,8-hexafluorotetracyano-naphthoquinodimethane (abbreviation: F6-TCNNQ), or 2-(7-dicyanomethylen-1,3,4,5,6,8,9,10-octafluoro-7H-pyren-2-ylidene)malononitrile. A compound in which electron-withdrawing groups are bonded to a condensed aromatic ring having a plurality of heteroatoms, such as HAT-CN, is particularly preferable because it is thermally stable. A [3]radialene derivative having an electron-withdrawing group (in particular, a cyano group or a halogen group such as a fluoro group) has a very high electron-accepting property and thus is preferable. Specific examples include α,α′,α″-1,2,3-cyclopropanetriylidenetris[4-cyano-2,3,5,6-tetrafluorobenzeneacetonitrile], α,α′,α″-1,2,3-cyclopropanetriylidenetris[2,6-dichloro-3,5-difluoro-4-(trifluoromethyl)benzeneacetonitrile], and α,α′,α″-1,2,3-cyclopropanetriylidenetris[2,3,4,5,6-pentafluorobenzeneacetonitrile]. As the substance having an acceptor property, transition metal oxide such as molybdenum oxide, vanadium oxide, ruthenium oxide, tungsten oxide, or manganese oxide can also be used, other than the above-described organic compounds.

The electron-relay layer 118 contains a substance having an electron-transport property and has a function of preventing an interaction between the N-type layer 119 and the P-type layer 117 and smoothly transferring electrons. The LUMO (Lowest Unoccupied Molecular Orbital) level of the substance having an electron-transport property contained in the electron-relay layer 118 is preferably between the LUMO level of the acceptor substance in the P-type layer 117 and the LUMO level of an organic compound contained in a layer that is included in the light-emitting unit on the first electrode 101 side and is in contact with the intermediate layer 116 (the first electron-transport layer 114_1 in the first light-emitting unit 501 in FIG. 1A). As a specific value of the energy level, the LUMO level of the substance having an electron-transport property used in the electron-relay layer 118 is preferably higher than or equal to −5.0 eV, further preferably higher than or equal to −5.0 eV and lower than or equal to −3.0 eV. Note that as the substance having an electron-transport property used in the electron-relay layer 118, a phthalocyanine-based material or a metal complex having a metal-oxygen bond and an aromatic ligand is preferably used.

Then, components of the above light-emitting device 130, other than the intermediate layer 116, are described.

The first electrode 101 includes an anode. The first electrode 101 may have a stacked-layer structure where the layer in contact with the organic compound layer 103 functions as the anode. The anode is preferably formed using any of metals, alloys, and conductive compounds with a high work function (specifically, higher than or equal to 4.0 eV), mixtures thereof, and the like. Specific examples include indium oxide-tin oxide (ITO: Indium Tin Oxide), indium oxide-tin oxide containing silicon or silicon oxide, indium oxide-zinc oxide, and indium oxide containing tungsten oxide and zinc oxide (IWZO). Such conductive metal oxide films are usually formed by a sputtering method, but may be formed by application of a sol-gel method or the like. In an example of the formation method, indium oxide-zinc oxide is formed by a sputtering method using a target obtained by adding 1 to 20 wt % of zinc oxide to indium oxide. Furthermore, indium oxide containing tungsten oxide and zinc oxide (IWZO) can be formed by a sputtering method using a target in which tungsten oxide and zinc oxide are added to indium oxide at 0.5 to 5 wt % and 0.1 to 1 wt %, respectively. Other examples of the material used for the anode include gold (Au), platinum (Pt), nickel (Ni), tungsten (W), chromium (Cr), molybdenum (Mo), iron (Fe), cobalt (Co), copper (Cu), palladium (Pd), and nitride of a metal material (e.g., titanium nitride). Graphene can also be used for the anode. Note that when the composite material contained in the P-type layer 117 in the intermediate layer 116 is used for a layer (typically, a hole-injection layer) that is in contact with the anode, an electrode material can be selected regardless of its work function.

The organic compound layer 103 has a stacked-layer structure. As the stacked-layer structure, FIG. 1A illustrates the structure that includes the first light-emitting unit 501 including the first light-emitting layer 113_1, the intermediate layer 116, and the second light-emitting unit 502 including the second light-emitting layer 113_2. In the structure, two light-emitting units are stacked with the intermediate layer therebetween; however, three or more light-emitting units may be stacked. Also in that case, an intermediate layer is provided between the light-emitting units. Each of the light-emitting units also has a stacked-layer structure. The light-emitting units can include a variety of functional layers such as a hole-injection layer, a hole-transport layer, an electron-transport layer, an electron-injection layer, carrier-blocking layers (a hole-blocking layer and an electron-blocking layer), and an exciton-blocking layer as appropriate, without being limited to the structure illustrated in FIG. 1A.

The hole-injection layer 111 is provided in contact with the anode and has a function of facilitating injection of holes into the organic compound layer 103 (the first light-emitting unit 501). The hole-injection layer 111 can be formed using phthalocyanine-based compound such as phthalocyanine (abbreviation: H₂Pc), a phthalocyanine-based complex compound such as copper phthalocyanine (abbreviation: CuPc), an aromatic amine compound such as 4,4′-bis[N-(4-diphenylaminophenyl)-N-phenylamino]biphenyl (abbreviation: DPAB) or 4,4′-bis(N-{4-[N′-(3-methylphenyl)-N′-phenylamino]phenyl}-N-phenylamino)biphenyl (abbreviation: DNTPD), a high molecular compound such as poly(3,4-ethylenedioxythiophene)/(polystyrenesulfonic acid) (abbreviation: PEDOT/PSS), or the like.

The hole-injection layer 111 may be formed using a substance having an electron-acceptor property. As the substance having an acceptor property, any of substances described as examples of the acceptor substance that is used in the composite material contained in the P-type layer 117 in the intermediate layer 116 can similarly be used.

The composite material contained in the P-type layer 117 in the intermediate layer 116 may be similarly used to form the hole-injection layer 111.

In the hole-injection layer 111, it is further preferable that the organic compound having a hole-transport property that is used in the composite material have a relatively deep HOMO (Highest Occupied Molecular Orbital) level higher than or equal to −5.7 eV and lower than or equal to −5.4 eV. When the organic compound having a hole-transport property that is used in the composite material has a relatively deep HOMO level, holes can be easily injected into the hole-transport layer to easily provide a light-emitting device having a long lifetime. In addition, when the organic compound having a hole-transport property that is used in the composite material has a relatively deep HOMO level, induction of holes can be inhibited properly so that a light-emitting device having a longer lifetime can be obtained.

The formation of the hole-injection layer 111 can improve the hole-injection property, whereby a light-emitting device having a low driving voltage can be obtained.

Among substances having an acceptor property, an organic compound having an acceptor property is easy to use because it is easily deposited by vapor deposition.

Since the P-type layer 117 in the intermediate layer 116 functions as a hole-injection layer, another hole-injection layer is not provided in the second light-emitting unit 502; however, a hole-injection layer may be provided in the second light-emitting unit.

The hole-transport layer (the first hole-transport layer 112_1 or the second hole-transport layer 112_2) includes an organic compound having a hole-transport property. The organic compound having a hole-transport property preferably has a hole mobility higher than or equal to 1×10⁻⁶ cm²/Vs.

Examples of the material having a hole-transport property include compounds having an aromatic amine skeleton, such as 4,4′-bis[N-(1-naphthyl)-N-phenylamino]biphenyl (abbreviation: NPB), N,N′-diphenyl-N,N′-bis(3-methylphenyl)-4,4′-diaminobiphenyl (abbreviation: TPD), N,N′-bis(9,9′-spirobi[9H-fluoren]-2-yl)-N,N′-diphenyl-4,4′-diaminobiphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 9,9-dimethyl-N-phenyl-N-[4-(9-phenyl-9H-carbazol-3-yl)phenyl]fluoren-2-amine (abbreviation: PCBAF), and N-phenyl-N-[4-(9-phenyl-9H-carbazol-3-yl)phenyl]-9,9′-spirobi[9H-fluoren]-2-amine (abbreviation: PCBASF); compounds having a carbazole skeleton, such as 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), 3,3′-bis(9-phenyl-9H-carbazole) (abbreviation: PCCP), 9,9′-bis(biphenyl-4-yl)-3,3′-bi-9H-carbazole (abbreviation: BisBPCz), 9,9′-bis(1,1′-biphenyl-3-yl)-3,3′-bi-9H-carbazole (abbreviation: BismBPCz), 9-(1,1′-biphenyl-3-yl)-9′-(1,1′-biphenyl-4-yl)-9H,9′H-3,3′-bicarbazole (abbreviation: mBPCCBP), 9-(2-naphthyl)-9′-phenyl-9H,9′H-3,3′-bicarbazole (abbreviation: βNCCP), 9-(3-biphenyl)-9′-(2-naphthyl)-3,3′-bi-9H-carbazole (abbreviation: βNCCmBP), 9-(4-biphenyl)-9′-(2-naphthyl)-3,3′-bi-9H-carbazole (abbreviation: βNCCBP), 9,9′-di-2-naphthyl-3,3′-9H,9′H-bicarbazole (abbreviation: BisβNCz), 9-(2-naphthyl)-9′-[1,1′: 4′,1″-terphenyl]-3-yl-3,3′-9H,9′H-bicarbazole, 9-(2-naphthyl)-9′-[1,1′: 3′,1″-terphenyl]-3-yl-3,3′-9H,9′H-bicarbazole, 9-(2-naphthyl)-9′-[1,1′: 3′,1″-terphenyl]-5′-yl-3,3′-9H,9′H-bicarbazole, 9-(2-naphthyl)-9′-[1,1′: 4′,1″-terphenyl]-4-yl-3,3′-9H,9′H-bicarbazole, 9-(2-naphthyl)-9′-[1,1′: 3′,1″-terphenyl]-4-yl-3,3′-9H,9′H-bicarbazole, 9-(2-naphthyl)-9′-(triphenylen-2-yl)-3,3′-9H,9′H-bicarbazole, 9-phenyl-9′-(triphenylen-2-yl)-3,3′-9H,9′H-bicarbazole (abbreviation: PCCzTp), 9,9′-bis(triphenylen-2-yl)-3,3′-9H,9′H-bicarbazole, 9-(4-biphenyl)-9′-(triphenylen-2-yl)-3,3′-9H,9′H-bicarbazole, and 9-(triphenylen-2-yl)-9′-[1,1′:3′,1″-terphenyl]-4-yl-3,3′-9H,9′H-bicarbazole; compounds having a thiophene skeleton, such as 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), and 4-[4-(9-phenyl-9H-fluoren-9-yl)phenyl]-6-phenyldibenzothiophene (abbreviation: DBTFLP-IV); and compounds having a furan skeleton, such as 4,4′,4″-(benzene-1,3,5-triyl)tri(dibenzofuran) (abbreviation: DBF3P-II) and 4-{3-[3-(9-phenyl-9H-fluoren-9-yl)phenyl]phenyl}dibenzofuran (abbreviation: mmDBFFLBi-II). Among the above materials, the compound having an aromatic amine skeleton and the compound having a carbazole skeleton are preferable because these compounds are highly reliable and have high hole-transport properties to contribute to a reduction in driving voltage. Note that any of the substances given as examples of the material having a hole-transport property used for the composite material for the hole-injection layer 111 can also be suitably used as the material included in the hole-transport layer.

The light-emitting layer (the first light-emitting layer 113_1 and the second light-emitting layer 113_2) preferably contains a light-emitting substance and a host material. The light-emitting layer may additionally contain other materials. Alternatively, the light-emitting layer may be a stack of two layers with different compositions.

The light-emitting substance may be a fluorescent substance, a phosphorescent substance, a substance exhibiting thermally activated delayed fluorescence (TADF), or other light-emitting substances.

Examples of the material that can be used as a fluorescent substance in the light-emitting layer are as follows. Other fluorescent substances can also be used.

The examples include 5,6-bis[4-(10-phenyl-9-anthryl)phenyl]-2,2′-bipyridine (abbreviation: PAP2BPy), 5,6-bis[4′-(10-phenyl-9-anthryl)biphenyl-4-yl]-2,2′-bipyridine (abbreviation: PAPP2BPy), N,N′-diphenyl-N,N′-bis[4-(9-phenyl-9H-fluoren-9-yl)phenyl]pyrene-1,6-diamine (abbreviation: 1,6FLPAPm), N,N′-bis(3-methylphenyl)-N,N′-bis[3-(9-phenyl-9H-fluoren-9-yl)phenyl]pyrene-1,6-diamine (abbreviation: 1,6mMemFLPAPm), N,N′-bis[4-(9H-carbazol-9-yl)phenyl]-N,N′-diphenylstilbene-4,4′-diamine (abbreviation: YGA2S), 4-(9H-carbazol-9-yl)-4′-(10-phenyl-9-anthryl)triphenylamine (abbreviation: YGAPA), 4-(9H-carbazol-9-yl)-4′-(9,10-diphenyl-2-anthryl)triphenylamine (abbreviation: 2YGAPPA), N,9-diphenyl-N-[4-(10-phenyl-9-anthryl)phenyl]-9H-carbazol-3-amine (abbreviation: PCAPA), perylene, 2,5,8,11-tetra-tert-butylperylene (abbreviation: TBP), 4-(10-phenyl-9-anthryl)-4′-(9-phenyl-9H-carbazol-3-yl)triphenylamine (abbreviation: PCBAPA), N,N″-(2-tert-butylanthracene-9,10-diyldi-4,1-phenylene)bis(N,N′,N″-triphenyl-1,4-phenylenediamine) (abbreviation: DPABPA), N,9-diphenyl-N-[4-(9,10-diphenyl-2-anthryl)phenyl]-9H-carbazol-3-amine (abbreviation: 2PCAPPA), N-[4-(9,10-diphenyl-2-anthryl)phenyl]-N,N′,N″-triphenyl-1,4-phenylenediamine (abbreviation: 2DPAPPA), N,N,N′,N′,N″,N″,N′″,N′″-octaphenyldibenzo[g,p]rysene-2,7,10,15-tetraamine (abbreviation: DBC1), coumarin 30, N-(9,10-diphenyl-2-anthryl)-N,9-diphenyl-9H-carbazol-3-amine (abbreviation: 2PCAPA), N-[9,10(bis-biphenyl-2-yl)-2-anthryl]-N,9-diphenyl-9H-carbazol-3-amine (abbreviation: 2PCABPhA), N-(9,10-diphenyl-2-anthryl)-N,N′,N″-triphenyl-1,4-phenylenediamine (abbreviation: 2DPAPA), N-[9,10-bis(biphenyl-2-yl)-2-anthryl]-N,N′,N′-triphenyl-1,4-phenylenediamine (abbreviation: 2DPABPhA), 9,10-bis(biphenyl-2-yl)-N-[4-(9H-carbazol-9-yl)phenyl]-N-phenylanthracen-2-amine (abbreviation: 2YGABPhA), N,N,9-triphenylanthracen-9-amine (abbreviation: DPhAPhA), coumarin 545T, N,N′-diphenylquinacridone (abbreviation: DPQd), rubrene, 5,12-bis(1,1′-biphenyl-4-yl)-6,11-diphenyltetracene (abbreviation: BPT), 2-(2-{2-[4-(dimethylamino)phenyl]ethenyl}-6-methyl-4H-pyran-4-ylidene)propanedinitrile (abbreviation: DCM1), 2-{2-methyl-6-[2-(2,3,6,7-tetrahydro-1H,5H-benzo[ij]quinolizin-9-yl)ethenyl]-4H-pyran-4-ylidene}propanedinitrile (abbreviation: DCM2), N,N,N′,N′-tetrakis(4-methylphenyl)tetracene-5,11-diamine (abbreviation: p-mPhTD), 7,14-diphenyl-N,N,N′,N′-tetrakis(4-methylphenyl)acenaphtho[1,2-a]fluoranthene-3,10-diamine (abbreviation: p-mPhAFD), 2-{2-isopropyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTI), 2-{2-tert-butyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTB), 2-(2,6-bis{2-[4-(dimethylamino)phenyl]ethenyl}-4H-pyran-4-ylidene)propanedinitrile (abbreviation: BisDCM), 2-{2,6-bis[2-(8-methoxy-1,1,7,7-tetramethyl-2,3,6,7-tetrahydro-1H,5H-benzo[ij]quinolizin-9-yl)ethenyl]-4H-pyran-4-ylidene}propanedinitrile (abbreviation: BisDCJTM), N,N′-diphenyl-N,N′-(1,6-pyrene-diyl)bis[(6-phenylbenzo[b]naphtho[1,2-d]furan)-8-amine](abbreviation: 1,6BnfAPrn-03), 3,10-bis[N-(9-phenyl-9H-carbazol-2-yl)-N-phenylamino]naphtho[2,3-b;6,7-b′]bisbenzofuran (abbreviation: 3,10PCA2Nbf(IV)-02), and 3,10-bis[N-(dibenzofuran-3-yl)-N-phenylamino]naphtho[2,3-b;6,7-b′]bisbenzofuran (abbreviation: 3,10FrA2Nbf(IV)-02). Condensed aromatic diamine compounds typified by pyrenediamine compounds such as 1,6FLPAPm, 1,6mMemFLPAPm, and 1,6BnfAPm-03 are particularly preferable because of their high hole-trapping properties, high emission efficiency, or high reliability.

Examples of the material that can be used when a phosphorescent substance is used as the light-emitting substance in the light-emitting layer are as follows.

The examples include an organometallic iridium complex having a 4H-triazole skeleton, such as tris{2-[5-(2-methylphenyl)-4-(2,6-dimethylphenyl)-4H-1,2,4-triazol-3-yl-κN2]phenyl-κC}iridium(III) (abbreviation: [Ir(mpptz-dmp)₃]), tris(5-methyl-3,4-diphenyl-4H-1,2,4-triazolato)iridium(III) (abbreviation: [Ir(Mptz)₃]), or tris[4-(3-biphenyl)-5-isopropyl-3-phenyl-4H-1,2,4-triazolato]iridium(III) (abbreviation: [Ir(iPrptz-3b)₃]); an organometallic iridium complex having a 1H-triazole skeleton, such as tris[3-methyl-1-(2-methylphenyl)-5-phenyl-1H-1,2,4-triazolato]iridium(III) (abbreviation: [Ir(Mptzl-mp)₃]) or tris(1-methyl-5-phenyl-3-propyl-1H-1,2,4-triazolato)iridium(III) (abbreviation: [Ir(Prptz1-Me)₃]); an organometallic iridium complex having an imidazole skeleton, such as fac-tris[1-(2,6-diisopropylphenyl)-2-phenyl-1H-imidazole]iridium(III) (abbreviation: [Ir(iPrpim)₃]) or tris[3-(2,6-dimethylphenyl)-7-methylimidazo[1,2-f]phenanthridinato]iridium(III) (abbreviation: [Ir(dmpimpt-Me)₃]); and an organometallic iridium complex in which a phenylpyridine derivative having an electron-withdrawing group is a ligand, such as bis[2-(4′,6′-difluorophenyl)pyridinato-N,C^{2′}]iridium(III) tetrakis(1-pyrazolyl)borate (abbreviation: FIr6), bis[2-(4′,6′-difluorophenyl)pyridinato-N,C^{2′}]iridium(III) picolinate (abbreviation: FIrpic), bis{2-[3′,5′-bis(trifluoromethyl)phenyl]pyridinato-N,C^{2′}}iridium(III) picolinate (abbreviation: [Ir(CF₃ppy)₂(pic)]), or bis[2-(4′,6′-difluorophenyl)pyridinato-N,C^{2′}]iridium(III) acetylacetonate (abbreviation: FIracac). These compounds exhibit blue phosphorescent light and have an emission peak in the wavelength range of 450 nm to 520 nm.

Other examples include an organometallic iridium complex having a pyrimidine skeleton, such as tris(4-methyl-6-phenylpyrimidinato)iridium(III) (abbreviation: [Ir(mppm)₃]), tris(4-t-butyl-6-phenylpyrimidinato)iridium(III) (abbreviation: [Ir(tBuppm)₃]), (acetylacetonato)bis(6-methyl-4-phenylpyrimidinato)iridium(III) (abbreviation: [Ir(mppm)₂(acac)]), (acetylacetonato)bis(6-tert-butyl-4-phenylpyrimidinato)iridium(III) (abbreviation: [Ir(tBuppm)₂(acac)]), (acetylacetonato)bis[6-(2-norbornyl)-4-phenylpyrimidinato]iridium(III) (abbreviation: [Ir(nbppm)₂(acac)]), (acetylacetonato)bis[5-methyl-6-(2-methylphenyl)-4-phenylpyrimidinato]iridium(III) (abbreviation: [Ir(mpmppm)₂(acac)]), or (acetylacetonato)bis(4,6-diphenylpyrimidinato)iridium(III) (abbreviation: [Ir(dppm)₂(acac)]); an organometallic iridium complex having a pyrazine skeleton, such as (acetylacetonato)bis(3,5-dimethyl-2-phenylpyrazinato)iridium(III) (abbreviation: [Ir(mppr-Me)₂(acac)]) or (acetylacetonato)bis(5-isopropyl-3-methyl-2-phenylpyrazinato)iridium(III) (abbreviation: [Ir(mppr-iPr)₂(acac)]); an organometallic iridium complex having a pyridine skeleton, such as tris(2-phenylpyridinato-N,C^{2′})iridium(III) (abbreviation: [Ir(ppy)₃]), bis(2-phenylpyridinato-N,C^{2′})iridium(III) acetylacetonate (abbreviation: [Ir(ppy)₂(acac)]), bis(benzo[h]quinolinato)iridium(III) acetylacetonate (abbreviation: [Ir(bzq)₂(acac)]), tris(benzo[h]quinolinato)iridium(III) (abbreviation: [Ir(bzq)₃]), tris(2-phenylquinolinato-N,C^{2′})iridium(III) (abbreviation: [Ir(pq)₃]), bis(2-phenylquinolinato-N,C^{2′})iridium(III) acetylacetonate (abbreviation: [Ir(pq)₂(acac)]), [2-d₃-methyl-8-(2-pyridinyl-κN)benzofuro[2,3-b]pyridine-κC]bis[2-(5-d₃-methyl-2-pyridinyl-N2)phenyl-κC]iridium(III) (abbreviation: Ir(5mppy-d₃)₂(mbfpypy-d₃)), (2-(methyl-d₃)-8-[4-(1-methylethyl-1-d)-2-pyridinyl-κN]benzofuro[2,3-b]pyridin-7-yl-κC)bis{5-(methyl-d₃)-2-[5-(methyl-d₃)-2-pyridinyl-κN]phenyl-κC}iridium(III) (abbreviation: Ir(5mtpy-d₆)₂(mbfpypy-iPr-d₄)), [2-d₃-methyl-(2-pyridinyl-κN)benzofuro[2,3-b]pyridine-κCbis[2-(2-pyridinyl-κN)phenyl-κC]iridium(III) (abbreviation: Ir(ppy)₂(mbfpypy-d₃)), or [2-(4-methyl-5-phenyl-2-pyridinyl-κN)phenyl-κC]bis[2-(2-pyridinyl-κN)phenyl-κC]iridium(III) (abbreviation: Ir(ppy)₂(mdppy)); and a rare earth metal complex such as tris(acetylacetonato)(monophenanthroline)terbium(III) (abbreviation: [Tb(acac)₃(Phen)]). These are mainly compounds that exhibit green phosphorescent light and have an emission peak in the wavelength range of 500 nm to 600 nm. Note that organometallic iridium complexes having a pyrimidine skeleton have distinctively high reliability or emission efficiency and thus are particularly preferable.

Other examples include an organometallic iridium complex having a pyrimidine skeleton, such as (diisobutyrylmethanato)bis[4,6-bis(3-methylphenyl)pyrimidinato]iridium(III) (abbreviation: [Ir(5mdppm)₂(dibm)]), bis[4,6-bis(3-methylphenyl)pyrimidinato](dipivaloylmethanato)iridium(III) (abbreviation: [Ir(5mdppm)₂(dpm)]), or bis[4,6-di(naphthalen-1-yl)pyrimidinato](dipivaloylmethanato)iridium(III) (abbreviation: [Ir(d1npm)₂(dpm)]); an organometallic iridium complex having a pyrazine skeleton, such as (acetylacetonato)bis(2,3,5-triphenylpyrazinato)iridium(III) (abbreviation: [Ir(tppr)₂(acac)]), bis(2,3,5-triphenylpyrazinato)(dipivaloylmethanato)iridium(III) (abbreviation: [Ir(tppr)₂(dpm)]), or (acetylacetonato)bis[2,3-bis(4-fluorophenyl)quinoxalinato]iridium(III) (abbreviation: [Ir(Fdpq)₂(acac)]); an organometallic iridium complex having a pyridine skeleton, such as tris(1-phenylisoquinolinato-N,C^{2′})iridium(III) (abbreviation: [Ir(piq)₃]) or bis(1-phenylisoquinolinato-N,C^{2′})iridium(III) acetylacetonate (abbreviation: [Ir(piq)₂(acac)]); a platinum complex such as 2,3,7,8,12,13,17,18-octaethyl-21H,23H-porphyrinplatinum(II) (abbreviation: PtOEP); and a rare earth metal complex such as tris(1,3-diphenyl-1,3-propanedionato)(monophenanthroline)europium(III) (abbreviation: [Eu(DBM)₃(Phen)]) or tris[1-(2-thenoyl)-3,3,3-trifluoroacetonato](monophenanthroline)europium(III) (abbreviation: [Eu(TTA)₃(Phen)]). These compounds exhibit red phosphorescent light and have an emission peak in the wavelength range of 600 nm to 700 nm. Organometallic iridium complexes having a pyrazine skeleton can provide red light emission with favorable chromaticity.

Besides the above phosphorescent compounds, known phosphorescent compounds may be selected and used.

Examples of the TADF material include a fullerene, a derivative thereof, an acridine, a derivative thereof, and an eosin derivative. Furthermore, a metal-containing porphyrin, such as a porphyrin containing magnesium (Mg), zinc (Zn), cadmium (Cd), tin (Sn), platinum (Pt), indium (In), or palladium (Pd), can be given as an example. Examples of the metal-containing porphyrin include a protoporphyrin-tin fluoride complex (SnF₂(Proto IX)), a mesoporphyrin-tin fluoride complex (SnF₂(Meso IX)), a hematoporphyrin-tin fluoride complex (SnF₂(Hemato IX)), a coproporphyrin tetramethyl ester-tin fluoride complex (SnF₂(Copro III-4Me)), an octaethylporphyrin-tin fluoride complex (SnF₂(OEP)), an etioporphyrin-tin fluoride complex (SnF₂(Etio I)), and an octaethylporphyrin-platinum chloride complex (PtCl₂OEP), which are represented by the following structural formulae.

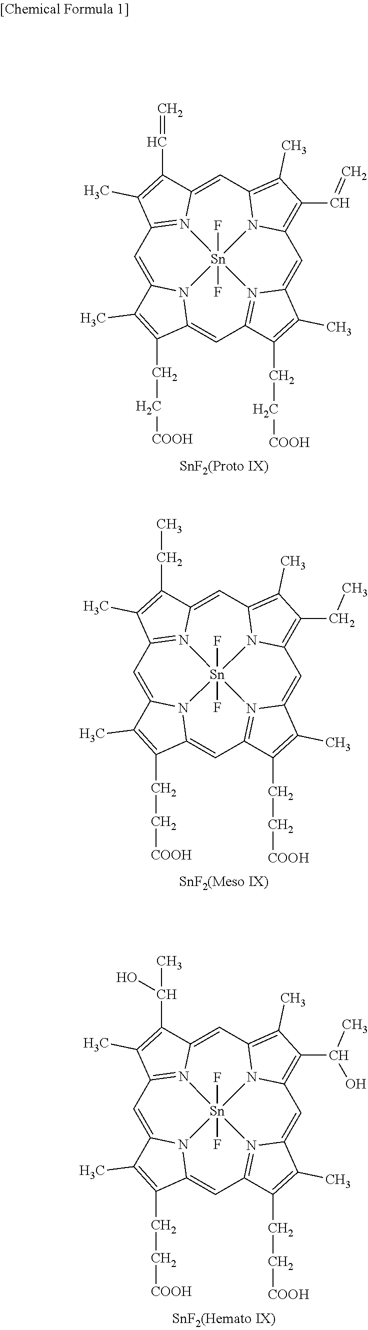

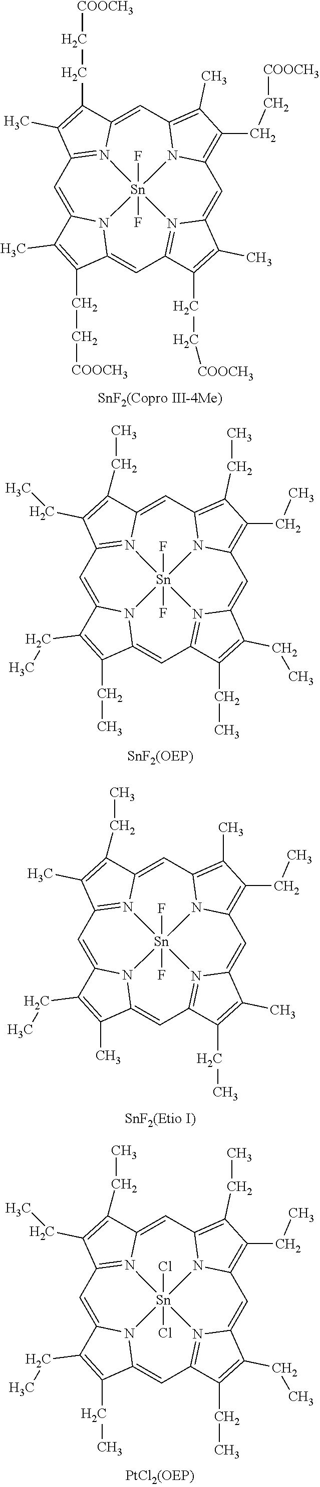

Alternatively, a heterocyclic compound having one or both of a π-electron rich heteroaromatic ring and a π-electron deficient heteroaromatic ring that is represented by the following structural formulae, such as 2-(biphenyl-4-yl)-4,6-bis(12-phenylindolo[2,3-a]carbazol-11-yl)-1,3,5-triazine (abbreviation: PIC-TRZ), 9-(4,6-diphenyl-1,3,5-triazin-2-yl)-9′-phenyl-9H,9′H-3,3′-bicarbazole (abbreviation: PCCzTzn), 2-{4-[3-(N-phenyl-9H-carbazol-3-yl)-9H-carbazol-9-yl]phenyl}-4,6-diphenyl-1,3,5-triazine (abbreviation: PCCzPTzn), 2-[4-(10H-phenoxazin-10-yl)phenyl]-4,6-diphenyl-1,3,5-triazine (abbreviation: PXZ-TRZ), 3-[4-(5-phenyl-5,10-dihydrophenazin-10-yl)phenyl]-4,54dphenyl-1,2,4-triazole (abbreviation: PPZ-3TPT), 3-(9,9-dimethyl-9H-acridin-10-yl)-9H-xanthen-9-one (abbreviation: ACRXTN), bis[4-(9,9-dimethyl-9,10-dihydroacridine)phenyl]sulfone (abbreviation: DMAC-DPS), or 10-phenyl-10H,10′H-spiro[acridin-9,9′-anthracen]-10′-one (abbreviation: ACRSA) can be used. Such a heterocyclic compound is preferable because of having excellent electron-transport and hole-transport properties owing to a π-electron rich heteroaromatic ring and a π-electron deficient heteroaromatic ring. Among skeletons having the π-electron deficient heteroaromatic ring, a pyridine skeleton, a diazine skeleton (a pyrimidine skeleton, a pyrazine skeleton, and a pyridazine skeleton), and a triazine skeleton are preferable because of their high stability and reliability. In particular, a benzofuropyrimidine skeleton, a benzothienopyrimidine skeleton, a benzofuropyrazine skeleton, and a benzothienopyrazine skeleton are preferable because of their high acceptor properties and high reliability. Among skeletons having the π-electron rich heteroaromatic ring, an acridine skeleton, a phenoxazine skeleton, a phenothiazine skeleton, a furan skeleton, a thiophene skeleton, and a pyrrole skeleton have high stability and reliability; thus, at least one of these skeletons is preferably included. A dibenzofuran skeleton is preferable as a furan skeleton, and a dibenzothiophene skeleton is preferable as a thiophene skeleton. As a pyrrole skeleton, an indole skeleton, a carbazole skeleton, an indolocarbazole skeleton, a bicarbazole skeleton, and a 3-(9-phenyl-9H-carbazol-3-yl)-9H-carbazole skeleton are particularly preferable. Note that a substance in which the π-electron rich heteroaromatic ring is directly bonded to the π-electron deficient heteroaromatic ring is particularly preferable because the electron-donating property of the π-electron rich heteroaromatic ring and the electron-accepting property of the π-electron deficient heteroaromatic ring are both improved, the energy difference between the S1 level and the T1 level becomes small, and thus thermally activated delayed fluorescence can be obtained with high efficiency. Note that an aromatic ring to which an electron-withdrawing group such as a cyano group is bonded may be used instead of the π-electron deficient heteroaromatic ring. As a π-electron rich skeleton, an aromatic amine skeleton, a phenazine skeleton, or the like can be used. As a π-electron deficient skeleton, a xanthene skeleton, a thioxanthene dioxide skeleton, an oxadiazole skeleton, a triazole skeleton, an imidazole skeleton, an anthraquinone skeleton, a skeleton containing boron such as phenylborane or boranthrene, an aromatic ring having a cyano group or a nitrile group such as benzonitrile or cyanobenzene, a heteroaromatic ring, a carbonyl skeleton such as benzophenone, a phosphine oxide skeleton, a sulfone skeleton, or the like can be used. As described above, a π-electron deficient skeleton and a π-electron rich skeleton can be used instead of at least one of the π-electron deficient heteroaromatic ring and the π-electron rich heteroaromatic ring.

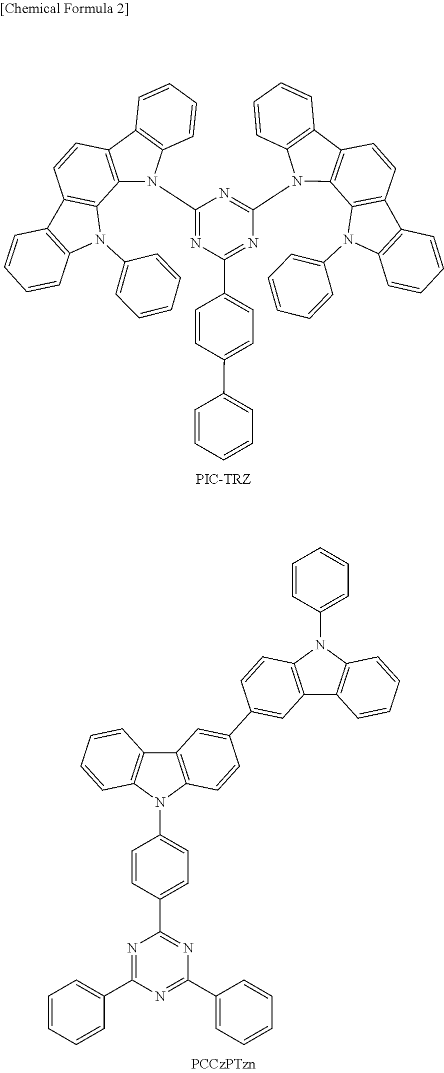 [SMILES: c1ccc(-c2ccc(-c3nc(-n4c5ccccc5c5ccc6c7ccccc7n(-c7ccccc7)c6c54)nc(-n4c5ccccc5c5ccc6c7ccccc7n(-c7ccccc7)c6c54)n3)cc2)cc1 ; c1ccc(-c2nc(-c3ccccc3)nc(-c3ccc(-n4c5ccccc5c5cc(-c6ccc7c(c6)c6ccccc6n7-c6ccccc6)ccc54)cc3)n2)cc1]

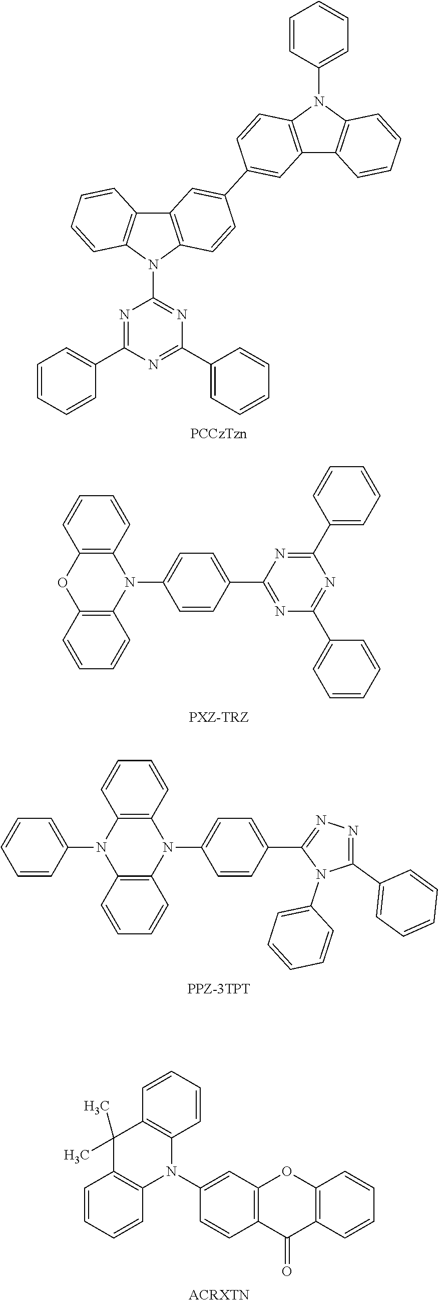 [SMILES: c1ccc(-c2nc(-c3ccccc3)nc(-n3c4ccccc4c4cc(-c5ccc6c(c5)c5ccccc5n6-c5ccccc5)ccc43)n2)cc1 ; c1ccc(-c2nc(-c3ccccc3)nc(-c3ccc(N4c5ccccc5Oc5ccccc54)cc3)n2)cc1 ; c1ccc(-c2nnc(-c3ccc(N4c5ccccc5N(c5ccccc5)c5ccccc54)cc3)n2-c2ccccc2)cc1 ; CC1(C)c2ccccc2N(c2ccc3c(=O)c4ccccc4oc3c2)c2ccccc21]

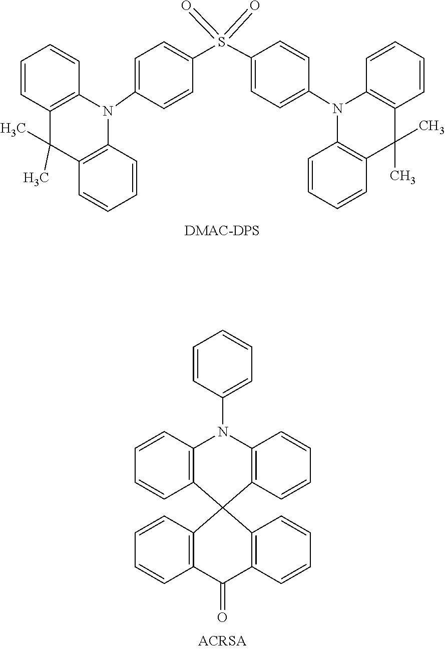 [SMILES: CC1(C)c2ccccc2N(c2ccc(S(=O)(=O)c3ccc(N4c5ccccc5C(C)(C)c5ccccc54)cc3)cc2)c2ccccc21 ; O=C1c2ccccc2C2(c3ccccc31)c1ccccc1N(c1ccccc1)c1ccccc12]

As the TADF material, a TADF material whose singlet excited state and triplet excited state are in a thermal equilibrium state may be used. Such a TADF material has a short emission lifetime (excitation lifetime), which allows inhibiting a decrease in efficiency in a high-luminance region of a light-emitting device. Specifically, a material having the following molecular structure can be used.

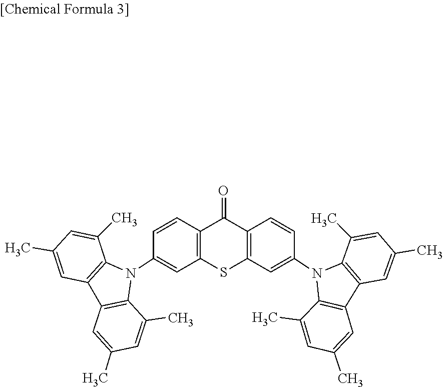

Note that a TADF material is a material having a small difference between the S1 level and the T1 level and a function of converting triplet excitation energy into singlet excitation energy by reverse intersystem crossing. Thus, it is possible to upconvert triplet excitation energy into singlet excitation energy (i.e., reverse intersystem crossing) using a small amount of thermal energy and efficiently generate a singlet excited state. In addition, the triplet excitation energy can be converted into light emission.

An exciplex whose excited state is formed of two kinds of substances has an extremely small difference between the S1 level and the T1 level and functions as a TADF material capable of converting triplet excitation energy into singlet excitation energy.

A phosphorescent spectrum observed at a low temperature (e.g., 77 K to 10 K) is used for an index of the T1 level. When the level of energy with a wavelength of the line obtained by extrapolating a tangent to the fluorescent spectrum at a tail on the short wavelength side is the S1 level and the level of energy with a wavelength of the line obtained by extrapolating a tangent to the phosphorescent spectrum at a tail on the short wavelength side is the T1 level, the difference between the S1 level and the T1 level of the TADF material is preferably smaller than or equal to 0.3 eV, further preferably smaller than or equal to 0.2 eV.

When a TADF material is used as the light-emitting substance, the S1 level of the host material is preferably higher than the S1 level of the TADF material. In addition, the T1 level of the host material is preferably higher than the T1 level of the TADF material.

As the host material in the light-emitting layer, various carrier-transport materials such as materials having an electron-transport property and/or materials having a hole-transport property, and the TADF materials can be used.

As the material having a hole-transport property, the above materials given as the material having a hole-transport property can be similarly used.

As the material having an electron-transport property, the above materials given as the material having an electron-transport property can be similarly used.

As the TADF material that can be used as the host material, the above materials mentioned as the TADF material can also be used. When the TADF material is used as the host material, triplet excitation energy generated in the TADF material is converted into singlet excitation energy by reverse intersystem crossing and transferred to the light-emitting substance, whereby the emission efficiency of the light-emitting device can be increased. Here, the TADF material functions as an energy donor, and the light-emitting substance functions as an energy acceptor.

This is very effective in the case where the light-emitting substance is a fluorescent substance. In that case, the S1 level of the TADF material is preferably higher than the S1 level of the fluorescent substance in order that high emission efficiency can be achieved. Furthermore, the T1 level of the TADF material is preferably higher than the S1 level of the fluorescent substance. Therefore, the T1 level of the TADF material is preferably higher than the T1 level of the fluorescent substance.

It is also preferable to use a TADF material that emits light whose wavelength overlaps with the wavelength on a lowest-energy-side absorption band of the fluorescent substance. This case is preferable because excitation energy is transferred smoothly from the TADF material to the fluorescent substance and light emission can be obtained efficiently.

In addition, in order to efficiently generate singlet excitation energy from the triplet excitation energy by reverse intersystem crossing, carrier recombination preferably occurs in the TADF material. It is also preferable that the triplet excitation energy generated in the TADF material not be transferred to the triplet excitation energy of the fluorescent substance. For that reason, the fluorescent substance preferably has a protective group around a luminophore (a skeleton which causes light emission) of the fluorescent substance. As the protective group, a substituent having no a bond and a saturated hydrocarbon are preferably used. Specific examples include an alkyl group having 3 to 10 carbon atoms, a substituted or unsubstituted cycloalkyl group having 3 to 10 carbon atoms, and a trialkylsilyl group having 3 to 10 carbon atoms. It is further preferable that the fluorescent substance have a plurality of protective groups. The substituents having no a bond are poor in carrier transport performance, so that the TADF material and the luminophore of the fluorescent substance can be made away from each other with little influence on carrier transportation or carrier recombination. Here, the luminophore refers to an atomic group (skeleton) that causes light emission in a fluorescent substance. The luminophore is preferably a skeleton having a π bond, further preferably includes an aromatic ring, and still further preferably includes a condensed aromatic ring or a condensed heteroaromatic ring. Examples of the condensed aromatic ring or the condensed heteroaromatic ring include a phenanthrene skeleton, a stilbene skeleton, an acridone skeleton, a phenoxazine skeleton, and a phenothiazine skeleton. Specifically, a fluorescent substance having any of a naphthalene skeleton, an anthracene skeleton, a fluorene skeleton, a chrysene skeleton, a triphenylene skeleton, a tetracene skeleton, a pyrene skeleton, a perylene skeleton, a coumarin skeleton, a quinacridone skeleton, and a naphthobisbenzofuran skeleton is preferable because of its high fluorescence quantum yield.

In the case where a fluorescent substance is used as the light-emitting substance, a material having an anthracene skeleton is suitably used as the host material. The use of a substance having an anthracene skeleton as the host material for the fluorescent substance makes it possible to obtain a light-emitting layer with high emission efficiency and high durability. As the substance having an anthracene skeleton that is used as the host material, a substance having a diphenylanthracene skeleton, in particular, a substance having a 9,10-diphenylanthracene skeleton, is chemically stable and thus is preferably used. The host material preferably has a carbazole skeleton because the hole-injection and hole-transport properties are improved; further preferably, the host material has a benzocarbazole skeleton in which a benzene ring is further condensed to carbazole because the HOMO level thereof is shallower than that of carbazole by approximately 0.1 eV and thus holes enter the host material easily. In particular, the host material preferably has a dibenzocarbazole skeleton because the HOMO level thereof is shallower than that of carbazole by approximately 0.1 eV so that holes enter the host material easily, the hole-transport property is improved, and the heat resistance is increased. Accordingly, a substance that has both a 9,10-diphenylanthracene skeleton and a carbazole skeleton (or a benzocarbazole skeleton or a dibenzocarbazole skeleton) is further preferable as the host material. Note that in terms of the hole-injection and hole-transport properties described above, instead of a carbazole skeleton, a benzofluorene skeleton or a dibenzofluorene skeleton may be used. Examples of such a substance include 9-phenyl-3-[4-(10-phenyl-9-anthryl)phenyl]-9H-carbazole (abbreviation: PCzPA), 3-[4-(1-naphthyl)-phenyl]-9-phenyl-9H-carbazole (abbreviation: PCPN), 9-[4-(10-phenyl-9-anthracenyl)phenyl]-9H-carbazole (abbreviation: CzPA), 7-[4-(10-phenyl-9-anthryl)phenyl]-7H-dibenzo[c,g]carbazole (abbreviation: cgDBCzPA), 6-[3-(9,10-diphenyl-2-anthryl)phenyl]-benzo[b]naphtho[1,2-d]furan (abbreviation: 2mBnfPPA), 9-phenyl-10-[4′-(9-phenyl-9H-fluoren-9-yl)biphenyl-4-yl]anthracene (abbreviation: FLPPA), 9-(1-naphthyl)-10-[4-(2-naphthyl)phenyl]anthracene (abbreviation: αN-βNPAnth), 9-(1-naphthyl)-10-(2-naphthyl)anthracene (abbreviation: α,βADN), 2-(10-phenylanthracen-9-yl)dibenzofuran, 2-(10-phenyl-9-anthracenyl)benzo[b]naphtho[2,3-d]furan (abbreviation: Bnf(II)PhA), 9-(2-naphthyl)-10-[3-(2-naphthyl)phenyl]anthracene (abbreviation: βN-mβNPAnth), and 1-[4-(10-(biphenyl-4-yl)-9-anthracenyl)phenyl]-2-ethyl-1H-benzimidazole (abbreviation: EtBImPBPhA). In particular, CzPA, cgDBCzPA, 2mBnfPPA, and PCzPA exhibit excellent properties and thus are preferably selected.

The host material may be a mixture of a plurality of kinds of substances; in the case of using a mixed host material, it is preferable to mix a material having an electron-transport property with a material having a hole-transport property. By mixing the material having an electron-transport property with the material having a hole-transport property, the transport property of the light-emitting layer 113 can be easily adjusted and a recombination region can be easily controlled. The weight ratio of the content of the material having a hole-transport property to the content of the material having an electron-transport property may be 1:19 to 19:1.

Note that a phosphorescent substance can be used as part of the mixed material. When a fluorescent substance is used as the light-emitting substance, a phosphorescent substance can be used as an energy donor for supplying excitation energy to the fluorescent substance.

An exciplex may be formed of these mixed materials. These mixed materials are preferably selected so as to form an exciplex that exhibits light emission overlapping with the wavelength of a lowest-energy-side absorption band of the light-emitting substance, in which case energy can be transferred smoothly and light emission can be obtained efficiently. The use of such a structure is preferable because the driving voltage can also be reduced.

At least one of the materials forming an exciplex may be a phosphorescent substance. In this case, triplet excitation energy can be efficiently converted into singlet excitation energy by reverse intersystem crossing.

Combination of a material having an electron-transport property and a material having a hole-transport property whose HOMO level is higher than or equal to that of the material having an electron-transport property is preferable for forming an exciplex efficiently. In addition, the LUMO level of the material having a hole-transport property is preferably higher than or equal to the LUMO level of the material having an electron-transport property. Note that the LUMO levels and the HOMO levels of the materials can be derived from the electrochemical characteristics (the reduction potentials and the oxidation potentials) of the materials that are measured by cyclic voltammetry (CV).

The formation of an exciplex can be confirmed by a phenomenon in which the emission spectrum of a mixed film in which the material having a hole-transport property and the material having an electron-transport property are mixed is shifted to a longer wavelength than the emission spectrum of each of the materials (or has another peak on the longer wavelength side) observed in comparison of the emission spectrum of the material having a hole-transport property, the emission spectrum of the material having an electron-transport property, and the emission spectrum of the mixed film of these materials, for example. Alternatively, the formation of an exciplex can be confirmed by a difference in transient response, such as a phenomenon in which the transient photoluminescence (PL) lifetime of the mixed film has longer lifetime components or has a larger proportion of delayed components than the transient PL of each of the materials, observed in comparison of the transient PL of the material having a hole-transport property, the transient PL of the material having an electron-transport property, and the transient PL of the mixed film of these materials. The transient PL can be rephrased as transient electroluminescence (EL). That is, the formation of an exciplex can also be confirmed by a difference in transient response observed in comparison of the transient EL of the material having a hole-transport property, the transient EL of the material having an electron-transport property, and the transient EL of the mixed film of these materials.

The electron-transport layer (the first electron-transport layer 114_1 and the second electron-transport layer 114_2) contains a substance having an electron-transport property. The material having an electron-transport property is preferably a substance having an electron mobility higher than or equal to 1×10⁻⁷ cm²/Vs, further preferably higher than or equal to 1×10⁻⁶ cm²/Vs in the case where the square root of the electric field strength [V/cm] is 600. Note that any other substance can also be used as long as the substance has an electron-transport property higher than a hole-transport property. An organic compound having a π-electron deficient heteroaromatic ring is preferable as the above organic compound. The organic compound having a π-electron deficient heteroaromatic ring is preferably one or more of an organic compound having a heteroaromatic ring having a polyazole skeleton, an organic compound having a heteroaromatic ring having a pyridine skeleton, an organic compound having a heteroaromatic ring having a diazine skeleton, and an organic compound having a heteroaromatic ring having a triazine skeleton.

As the organic compound having an electron-transport property that can be used in the electron-transport layer, the organic compound that can be used as the organic compound having an electron-transport property in the N-type layer in the intermediate layer 116 can be similarly used. Among the above materials, the organic compound having a heteroaromatic ring having a diazine skeleton, the organic compound having a heteroaromatic ring having a pyridine skeleton, and the organic compound having a heteroaromatic ring having a triazine skeleton have high reliability and thus are preferable. In particular, the organic compound having a heteroaromatic ring having a diazine (pyrimidine or pyrazine) skeleton and the organic compound having a heteroaromatic ring having a triazine skeleton have a high electron-transport property to contribute to a reduction in driving voltage.

The electron mobility of the electron-transport layer in the case where the square root of the electric field strength [V/cm] is 600 is preferably higher than or equal to 1×10⁻⁷ cm²/Vs and lower than or equal to 5×10⁻⁵ cm²/Vs. The amount of electrons injected into the light-emitting layer can be controlled by the reduction in the electron-transport property of the electron-transport layer, whereby the light-emitting layer can be prevented from having excess electrons. It is particularly preferable to employ this structure when the hole-injection layer is formed using a composite material that includes a material having a hole-transport property with a relatively deep HOMO level higher than or equal to −5.7 eV and lower than or equal to −5.4 eV, in which case a long lifetime can be achieved. In this case, the material having an electron-transport property preferably has a HOMO level higher than or equal to −6.0 eV.

A layer containing an alkali metal, an alkaline earth metal, a rare earth metal complex, a compound thereof, or a complex thereof such as lithium fluoride (LiF), cesium fluoride (CsF), calcium fluoride (CaF₂), 8-quinolinolato-lithium (abbreviation: Liq), or ytterbium (Yb) may be provided as the electron-injection layer 115. An electride or a layer that is formed using a substance having an electron-transport property and that contains an alkali metal, an alkaline earth metal, or a compound thereof may be used as the electron-injection layer 115. Examples of the electride include a substance in which electrons are added at high concentration to calcium oxide-aluminum oxide.

Note that as the electron-injection layer 115, it is possible to use a layer containing a substance that has an electron-transport property (preferably an organic compound having a bipyridine skeleton) and includes a fluoride of the alkali metal or the alkaline earth metal at a concentration higher than or equal to that at which the electron-injection layer 115 becomes in a microcrystalline state (50 wt % or higher). Since the layer has a low refractive index, a light-emitting device having higher external quantum efficiency can be provided.

The second electrode 102 includes a cathode. The second electrode 102 may have a stacked-layer structure where the layer in contact with the organic compound layer 103 functions as the cathode. As a substance of the cathode, any of metals, alloys, and electrically conductive compounds with a low work function (specifically, lower than or equal to 3.8 eV), mixtures thereof, and the like can be used. Specific examples of such a cathode material include elements belonging to Group 1 or 2 of the periodic table, such as alkali metals (e.g., lithium (Li) and cesium (Cs)), magnesium (Mg), calcium (Ca), and strontium (Sr), alloys containing these elements (e.g., MgAg and AlLi), rare earth metals such as europium (Eu) and ytterbium (Yb), and alloys containing these rare earth metals. However, when the electron-injection layer is provided between the second electrode 102 and the electron-transport layer, a variety of conductive materials such as Al, Ag, ITO, and indium oxide-tin oxide containing silicon or silicon oxide can be used for the cathode regardless of the work function.

When the second electrode 102 is formed using a material that transmits visible light, the light-emitting device can emit light from the second electrode 102 side.

Films of these conductive materials can be formed by a dry process such as a vacuum evaporation method or a sputtering method, an ink-jet method, a spin coating method, or the like. Alternatively, a wet process using a sol-gel method or a wet process using a paste of a metal material may be employed.

Any of a variety of methods can be used for forming the organic compound layer 103, regardless of whether it is a dry process or a wet process. For example, a vacuum evaporation method, a gravure printing method, an offset printing method, a screen printing method, an ink-jet method, a spin coating method, or the like may be used.

Different film formation methods may be used to form the electrodes or the layers described above.

This embodiment can be combined with the other embodiments or an example as appropriate. In this specification, in the case where a plurality of structure examples are described in one embodiment, the structure examples can be combined as appropriate.

### Embodiment 3

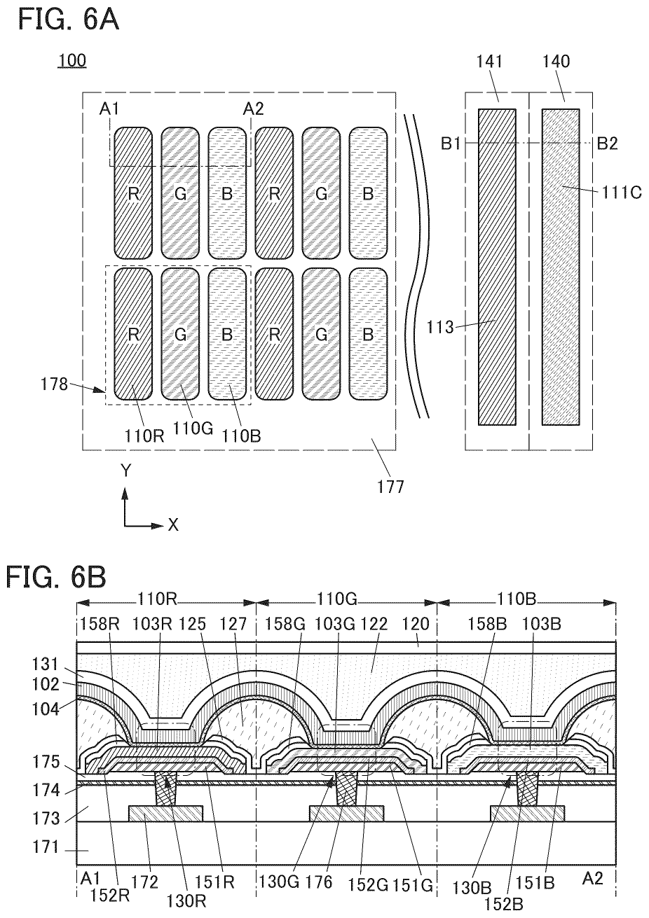

As illustrated as an example in FIG. 6A and FIG. 6B, a plurality of light-emitting devices 130 are formed over an insulating layer 175 to constitute a display device. In this embodiment, display devices of embodiments of the present invention are described in detail.

A display device 100 includes a pixel portion 177 in which a plurality of pixels 178 are arranged in a matrix. The pixel 178 includes a subpixel 110R, a subpixel 110G, and a subpixel 110B.

In this specification and the like, for example, matters common to the subpixel 110R, the subpixel 110G, and the subpixel 110B are sometimes described using the collective term “subpixel 110”. In the same manner, in the description common to other components that are distinguished by alphabets, reference numerals without alphabets are sometimes used.

The subpixel 110R emits red light, the subpixel 110G emits green light, and the subpixel 110B emits blue light. Accordingly, an image can be displayed on the pixel portion 177. Note that in this embodiment, subpixels of three colors of red (R), green (G), and blue (B) are given as examples; however, subpixels of a different combination of colors may be employed. The number of subpixels is not limited to three, and four or more of subpixels may be used. Examples of four subpixels include subpixels of four colors of R, G, B, and white (W), subpixels of four colors of R, G, B, and Y, and four subpixels of R, G, B, and infrared light (IR).

In this specification and the like, the row direction is referred to as X direction and the column direction is referred to as Y direction in some cases. The X direction and the Y direction intersect with each other and are perpendicular to each other, for example.

FIG. 6A illustrates an example where subpixels of different colors are arranged in the X direction and subpixels of the same color are arranged in the Y direction. Note that subpixels of different colors may be arranged in the Y direction, and subpixels of the same color may be arranged in the X direction.

Outside the pixel portion 177, a connection portion 140 and a region 141 may also be provided. The region 141 is provided between the pixel portion 177 and the connection portion 140. The organic compound layer 103 is provided in the region 141. A conductive layer 151C is provided in the connection portion 140.

Although FIG. 6A illustrates an example where the connection portion 140 and the region 141 are positioned on the right side of the pixel portion 177, there is no particular limitation on the position of the connection portion 140 and the region 141. In addition, the number of each of the connection portions 140 and the regions 141 can be one or more.

FIG. 6B is an example of a cross-sectional view taken along a dashed-dotted line A1-A2 in FIG. 6A. As illustrated in FIG. 6B, the display device 100 includes an insulating layer 171, a conductive layer 172 over the insulating layer 171, an insulating layer 173 over the insulating layer 171 and the conductive layer 172, an insulating layer 174 over the insulating layer 173, and the insulating layer 175 over the insulating layer 174. The insulating layer 171 is provided over a substrate (not illustrated). An opening reaching the conductive layer 172 is provided in the insulating layer 175, the insulating layer 174, and the insulating layer 173, and a plug 176 is provided so as to fill the opening.

In the pixel portion 177, the light-emitting device 130 is provided over the insulating layer 175 and the plug 176. A protective layer 131 is provided to cover the light-emitting device 130. A substrate 120 is attached to the protective layer 131 with a resin layer 122. In a region between adjacent light-emitting device 130, an inorganic insulating layer 125 and an insulating layer 127 over the inorganic insulating layer 125 are preferably provided.

Although FIG. 6B illustrates a plurality of cross sections of the inorganic insulating layer 125 and the insulating layer 127, it is preferable that the inorganic insulating layer 125 and the insulating layer 127 be each a continuous layer when the display device 100 is seen from above. In other words, the insulating layer 127 preferably has an opening over a first electrode.

In FIG. 6B, a light-emitting device 130R, a light-emitting device 130G, and a light-emitting device 130B are shown as the light-emitting device 130. The light-emitting device 130R, the light-emitting device 130G, and the light-emitting device 130B emit light of different colors. For example, the light-emitting device 130R can emit red light, the light-emitting device 130G can emit green light, and the light-emitting device 130B can emit blue light. The light-emitting device 130R, the light-emitting device 130G, or the light-emitting device 130B may emit visible light of another color or infrared light.

The display device of one embodiment of the present invention is a top-emission display device where light is emitted in the direction opposite to a substrate over which the light-emitting devices are formed. Note that the display device of one embodiment of the present invention may be of a bottom-emission type.

Examples of a light-emitting substance contained in the light-emitting device 130 include organic compounds or organometallic complexes such as a substance exhibiting fluorescence (a fluorescent material), a substance exhibiting phosphorescence (a phosphorescent material), and a substance exhibiting thermally activated delayed fluorescence (a TADF material). Other examples include inorganic compounds (e.g., a quantum dot material).

The light-emitting device 130R has a structure as described in Embodiment 1. The light-emitting device 130R includes the first electrode (pixel electrode) including a conductive layer 151R and a conductive layer 152R, an organic compound layer 103R over the first electrode, the common layer 104 over the organic compound layer 103R, and the second electrode (common electrode) 102 over the common layer 104. Although the common layer 104 is not necessarily provided, it is preferable to provide the common layer 104 to reduce damage to the organic compound layer 103R during processing. In the case where the common layer 104 is provided, the common layer 104 is preferably an electron-injection layer. Furthermore, in the case where the common layer 104 is provided, a stack of the organic compound layer 103R and the common layer 104 corresponds to the organic compound layer 103 described in Embodiment 1.

The light-emitting device 130G has a structure as described in Embodiment 1. The light-emitting device 130G includes the first electrode (pixel electrode) including a conductive layer 151G and a conductive layer 152G, an organic compound layer 103G over the first electrode, the common layer 104 over the organic compound layer 103G, and the second electrode (common electrode) 102 over the common layer. Although the common layer 104 is not necessarily provided, it is preferable to provide the common layer 104 to reduce damage to the organic compound layer 103G during processing. In the case where the common layer 104 is provided, the common layer 104 is preferably an electron-injection layer. Furthermore, in the case where the common layer 104 is provided, a stack of the organic compound layer 103G and the common layer 104 corresponds to the organic compound layer 103 described in Embodiment 1.

The light-emitting device 130B has a structure as described in Embodiment 1. The light-emitting device 130B includes the first electrode (pixel electrode) including a conductive layer 151B and a conductive layer 152B, an organic compound layer 103B over the first electrode, the common layer 104 over the organic compound layer 103B, and the second electrode (common electrode) 102 over the common layer 104. Although the common layer 104 is not necessarily provided, it is preferable to provide the common layer 104 to reduce damage to the organic compound layer 103B during processing. In the case where the common layer 104 is provided, the common layer 104 is preferably an electron-injection layer. Furthermore, in the case where the common layer 104 is provided, a stack of the organic compound layer 103B and the common layer 104 corresponds to the organic compound layer 103 described in Embodiment 1.

One of the pixel electrode and the common electrode of the light-emitting device functions as an anode, and the other thereof functions as a cathode. Hereinafter, description is made on the assumption that the pixel electrode functions as the anode and the common electrode functions as the cathode unless otherwise specified.

The organic compound layer 103R, the organic compound layer 103G, and the organic compound layer 103B are island-shaped layers that are separate from each other; alternatively, an organic compound layer of the light-emitting devices of one emission color may be separate from an organic compound layer of the display devices of another emission color. Providing the island-shaped organic compound layer 103 in each of the light-emitting devices 130 can inhibit leakage current between the adjacent light-emitting devices 130 even in a high-resolution display device. This can prevent crosstalk, so that the display device can achieve extremely high contrast. In particular, a display device having high current efficiency at low luminance can be achieved.

The island-shaped organic compound layer 103 is formed by forming an EL film and processing the EL film by a lithography method.

The organic compound layer 103 is preferably provided to cover the top surface and the side surface of the first electrode (pixel electrode) of the light-emitting device 130. Such a structure can easily increase the aperture ratio of the display device 100 as compared with the structure in which an end portion of the organic compound layer 103 is positioned inward from an end portion of the pixel electrode. Covering the side surface of the pixel electrode of the light-emitting device 130 with the organic compound layer 103 inhibits contact between the pixel electrode and the second electrode 102, thereby inhibiting a short circuit in the light-emitting device 130. Furthermore, the distance between the light-emitting region (i.e., the region overlapping with the pixel electrode) in the organic compound layer 103 and the end portion of the organic compound layer 103 can be increased. Since the end portion of the organic compound layer 103 might be damaged by processing, the use of a region away from the end portion of the organic compound layer 103 as the light-emitting region can improve the reliability of the light-emitting device 130.

In the display device of one embodiment of the present invention, the first electrode (pixel electrode) of the light-emitting device preferably has a stacked-layer structure. For example, in the example illustrated in FIG. 6B, the first electrode of the light-emitting device 130 is a stack of a conductive layer 151 and a conductive layer 152. In the case where the display device 100 has a top-emission structure and the pixel electrode of the light-emitting device 130 functions as an anode, for example, it is preferable that the conductive layer 151 have high visible light reflectance and the conductive layer 152 have visible-light-transmitting property and a high work function. In the case where the display device 100 is of a top-emission type, the higher the visible light reflectance of the pixel electrode is, the higher the efficiency of extraction of the light emitted by the organic compound layer 103 is. In the case where the pixel electrode functions as an anode, the higher the work function of the pixel electrode is, the easier it is to inject holes into the organic compound layer 103. Thus, when the pixel electrode of the light-emitting device 130 has a stacked-layer structure of the conductive layer 151 with high visible light reflectance and the conductive layer 152 with a high work function, the light-emitting device 130 can have high light extraction efficiency and a low driving voltage.

In the case where the conductive layer 151 has high visible light reflectance, the visible light reflectance of the conductive layer 151 is preferably higher than or equal to 40% and lower than or equal to 100%, further preferably higher than or equal to 70% and lower than or equal to 100%, for example. When the conductive layer 152 is used as an electrode having a visible-light-transmitting property, the visible light transmittance is preferably higher than or equal to 40%, for example.

Here, in the case of having a stacked-layer structure of a plurality of layers, the pixel electrode might change in quality as a result of a reaction occurring between the plurality of layers, for example. For example, when a film formed after the formation of the pixel electrode is removed by a wet etching method, contact of a chemical solution with the pixel electrode might cause galvanic corrosion.

In view of the above, the conductive layer 152 is formed to cover the top surface and the side surface of the conductive layer 151 in the display device 100 of this embodiment. This can inhibit the chemical solution from coming into contact with the conductive layer 151 even in the case where a film that is formed after formation of the pixel electrode including the conductive layer 151 and the conductive layer 152 is removed by a wet etching method, for example. Thus, generation of galvanic corrosion to the pixel electrode can be suppressed, for example. Thus, since the display device 100 can be manufactured by a method giving a high yield, an inexpensive display device can be provided. In addition, generation of a defect in the display device 100 can be inhibited, which makes the display device 100 highly reliable.

A metal material can be used for the conductive layer 151, for example. Specifically, it is possible to use a metal such as aluminum (Al), titanium (Ti), chromium (Cr), manganese (Mn), iron (Fe), cobalt (Co), nickel (Ni), copper (Cu), gallium (Ga), zinc (Zn), indium (In), tin (Sn), molybdenum (Mo), tantalum (Ta), tungsten (W), palladium (Pd), gold (Au), platinum (Pt), silver (Ag), yttrium (Y), or neodymium (Nd) and an alloy containing an appropriate combination of any of these metals, for example.

For the conductive layer 152, an oxide containing one or more selected from indium, tin, zinc, gallium, titanium, aluminum, and silicon can be used. For example, it is preferable to use a conductive oxide containing one or more of indium oxide, indium tin oxide, indium zinc oxide, zinc oxide, zinc oxide containing gallium, titanium oxide, indium zinc oxide containing gallium, indium zinc oxide containing aluminum, indium tin oxide containing silicon, indium zinc oxide containing silicon, and the like. In particular, indium tin oxide containing silicon can be suitably used for the conductive layer 152 because of having a high work function, for example, a work function higher than or equal to 4.0 eV.

The conductive layer 151 may have a stacked-layer structure of a plurality of layers containing different materials and the conductive layer 152 may have a stacked-layer structure of a plurality of layers containing different materials. In that case, the conductive layer 151 may include a layer formed using a material that can be used for the conductive layer 152, such as a conductive oxide. Furthermore, the conductive layer 152 may include a layer formed using a material that can be used for the conductive layer 151, such as a metal material. In the case where the conductive layer 151 has a stacked-layer structure of two or more layers, for example, a layer in contact with the conductive layer 152 can be formed using a material that can be used for the conductive layer 152.

The side surface of the conductive layer 151 preferably has a tapered shape. Specifically, the side surface of the conductive layer 151 preferably has a tapered shape with a taper angle less than 90°. In that case, the conductive layer 152 provided along the side surface of the conductive layer 151 also has a tapered shape. When the side surface of the conductive layer 152 has a tapered shape, coverage with the organic compound layer 103 provided along the side surface of the conductive layer 152 can be improved.

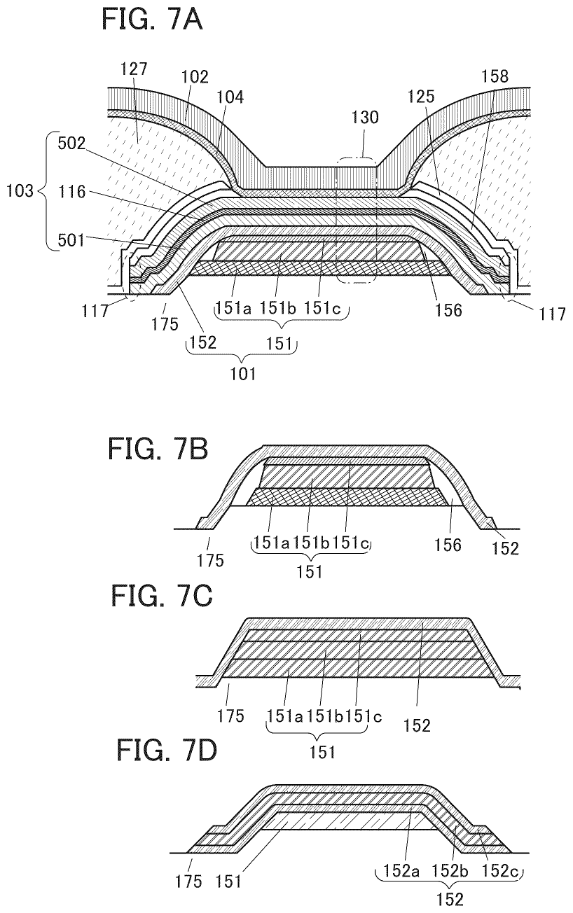

FIG. 7A illustrates the case where the conductive layer 151 has a stacked-layer structure of a plurality of layers containing different materials. As illustrated in FIG. 7A, the conductive layer 151 includes a conductive layer 151a, a conductive layer 151b over the conductive layer 151a, and a conductive layer 151c over the conductive layer 151b. In other words, the conductive layer 151 illustrated in FIG. 7A has a three-layer stacked structure. In the case where the conductive layer 151 has a stacked-layer structure of a plurality of layers as described above, the visible light reflectance of at least one of the layers included in the conductive layer 151 can be higher than that of the conductive layer 152.

In the example illustrated in FIG. 7A, the conductive layer 151b is interposed between the conductive layer 151a and the conductive layer 151c. A material that is less likely to change in quality than a material for the conductive layer 151b is preferably used for the conductive layer 151a and the conductive layer 151c. For example, a material that is less likely to cause migration due to contact with the insulating layer 175 than the material for the conductive layer 151b can be used for the conductive layer 151a. For the conductive layer 151c, a material that is less likely to be oxidized than the conductive layer 151b and that forms an oxide having lower electrical resistivity than an oxide of the material for the conductive layer 151b can be used.

In this manner, the structure in which the conductive layer 151b is interposed between the conductive layer 151a and the conductive layer 151c can expand the range of choices for the material for the conductive layer 151b. The conductive layer 151b, for example, can thus have higher visible light reflectance than at least one of the conductive layer 151a and the conductive layer 151c. For example, aluminum can be used for the conductive layer 151b. Note that an alloy containing aluminum may be used for the conductive layer 151b. For the conductive layer 151a, titanium, a material which has lower visible light reflectance than aluminum and is less likely to cause migration even at the time of contact with the insulating layer 175 than aluminum, can be used. For the conductive layer 151c, titanium, a material which has lower visible light reflectance than aluminum and is less likely to be oxidized than aluminum and whose oxide has lower electrical resistivity than aluminum oxide, can be used.

For the conductive layer 151c, silver or an alloy containing silver may be used. Silver is characterized by its visible light reflectance higher than that of titanium. In addition, silver is characterized by being less likely to be oxidized than aluminum, and silver oxide is characterized by having electrical resistivity lower than that of aluminum oxide. Thus, the use of silver or an alloy containing silver for the conductive layer 151c can suitably increase the visible light reflectance of the conductive layer 151 and inhibit an increase in the electrical resistance of the pixel electrode due to oxidation of the conductive layer 151b. Here, an alloy of silver, palladium, and copper (Ag—Pd—Cu, also referred to as APC) can be used as the alloy containing silver, for example. When the conductive layer 151c is formed using silver or an alloy containing silver and the conductive layer 151b is formed using aluminum, the visible light reflectance of the conductive layer 151c can be higher than that of the conductive layer 151b. Here, the conductive layer 151b may be formed using silver or an alloy containing silver. The conductive layer 151a may be formed using silver or an alloy containing silver.

Meanwhile, a film formed using titanium has better processability in etching than a film formed using silver. Thus, the use of titanium for the conductive layer 151c facilitates the formation of the conductive layer 151c. Note that a film formed using aluminum also has better processability in etching than a film formed using silver.

The conductive layer 151 having a stacked-layer structure of a plurality of layers as described above can improve the characteristics of the display device. For example, the display device 100 can have high light extraction efficiency and high reliability.

Here, in the case where the light-emitting device 130 has a microcavity structure, the use of silver or an alloy containing silver, which is a material having high visible light reflectance, for the conductive layer 151c can suitably increase the light extraction efficiency of the display device 100.

As already described above, the side surface of the conductive layer 151 preferably has a tapered shape. Specifically, the side surface of the conductive layer 151 preferably has a tapered shape with a taper angle less than 90°. For example, in the conductive layer 151 illustrated in FIG. 7A, the side surface of at least one of the conductive layer 151a, the conductive layer 151b, and the conductive layer 151c preferably has a tapered shape.

The conductive layer 151 illustrated in FIG. 7A can be formed by a photolithography method. Specifically, first, a conductive film to be the conductive layer 151a, a conductive film to be the conductive layer 151b, and a conductive film to be the conductive layer 151c are sequentially formed. Next, a resist mask is formed over the conductive film to be the conductive layer 151c. Then, the conductive film in the region not overlapping with the resist mask is removed by an etching method, for example. Here, the side surface of the conductive layer 151 can have a tapered shape by processing the conductive film under conditions where the resist mask is easily recessed (reduced in size) as compared to the case where the conductive layer 151 is formed such that the side surface does not have a tapered shape, i.e., a perpendicular side surface is formed.

Here, when the conductive film is processed under conditions where the resist mask is easily recessed (reduced in size), the conductive film might be easily processed in the horizontal direction. That is, the etching sometimes might become isotropic as compared to the case where the conductive layer 151 is formed to have a perpendicular side surface.

In the case where the conductive layer 151 is a stack of a plurality of layers formed of different materials, the plurality of layers sometimes differ in processability in the horizontal direction. For example, the conductive layer 151a, the conductive layer 151b, and the conductive layer 151c sometimes differ in processability in the horizontal direction.

In that case, after the processing of the conductive film, as illustrated in FIG. 7A, the side surface of the conductive layer 151b may be positioned inward from the side surfaces of the conductive layer 151a and the conductive layer 151c and a protruding portion may be formed. This might impair coverage of the conductive layer 151 with the conductive layer 152 to cause step disconnection in the conductive layer 152.

Thus, an insulating layer 156 is preferably provided as illustrated in FIG. 7A. FIG. 7A illustrates an example in which the insulating layer 156 is provided over the conductive layer 151a to include a region overlapping with the side surface of the conductive layer 151b. Such a structure can inhibit occurrence of step disconnection or a reduction in the thickness of the conductive layer 152 due to the protruding portion; thus, disconnection or an increase in driving voltage can be inhibited.

Although FIG. 7A illustrates the structure where the side surface of the conductive layer 151b is entirely covered with the insulating layer 156, part of the side surface of the conductive layer 151b is not necessarily covered with the insulating layer 156. Also in a pixel electrode with a later-described structure, part of the side surface of the conductive layer 151b is not necessarily covered with the insulating layer 156.

In the case where the conductive layer 151 has the structure illustrated in FIG. 7A, the conductive layer 152 is provided to cover the conductive layer 151a, the conductive layer 151b, and the conductive layer 151c and the insulating layer 156 and to be electrically connected to the conductive layer 151a, the conductive layer 151b, and the conductive layer 151c. This can prevent a chemical solution from coming into contact with the conductive layer 151a, the conductive layer 151b, and the conductive layer 151c when a film formed after formation of the conductive layer 152 is removed by a wet etching method, for example. It is thus possible to inhibit occurrence of corrosion in the conductive layer 151a, the conductive layer 151b, and the conductive layer 151c. As described above, the display device 100 can be manufactured by a high-yield method. In addition, generation of a defect can be inhibited, which makes the display device 100 highly reliable.

Here, the insulating layer 156 preferably has a curved surface as illustrated in FIG. 7A. In this case, step disconnection in the conductive layer 152 covering the insulating layer 156 is less likely to occur than those in the case where the insulating layer 156 has a perpendicular side surface (a side surface parallel to the Z direction), for example. In addition, step disconnection in the conductive layer 152 covering the insulating layer 156 is less likely to occur also in the case where the side surface of the insulating layer 156 has a tapered shape, specifically, a tapered shape with a taper angle less than 90°, than those in the case where the insulating layer 156 has a perpendicular side surface, for example. As described above, the display device 100 can be manufactured by a high-yield method. In addition, generation of a defect can be inhibited, which makes the display device 100 highly reliable.

FIG. 7A illustrates the structure where the side surface of the conductive layer 151b is positioned inward from that of the conductive layer 151a and that of the conductive layer 151c; however, one embodiment of the present invention is not limited thereto. For example, the side surface of the conductive layer 151b may be positioned outward from that of the conductive layer 151a. The side surface of the conductive layer 151b may be positioned outward from that of the conductive layer 151c.

FIG. 7B to FIG. 7D illustrate other structures of the first electrode 101. FIG. 7B illustrates a variation structure of the first electrode 101 in FIG. 1, in which the insulating layer 156 covers the side surfaces of the conductive layer 151a, the conductive layer 151b, and the conductive layer 151c instead of covering only the side surface of the conductive layer 151b.

FIG. 7C illustrates a variation structure of the first electrode 101 in FIG. 1, in which the insulating layer 156 is not provided.

FIG. 7D illustrates a variation structure of the first electrode 101 in FIG. 1, in which the conductive layer 151 does not have a stacked-layer structure but the conductive layer 152 has a stacked-layer structure.

A conductive layer 152a has higher adhesion to the conductive layer 152b than the insulating layer 175 does, for example. For the conductive layer 152a, an oxide containing one or more selected from indium, tin, zinc, gallium, titanium, aluminum, and silicon can be used. For example, it is preferable to use a conductive oxide containing one or more of indium oxide, indium tin oxide, indium zinc oxide, zinc oxide, zinc oxide containing gallium, titanium oxide, indium titanium oxide, zinc titanate, aluminum zinc oxide, indium zinc oxide containing gallium, indium zinc oxide containing aluminum, indium tin oxide containing silicon, indium zinc oxide containing silicon, and the like. Accordingly, peeling of the conductive layer 152b can be inhibited. The conductive layer 152b is not in contact with the insulating layer 175.

The conductive layer 152b is a layer whose visible light reflectance (e.g., reflectance with respect to light with a predetermined wavelength longer than or equal to 400 nm and shorter than 750 nm) is higher than that of the conductive layer 151, the conductive layer 152a, and the conductive layer 152c. The visible light reflectance of the conductive layer 152b can be, for example, higher than or equal to 70% and lower than or equal to 100%, and is preferably higher than or equal to 80% and lower than or equal to 100%, further preferably higher than or equal to 90% and lower than or equal to 100%. For the conductive layer 152b, a material having higher visible light reflectance than aluminum can be used, for example. Specifically, for the conductive layer 152b, silver or an alloy containing silver can be used, for example. As the alloy containing silver, an alloy containing silver, palladium, and copper (APC), for example, can be used. Consequently, the display device 100 can be a display device with high light extraction efficiency. Note that a metal other than silver may be used for the conductive layer 152b.

When the conductive layer 151 and the conductive layer 152 serve as the anode, a layer having a high work function is preferably used as the conductive layer 152c. The conductive layer 152c has a higher work function than the conductive layer 152b, for example. For the conductive layer 152c, a material similar to the material usable for the conductive layer 152a can be used, for example. For example, the conductive layer 152a and the conductive layer 152c can be formed using the same kind of material. For example, in the case where indium tin oxide is used for the conductive layer 152a, indium tin oxide can also be used for the conductive layer 152c.

When the conductive layer 151 and the conductive layer 152 serve as the cathode, the conductive layer 152c is preferably a layer having a low work function. The conductive layer 152c has a lower work function than the conductive layer 152b, for example.

The conductive layer 152c is preferably a layer having high visible light transmittance (e.g., transmittance with respect to light with a predetermined wavelength longer than or equal to 400 nm and shorter than 750 nm). For example, the visible light transmittance of the conductive layer 152c is preferably higher than those of the conductive layer 151 and the conductive layer 152b. The visible light transmittance of the conductive layer 152c can be, for example, greater than or equal to 60% and less than or equal to 100%, and is preferably higher than or equal to 70% and lower than or equal to 100%, further preferably higher than or equal to 80% and lower than or equal to 100%. In that case, the amount of light that is absorbed by the conductive layer 152c after being emitted from the organic compound layer 103 can be reduced. As described above, the conductive layer 152b under the conductive layer 152c can be a layer having high visible light reflectance. Thus, the display device 100 can have high light extraction efficiency.

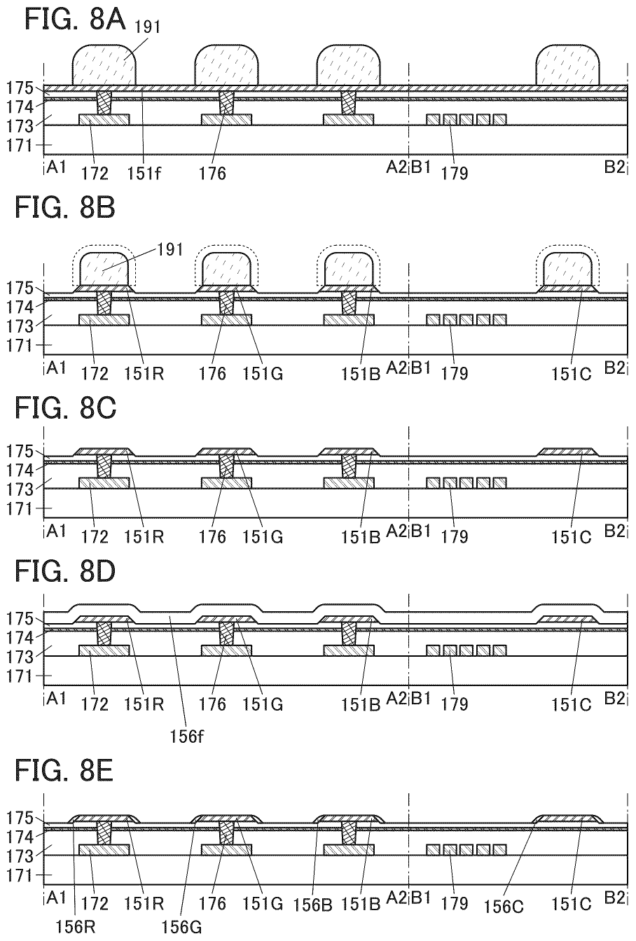

Next, an exemplary method for manufacturing the display device 100 having the structure illustrated in FIG. 6A is described with reference to FIG. 8 to FIG. 13.

### [Manufacturing Method Example]

Thin films included in the display device (insulating films, semiconductor films, conductive films, and the like) can be formed by a sputtering method, a chemical vapor deposition (CVD) method, a vacuum evaporation method, a pulsed laser deposition (PLD) method, an ALD method, or the like. Examples of the CVD method include a plasma-enhanced chemical vapor deposition (PECVD) method and a thermal CVD method. As an example of the thermal CVD method, a metal organic chemical vapor deposition (MOCVD) method can be given.

The thin films included in the display device (insulating films, semiconductor films, conductive films, and the like) can be formed by a wet film formation method such as spin coating, dipping, spray coating, inkjetting, dispensing, screen printing, offset printing, a doctor knife method, slit coating, roll coating, curtain coating, or knife coating.

For manufacture of the light-emitting devices, a vacuum process such as an evaporation method or a solution process such as a spin coating method or an inkjet method can be especially used. Examples of an evaporation method include physical vapor deposition methods (PVD methods) such as a sputtering method, an ion plating method, an ion beam evaporation method, a molecular beam evaporation method, and a vacuum evaporation method, and a chemical vapor deposition method (CVD method). In particular, the functional layers (e.g., the hole-injection layer, the hole-transport layer, the hole-blocking layer, the light-emitting layer, the electron-blocking layer, the electron-transport layer, and the electron-injection layer) included in the organic compound layer can be formed by an evaporation method (e.g., a vacuum evaporation method), a coating method (a dip coating method, a die coating method, a bar coating method, a spin coating method, a spray coating method, or the like), a printing method (an inkjet method, a screen printing (stencil) method, an offset printing (planography) method, a flexography (relief printing) method, a gravure printing method, a micro-contact printing method, or the like), or the like.

Thin films that form the display device can be processed by, for example, a photolithography method. Alternatively, the thin films may be processed by a nanoimprinting method, a sandblasting method, a lift-off method, or the like. An island-shaped thin film may be directly formed by a film formation method using a shielding mask such as a metal mask.

There are the following two typical methods of a photolithography method. In one of the methods, a resist mask is formed over a thin film that is to be processed, the thin film is processed by, for example, etching, and then the resist mask is removed. In the other method, after a photosensitive thin film is formed, light exposure and development are performed, so that the thin film is processed into a desired shape.

As light used for light exposure in a photolithography method, for example, an i-line (with a wavelength of 365 nm), a g-line (with a wavelength of 436 nm), an h-line (with a wavelength of 405 nm), or light in which these lines are mixed can be used. Besides, ultraviolet rays, KrF laser light, ArF laser light, or the like can be used. In addition, light exposure may be performed by liquid immersion exposure technique. As the light used for light exposure, extreme ultraviolet (EUV) light or X-rays may be used. Instead of the light used for the light exposure, an electron beam can also be used. It is preferable to use extreme ultraviolet light, X-rays, or an electron beam because extremely minute processing is possible. Note that when light exposure is performed by scanning of a beam such as an electron beam, a photomask is not needed.

For etching of the thin films, a dry etching method, a wet etching method, a sandblasting method, or the like can be used.

First, the insulating layer 171 is formed over a substrate (not illustrated), as illustrated in FIG. 8A. Next, the conductive layer 172 and a conductive layer 179 are formed over the insulating layer 171, and the insulating layer 173 is formed over the insulating layer 171 so as to cover the conductive layer 172 and the conductive layer 179. Then, the insulating layer 174 is formed over the insulating layer 173, and the insulating layer 175 is formed over the insulating layer 174.

As the substrate, a substrate having at least heat resistance high enough to withstand heat treatment performed later can be used. In the case where an insulating substrate is used as the substrate, a glass substrate, a quartz substrate, a sapphire substrate, a ceramic substrate, an organic resin substrate, or the like can be used. Alternatively, it is possible to use a semiconductor substrate such as a single crystal semiconductor substrate or a polycrystalline semiconductor substrate of silicon, silicon carbide, or the like, a compound semiconductor substrate of silicon germanium or the like, or an SOI substrate.

Next, openings reaching the conductive layer 172 are formed in the insulating layer 175, the insulating layer 174, and the insulating layer 173, as illustrated in FIG. 8A. Then, the plugs 176 are formed to fill the openings.

Next, a conductive film 151f to be the conductive layer 151R, the conductive layer 151G, the conductive layer 151B, and the conductive layer 151C later is formed over the plugs 176 and the insulating layer 175, as illustrated in FIG. 8A. For formation of the conductive film 151f, a sputtering method or a vacuum evaporation method can be used, for example. A metal material can be used for the conductive film 151f, for example.

Next, as illustrated in FIG. 8A, a resist mask 191 is formed over the conductive film 151f. The resist mask 191 can be formed by application of a photosensitive material (photoresist), light exposure, and development.

Subsequently, as illustrated in FIG. 8B, the conductive film 151f in a region that is not overlapped by the resist mask 191, for example, is removed by an etching method such as a dry etching method, for example. Note that in the case where the conductive film 151f includes a layer formed using a conductive oxide such as indium tin oxide, for example, the layer may be removed by a wet etching method. Thus, the conductive layer 151 is formed. Here, in the case where part of the conductive film 151f is removed by a dry etching method, for example, a depressed portion may be formed in a region of the insulating layer 175 that does not overlap with the conductive layer 151.

Next, as illustrated in FIG. 8C, the resist mask 191 is removed. The resist mask 191 can be removed by ashing using oxygen plasma, for example. Alternatively, an oxygen gas and CF₄, C₄F₈, SF₆, CHF₃, Cl₂, H₂O, BCl₃, or a Group 18 element such as He may be used. Alternatively, the resist mask 191 may be removed by wet etching.

Next, as illustrated in FIG. 8D, an insulating film 156f to be an insulating layer 156R, an insulating layer 156G, an insulating layer 156B, and an insulating layer 156C later is formed over the conductive layer 151R, the conductive layer 151G, the conductive layer 151B, the conductive layer 151C, and the insulating layer 175. The insulating film 156f can be formed by a CVD method, an ALD method, a sputtering method, or a vacuum evaporation method, for example.

The insulating film 156f can be formed using an inorganic material. As the insulating film 156f, an inorganic insulating film such as an oxide insulating film, a nitride insulating film, an oxynitride insulating film, or a nitride oxide insulating film can be used, for example. As the insulating film 156f, an oxide insulating film containing silicon, a nitride insulating film containing silicon, an oxynitride insulating film containing silicon, a nitride oxide insulating film containing silicon, or the like can be used, for example. As the insulating film 156f, silicon oxynitride can be used, for example.

Subsequently, as illustrated in FIG. 8E, the insulating film 156f is processed to form the insulating layer 156R, the insulating layer 156G, the insulating layer 156B, and the insulating layer 156C. The insulating layer 156 can be formed by performing etching substantially uniformly on the top surface of the insulating film 156f, for example. Such uniform etching for planarization is also referred to as etch-back treatment. Note that the insulating layer 156 may be formed by a photolithography method.

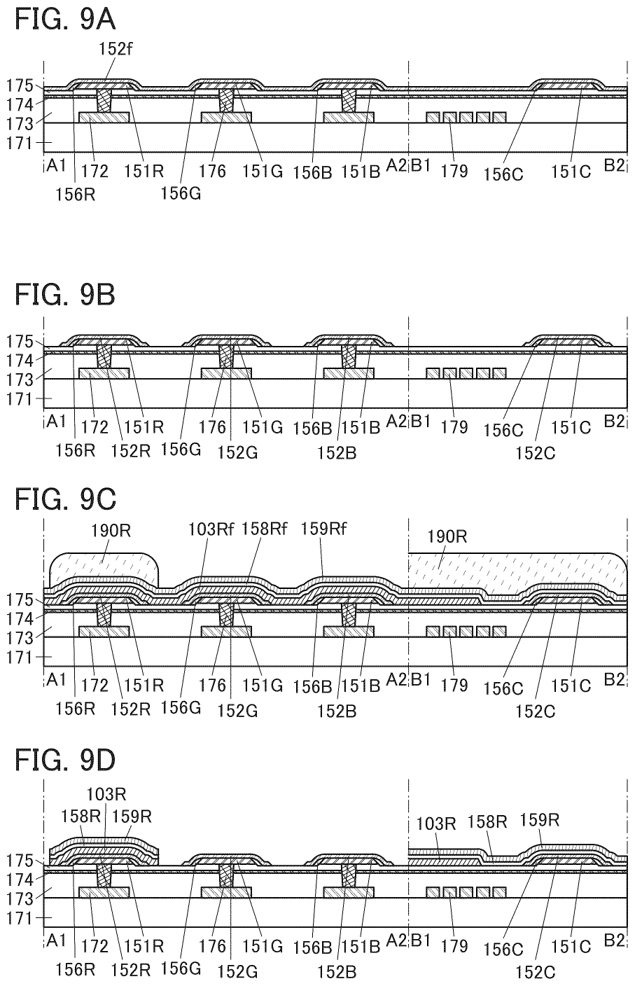

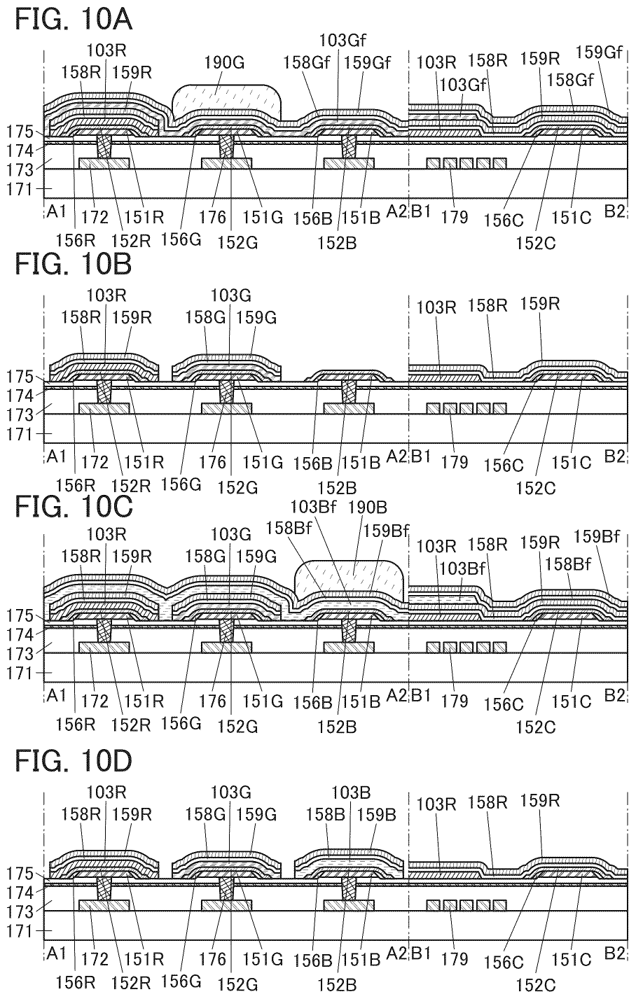

Then, as illustrated in FIG. 9A, a conductive film 152f to be the conductive layer 152R, the conductive layer 152G, the conductive layer 152B, and the conductive layer 152C is formed over the conductive layer 151R, the conductive layer 151G, the conductive layer 151B, the conductive layer 151C, the insulating layer 156R, the insulating layer 156G, the insulating layer 156B, the insulating layer 156C, and the insulating layer 175. Specifically, the conductive film 152f is formed to cover the conductive layer 151R, the conductive layer 151G, the conductive layer 151B, the conductive layer 151C, the insulating layer 156R, the insulating layer 156G, the insulating layer 156B, and the insulating layer 156C, for example.

For formation of the conductive film 152f, a sputtering method or a vacuum evaporation method can be used, for example. A conductive oxide can be used for the conductive film 152f, for example. The conductive film 152f can have a stacked-layer structure of a metal material film and a film formed thereover using a conductive oxide. For example, the conductive film 152f can have a stacked-layer structure of titanium, silver, or an alloy containing silver and a film formed thereover using a conductive oxide.

The conductive film 152f can be formed by an ALD method. For the conductive film 152f, an oxide containing one or more selected from indium, tin, zinc, gallium, titanium, aluminum, and silicon can be used. In this case, the conductive film 152f can be formed by repeating a cycle of introduction of a precursor (generally referred to as a metal precursor or the like in some cases), purge of the precursor, introduction of an oxidizer (generally referred to as a reactant, a non-metal precursor, or the like in some cases), and purge of the oxidizer. Here, in the case where an oxide film containing a plurality of kinds of metals, such as an indium tin oxide film, is formed as the conductive film 152f, the composition of the metals can be controlled by varying the number of cycles for different kinds of precursors.

For example, in the case where an indium tin oxide film is formed as the conductive film 152f, after a precursor containing indium is introduced, the precursor is purged, and an oxidizer is introduced to form an In—O film, and then a precursor containing tin is introduced, the precursor is purged, and an oxidizer is introduced to form a Sn—O film. Here, when the number of cycles of forming an In—O film is larger than the number of cycles of forming a Sn—O film, the number of In atoms contained in the conductive film 152f can be larger than the number of Sn atoms contained therein.

For example, to form a zinc oxide film as the conductive film 152f, a Zn—O film is formed in the above procedure. For example, to form an aluminum zinc oxide film as the conductive film 152f, a Zn—O film and an Al—O film are formed in the above procedure. For example, to form a titanium oxide film as the conductive film 152f, a Ti—O film is formed in the above procedure. For example, to form an indium tin oxide film containing silicon as the conductive film 152f, an In—O film, a Sn—O film, and a Si—O film are formed in the above procedure. For example, to form a zinc oxide film containing gallium, a Ga—O film and a Zn—O film are formed in the above procedure.

As a precursor containing indium, it is possible to use, for example, triethylindium, trimethylindium, or [1,1,1-trimethyl-N-(trimethylsilyl)amide]-indium. As a precursor containing tin, it is possible to use, for example, tin chloride or tetrakis(dimethylamido)tin. As a precursor containing zinc, it is possible to use, for example, diethylzinc or dimethylzinc. As a precursor containing gallium, it is possible to use, for example, triethylgallium. As a precursor containing titanium, it is possible to use, for example, titanium chloride, tetrakis(dimethylamido)titanium, or tetraisopropyl titanate. As a precursor containing aluminum, it is possible to use, for example, aluminum chloride or trimethylaluminum. As a precursor containing silicon, it is possible to use trisilylamine, bis(diethylamino)silane, tris(dimethylamino)silane, bis(tert-butylamino)silane, or bis(ethylmethylamino)silane. As the oxidizer, water vapor, oxygen plasma, or an ozone gas can be used.

Then, as illustrated in FIG. 9B, the conductive film 152f is processed by a photolithography method, for example, so that the conductive layer 152R, the conductive layer 152G, the conductive layer 152B, and the conductive layer 152C are formed. Specifically, the conductive film 152f is partly removed by an etching method after a resist mask is formed, for example. The conductive film 152f can be removed by a wet etching method, for example. The conductive film 152f may be removed by a dry etching method. Through the above steps, the pixel electrode including the conductive layer 151 and the conductive layer 152 is formed.

Then, the conductive layer 152 is preferably subjected to hydrophobic treatment. The hydrophobic treatment can change the property of the surface of a processing target from hydrophilic to hydrophobic, or can improve the hydrophobic property of the surface of the processing target. The hydrophobic treatment for the conductive layer 152 can increase the adhesion between the conductive layer 152 and the organic compound layer 103 formed in a later step and inhibits peeling. Note that the hydrophobic treatment is not necessarily performed.

Next, as illustrated in FIG. 9C, the organic compound film 103Rf to be the organic compound layer 103R later is formed over the conductive layer 152R, the conductive layer 152G, the conductive layer 152B, and the insulating layer 175.

As illustrated in FIG. 9C, the organic compound film 103Rf is not formed over the conductive layer 152C. The organic compound film 103Rf can be formed only in an intended region by using a mask for specifying a film formation area (also referred to as an area mask or a rough metal mask to be distinguished from a fine metal mask), for example. Employing a film formation step using an area mask and a processing step using a resist mask enables a light-emitting device to be manufactured by a relatively easy process.

The organic compound film 103Rf can be formed by an evaporation method, specifically a vacuum evaporation method, for example. The organic compound film 103Rf may be formed by a transfer method, a printing method, an inkjet method, a coating method, or the like.

Next, as illustrated in FIG. 9C, a sacrificial film 158Rf to be a sacrificial layer 158R later and a mask film 159Rf to be a mask layer 159R later are sequentially formed over the organic compound film 103Rf, the conductive layer 152C, and the insulating layer 175.

Although this embodiment describes an example in which the mask film is formed with a two-layer structure of the sacrificial film 158Rf and the mask film 159Rf, the mask film may have a single-layer structure or a stacked-layer structure of three or more layers.

The sacrificial layer provided over the organic compound film 103Rf can reduce damage to the organic compound film 103Rf in the manufacturing process of the display device, increasing the reliability of the light-emitting device.

As the sacrificial film 158Rf, a film that is highly resistant to the processing conditions for the organic compound film 103Rf, specifically, a film having high etching selectivity with the organic compound film 103Rf is used. As the mask film 159Rf, a film having high etching selectivity with the sacrificial film 158Rf is used.

The sacrificial film 158Rf and the mask film 159Rf are formed at a temperature lower than the upper temperature limit of the organic compound film 103Rf. The typical substrate temperatures in formation of the sacrificial film 158Rf and the mask film 159Rf are each lower than or equal to 200° C., preferably lower than or equal to 150° C., further preferably lower than or equal to 120° C., still further preferably lower than or equal to 100° C., yet still further preferably lower than or equal to 80° C.

As the sacrificial film 158Rf and the mask film 159Rf, it is preferable to use a film that can be removed by a wet etching method. Using a wet etching method can reduce damage to the organic compound film 103Rf in processing the sacrificial film 158Rf and the mask film 159Rf, as compared to the case of using a dry etching method.

The sacrificial film 158Rf and the mask film 159Rf can be formed by a sputtering method, an ALD method (a thermal ALD method or a PEALD method), a CVD method, or a vacuum evaporation method, for example. Alternatively, the aforementioned wet film formation method may be used for the formation.

Note that the sacrificial film 158Rf, which is formed over and in contact with the organic compound film 103Rf, is preferably formed by a formation method that causes less damage to the organic compound film 103Rf than a formation method for the mask film 159Rf. For example, the sacrificial film 158Rf is preferably formed by an ALD method or a vacuum evaporation method rather than a sputtering method.

As the sacrificial film 158Rf and the mask film 159Rf, it is possible to use one or more of a metal film, an alloy film, a metal oxide film, a semiconductor film, an organic insulating film, and an inorganic insulating film, for example.

For the sacrificial film 158Rf and the mask film 159Rf, it is possible to use a metal material such as gold, silver, platinum, magnesium, nickel, tungsten, chromium, molybdenum, iron, cobalt, copper, palladium, titanium, aluminum, yttrium, zirconium, or tantalum or an alloy material containing any of the metal materials, for example. It is particularly preferable to use a low-melting-point material such as aluminum or silver. The use of a metal material capable of blocking ultraviolet rays for one or both of the sacrificial film 158Rf and the mask film 159Rf is preferable, in which case the organic compound film 103Rf can be inhibited from being irradiated with ultraviolet rays and deteriorating.

For each of the sacrificial film 158Rf and the mask film 159Rf, it is possible to use a metal oxide such as In—Ga—Zn oxide, indium oxide, In—Zn oxide, In—Sn oxide, indium titanium oxide (In—Ti oxide), indium tin zinc oxide (In—Sn—Zn oxide), indium titanium zinc oxide (In—Ti—Zn oxide), indium gallium tin zinc oxide (In—Ga—Sn—Zn oxide), or indium tin oxide containing silicon.

Note that an element M (M is one or more of aluminum, silicon, boron, yttrium, copper, vanadium, beryllium, titanium, iron, nickel, germanium, zirconium, molybdenum, lanthanum, cerium, neodymium, hafnium, tantalum, tungsten, and magnesium) may be used instead of gallium described above.

As each of the sacrificial film and the mask film, a film containing a material having a light-blocking property, particularly with respect to ultraviolet rays, is preferably used. Although a variety of materials such as a metal, an insulator, a semiconductor, and a metalloid that have a property of blocking ultraviolet rays can be used as the material having a light-blocking property, each of the sacrificial film and the mask film is preferably a film capable of being processed by etching and is particularly preferably a film having good processability because part or the whole of each of the sacrificial film and the mask film is removed in a later step.

For example, a semiconductor material with excellent compatibility with a semiconductor manufacturing process, such as silicon or germanium, is preferably used for the sacrificial film and the mask film. Alternatively, an oxide or a nitride of the semiconductor material can be used. A non-metallic material such as carbon or a compound thereof can be used. A metal such as titanium, tantalum, tungsten, chromium, or aluminum or an alloy containing at least one of these metals can be used. Alternatively, an oxide containing the above-described metal, such as titanium oxide or chromium oxide, or a nitride such as titanium nitride, chromium nitride, or tantalum nitride can be used.

The use of a film containing a material having a property of blocking ultraviolet rays as each of the sacrificial film and the mask film can inhibit the organic compound layer from being irradiated with ultraviolet rays in alight exposure step, for example. The organic compound layer is inhibited from being damaged by ultraviolet rays, so that the reliability of the light-emitting device can be improved.

Note that the film containing a material having a property of blocking ultraviolet rays can have the same effect even when used for an inorganic insulating film 125f described later.

As each of the sacrificial film 158Rf and the mask film 159Rf, any of a variety of inorganic insulating films can be used. In particular, an oxide insulating film is preferable because its adhesion to the organic compound film 103Rf is higher than that of a nitride insulating film. For example, an inorganic insulating material such as aluminum oxide, hafnium oxide, or silicon oxide can be used for the sacrificial film 158Rf and the mask film 159Rf. As each of the sacrificial film 158Rf and the mask film 159Rf, an aluminum oxide film can be formed by an ALD method, for example. The use of an ALD method is preferable, in which case damage to a base (in particular, the organic compound layer) can be reduced.

For example, an inorganic insulating film (e.g., an aluminum oxide film) formed by an ALD method can be used as the sacrificial film 158Rf, and an inorganic film (e.g., an In—Ga—Zn oxide film, an aluminum film, or a tungsten film) formed by a sputtering method can be used as the mask film 159Rf.

Note that the same inorganic insulating film can be used for both the sacrificial film 158Rf and the inorganic insulating layer 125 that is to be formed later. For example, an aluminum oxide film formed by an ALD method can be used for both the sacrificial film 158Rf and the inorganic insulating layer 125. Here, for the sacrificial film 158Rf and the inorganic insulating layer 125, the same film formation condition may be used or different film formation conditions may be used. For example, when the sacrificial film 158Rf is formed under conditions similar to those of the inorganic insulating layer 125, the sacrificial film 158Rf can be an insulating layer having a high barrier property against at least one of water and oxygen. Meanwhile, the sacrificial film 158Rf is a layer most or all of which is to be removed in a later step, and thus is preferably easy to process. Therefore, the sacrificial film 158Rf is preferably formed with a substrate temperature lower than that for formation of the inorganic insulating layer 125.

An organic material may be used for one or both of the sacrificial film 158Rf and the mask film 159Rf. For example, as the organic material, a material that can be dissolved in a solvent chemically stable with respect to at least the uppermost film of the EL film 103Rf may be used. Specifically, a material that will be dissolved in water or alcohol can be suitably used. In film formation of a film of such a material, it is preferable to apply the material dissolved in a solvent such as water or alcohol by a wet film formation method and then perform heat treatment for evaporating the solvent. At this time, the heat treatment is preferably performed in a reduced-pressure atmosphere, in which case the solvent can be removed at a low temperature in a short time and thermal damage to the EL film 103Rf can be reduced accordingly.

For each of the sacrificial film 158Rf and the mask film 159Rf, an organic resin such as polyvinyl alcohol (PVA), polyvinyl butyral, polyvinylpyrrolidone, polyethylene glycol, polyglycerin, pullulan, water-soluble cellulose, an alcohol-soluble polyamide resin, or a fluororesin such as perfluoropolymer may be used.

For example, an organic film (e.g., a PVA film) formed by an evaporation method or the above wet film formation method can be used as the sacrificial film 158Rf, and an inorganic film (e.g., a silicon nitride film) formed by a sputtering method can be used as the mask film 159Rf.

Then, a resist mask 190R is formed over the mask film 159Rf, as illustrated in FIG. 9C. The resist mask 190R can be formed by application of a photosensitive material (photoresist), light exposure, and development.

Either a positive resist material or a negative resist material may be used to form the resist mask 190R.

The resist mask 190R is provided at a position overlapping with the conductive layer 152R Note that the resist mask 190R is preferably provided also at a position overlapping with the conductive layer 152C. This can inhibit the conductive layer 152C from being damaged during the manufacturing process of the display device. Note that the resist mask 190R is not necessarily provided over the conductive layer 152C. The resist mask 190R is preferably provided to cover the area from the end portion of the organic compound film 103Rf to the end portion of the conductive layer 152C (the end portion closer to the organic compound film 103Rf), as illustrated in the cross-sectional view along the line B1-B2 in FIG. 9C.

Subsequently, as illustrated in FIG. 9D, part of the mask film 159Rf is removed using the resist mask 190R, whereby the mask layer 159R is formed. The mask layer 159R remains over the conductive layer 152R and over the conductive layer 152C. After that, the resist mask 190R is removed. Then, part of the sacrificial film 158Rf is removed using the mask layer 159R as a mask (also referred to as a hard mask), whereby the sacrificial layer 158R is formed.

The sacrificial film 158Rf and the mask film 159Rf can be processed by a wet etching method or a dry etching method. The sacrificial film 158Rf and the mask film 159Rf are preferably processed by isotropic etching.

Using a wet etching method can reduce damage to the organic compound film 103Rf in processing the sacrificial film 158Rf and the mask film 159Rf, as compared to the case of using a dry etching method. In the case of using a wet etching method, it is preferable to use a developer, a tetramethylammonium hydroxide aqueous solution (TMAH), dilute hydrofluoric acid, oxalic acid, phosphoric acid, acetic acid, nitric acid, or a chemical solution containing a mixed solution of any of these acids, for example.

Since the organic compound film 103Rf is not exposed in processing the mask film 159Rf, the range of choices of the processing method is wider than that for processing the sacrificial film 158Rf. Specifically, even in the case where a gas containing oxygen is used as the etching gas in the processing of the mask film 159Rf, deterioration of the organic compound film 103Rf can be inhibited.

In the case of using a dry etching method for processing the sacrificial film 158Rf, deterioration of the organic compound film 103Rf can be inhibited by not using a gas containing oxygen as the etching gas. In the case of using a dry etching method, it is preferable to use a gas containing CF₄, C₄F₈, SF₆, CHF₃, Cl₂, H₂O, BCl₃, or a Group 18 element such as He, for example, as the etching gas.

For example, in the case where an aluminum oxide film formed by an ALD method is used as the sacrificial film 158Rf, part of the sacrificial film 158Rf can be removed by a dry etching method using a combination of CHF₃ and He or a combination of CHF₃, He, and CH₄. In the case where an In—Ga—Zn oxide film formed by a sputtering method is used as the mask film 159Rf, part of the mask film 159Rf can be removed by a wet etching method using a diluted phosphoric acid. Alternatively, part of the mask film 159Rf may be removed by a dry etching method using CH₄ and Ar. Alternatively, part of the mask film 159Rf can be removed by a wet etching method using diluted phosphoric acid. In the case where a tungsten film formed by a sputtering method is used as the mask film 159Rf, part of the mask film 159Rf can be removed by a dry etching method using SF₆, a combination of CF₄ and O₂, or a combination of CF₄, Cl₂, and O₂.

The resist mask 190R can be removed by a method similar to that for the resist mask 191. The resist mask 190R can be removed by ashing using oxygen plasma, for example. Alternatively, an oxygen gas and CF₄, C₄F₈, SF₆, CHF₃, Cl₂, H₂O, BCl₃, or a Group 18 element such as He may be used. Alternatively, the resist mask 190R may be removed by wet etching. At this time, the sacrificial film 158Rf is positioned on the outermost surface and the organic compound film 103Rf is not exposed; thus, the organic compound film 103Rf can be inhibited from being damaged in the step of removing the resist mask 190R In addition, the range of choices of the method for removing the resist mask 190R can be widened.

Next, as illustrated in FIG. 9D, the organic compound film 103Rf is processed to form the organic compound layer 103R For example, part of the organic compound film 103Rf is removed using the mask layer 159R and the sacrificial layer 158R as a hard mask to form the organic compound layer 103R.

Accordingly, as illustrated in FIG. 9D, a stacked-layer structure of the organic compound layer 103R, the sacrificial layer 158R, and the mask layer 159R remains over the conductive layer 152R The conductive layer 152G and the conductive layer 152B are exposed.

FIG. 9D illustrates an example in which the end portion of the organic compound layer 103R is positioned outward from the end portion of the conductive layer 152R Such a structure can increase the aperture ratio of the pixel. Although not illustrated in FIG. 9D, by the above etching treatment, a depressed portion may be formed in the insulating layer 175 in a region that does not overlap with the organic compound layer 103R.

The organic compound layer 103R covers the top surface and the side surface of the conductive layer 152R and thus, the subsequent steps can be performed without exposure of the conductive layer 152R When the end portion of the conductive layer 152R is exposed, corrosion might occur in the etching step, for example. A product generated by corrosion of the conductive layer 152R may be unstable, and for example, might be dissolved in a solution when wet etching is performed and might be scattered in an atmosphere when dry etching is performed. The product dissolved in a solution or scattered in an atmosphere might be attached to a surface to be processed, the side surface of the organic compound layer 103R, and the like, which adversely affects the characteristics of the light-emitting device or forms a leakage path between the light-emitting devices in some cases. In a region where the end portion of the conductive layer 152R is exposed, adhesion between layers in contact with each other might be lowered, which might be likely to cause peeling of the organic compound layer 103R or the conductive layer 152R.

Thus, the structure where the organic compound layer 103R covers the top surface and the side surface of the conductive layer 152R can improve the yield and characteristics of the light-emitting device, for example.

As described above, the resist mask 190R is preferably provided to cover the area from the end portion of the organic compound layer 103R to the end portion of the conductive layer 152C (the end portion closer to the organic compound layer 103R) in the cross section B1-B2. Thus, as illustrated in FIG. 9D, the sacrificial layer 158R and the mask layer 159R are provided to cover the area from the end portion of the organic compound layer 103R to the end portion of the conductive layer 152C (the end portion closer to the organic compound layer 103R) in the cross section B1-B2. Hence, the insulating layer 175 can be inhibited from being exposed in the cross section B1-B2, for example. This can prevent the insulating layer 175, the insulating layer 174, and the insulating layer 173 from being partly removed by etching and thus prevent the conductive layer 179 from being exposed. Thus, unintentional electrical connection between the conductive layer 179 and another conductive layer can be inhibited. For example, a short circuit between the conductive layer 179 and a common electrode 155 formed in a later step can be inhibited.

The organic compound film 103Rf is preferably processed by anisotropic etching. In particular, anisotropic dry etching is preferable. Alternatively, wet etching may be used.

In the case of using a dry etching method, deterioration of the organic compound film 103Rf can be inhibited by not using a gas containing oxygen as the etching gas.

A gas containing oxygen may be used as the etching gas. When the etching gas contains oxygen, the etching rate can be increased. Therefore the etching can be performed under a low-power condition while an adequately high etching rate is maintained. Thus, damage to the organic compound film 103Rf can be inhibited. Furthermore, a defect such as attachment of a reaction product generated at the etching can be inhibited.

In the case of using a dry etching method, it is preferable to use a gas containing at least one of H₂, CF₄, C₄F₈, SF₆, CHF₃, Cl₂, H₂O, BCl₃, and a Group 18 element such as He or Ar as the etching gas, for example. Alternatively, a gas containing oxygen and at least one kind of the above is preferably used as the etching gas. Alternatively, an oxygen gas may be used as the etching gas. Specifically, for example, a gas containing H₂ and Ar or a gas containing CF₄ and He can be used as the etching gas. For example, a gas containing CF₄, He, and oxygen can be used as the etching gas. For example, a gas containing H₂ and Ar and a gas containing oxygen can be used as the etching gas.

As described above, in one embodiment of the present invention, the mask layer 159R is formed in the following manner: the resist mask 190R is formed over the mask film 159Rf, and part of the mask film 159Rf is removed using the resist mask 190R After that, part of the organic compound film 103Rf is removed using the mask layer 159R as a hard mask, so that the organic compound layer 103R is formed. In other words, the organic compound layer 103R can be formed by processing the organic compound film 103Rf by a photolithography method. Note that part of the organic compound film 103Rf may be removed using the resist mask 190R Then, the resist mask 190R may be removed.

Next, hydrophobic treatment for the conductive layer 152G, for example, is preferably performed. At the time of processing the organic compound film 103Rf, the surface of the conductive layer 152G changes to have hydrophilic properties in some cases, for example. The hydrophobic treatment for the conductive layer 152G, for example, can increase the adhesion between the conductive layer 152G and a layer to be formed in a later step (which is the organic compound layer 103G here) and inhibit peeling. Note that the hydrophobic treatment is not necessarily performed.

Next, as illustrated in FIG. 10A, an organic compound film 103Gf to be the organic compound layer 103G later is formed over the conductive layer 152G, the conductive layer 152B, the mask layer 159R, and the insulating layer 175.

The organic compound film 103Gf can be formed by a method similar to a method that can be employed to form the organic compound film 103Rf. The organic compound film 103Gf can have a structure similar to that of the organic compound film 103Rf.

Then, as illustrated in FIG. 10A, a sacrificial film 158Gf to be a sacrificial layer 158G later and a mask film 159Gf to be a mask layer 159G later are sequentially formed over the EL film 103Gf and the mask layer 159R After that, a resist mask 190G is formed. The materials and the formation methods of the sacrificial film 158Gf and the mask film 159Gf are similar to conditions applicable to the sacrificial film 158Rf and the mask film 159Rf. The materials and the formation method of the resist mask 190G are similar to conditions applicable to the resist mask 190R.

The resist mask 190G is provided at a position overlapping with the conductive layer 152G.

Subsequently, as illustrated in FIG. 10B, part of the mask film 159Gf is removed using the resist mask 190G, whereby the mask layer 159G is formed. The mask layer 159G remains over the conductive layer 152G. After that, the resist mask 190G is removed. Then, part of the sacrificial film 158Gf is removed using the mask layer 159G as a mask, whereby the sacrificial layer 158G is formed. Next, the organic compound film 103Gf is processed to form the organic compound layer 103G. For example, part of the organic compound film 103Gf is removed using the mask layer 159G and the sacrificial layer 158G as a hard mask to form the organic compound layer 103G.

Accordingly, as illustrated in FIG. 10B, a stacked-layer structure of the organic compound layer 103G, the sacrificial layer 158G, and the mask layer 159G remains over the conductive layer 152G. The mask layer 159R and the conductive layer 152B are exposed.

Next, hydrophobic treatment for the conductive layer 152B, for example, is preferably performed. At the time of processing the organic compound film 103Gf, the surface of the conductive layer 152B changes to have hydrophilic properties in some cases, for example. The hydrophobic treatment for the conductive layer 152B, for example, can increase the adhesion between the conductive layer 152B and a layer to be formed in a later step (which is the organic compound layer 103B here) and inhibit peeling. Note that the hydrophobic treatment is not necessarily performed.

Next, as illustrated in FIG. 10C, an organic compound film 103Bf to be the organic compound layer 103B later is formed over the conductive layer 152B, the mask layer 159R, the mask layer 159G, and the insulating layer 175.

The organic compound film 103Bf can be formed by a method similar to a method that can be employed to form the organic compound film 103Rf. The organic compound film 103Bf can have a structure similar to that of the organic compound film 103Rf.

Then, as illustrated in FIG. 10C, a sacrificial film 158Bf to be a sacrificial layer 158B later and a mask film 159Bf to be a mask layer 159B later are sequentially formed over the organic compound film 103Bf and the mask layer 159R. After that, a resist mask 190B is formed. The materials and the formation methods of the sacrificial film 158Bf and the mask film 159Bf are similar to conditions applicable to the sacrificial film 158Rf and the mask film 159Rf. The materials and the formation method of the resist mask 190B are similar to conditions applicable to the resist mask 190R.

The resist mask 190B is provided at a position overlapping with the conductive layer 152B.

Subsequently, as illustrated in FIG. 10D, part of the mask film 159Bf is removed using the resist mask 190B, whereby the mask layer 159B is formed. The mask layer 159B remains over the conductive layer 152B. After that, the resist mask 190B is removed. Then, part of the sacrificial film 158Bf is removed using the mask layer 159B as a mask, whereby the sacrificial layer 158B is formed. Next, the organic compound film 103Bf is processed to form the organic compound layer 103B. For example, part of the organic compound film 103Bf is removed using the mask layer 159B and the sacrificial layer 158B as a hard mask to form the organic compound layer 103B.

Accordingly, as illustrated in FIG. 10D, a stacked-layer structure of the organic compound layer 103B, the sacrificial layer 158B, and the mask layer 159B remains over the conductive layer 152B. The mask layer 159R and the mask layer 159G are exposed.

Note that side surfaces of the organic compound layer 103R, the organic compound layer 103G, and the organic compound layer 103B are preferably perpendicular or substantially perpendicular to their formation surfaces. For example, the angle between the formation surfaces and these side surfaces is preferably greater than or equal to 60° and less than or equal to 90°.

As described above, the distance between adjacent two layers among the organic compound layer 103R, the organic compound layer 103G, and the organic compound layer 103B formed by a photolithography method can be shortened to less than or equal to 8 μm, less than or equal to 5 μm, less than or equal to 3 μm, less than or equal to 2 μm, or less than or equal to 1 sm. Here, the distance can be specified, for example, by a distance between opposite end portions of two adjacent layers among the organic compound layer 103R, the organic compound layer 103G, and the organic compound layer 103B. The distance between the island-shaped organic compound layers is shortened in this manner, whereby a display device with high resolution and a high aperture ratio can be provided. In addition, the distance between the first electrodes of adjacent light-emitting devices can also be shortened to be, for example, less than or equal to 10 μm, less than or equal to 8 μm, less than or equal to 5 μm, less than or equal to 3 μm, or less than or equal to 2 pm. Note that the distance between the first electrodes of adjacent light-emitting devices is preferably greater than or equal to 2 μm and less than or equal to 5 pm.

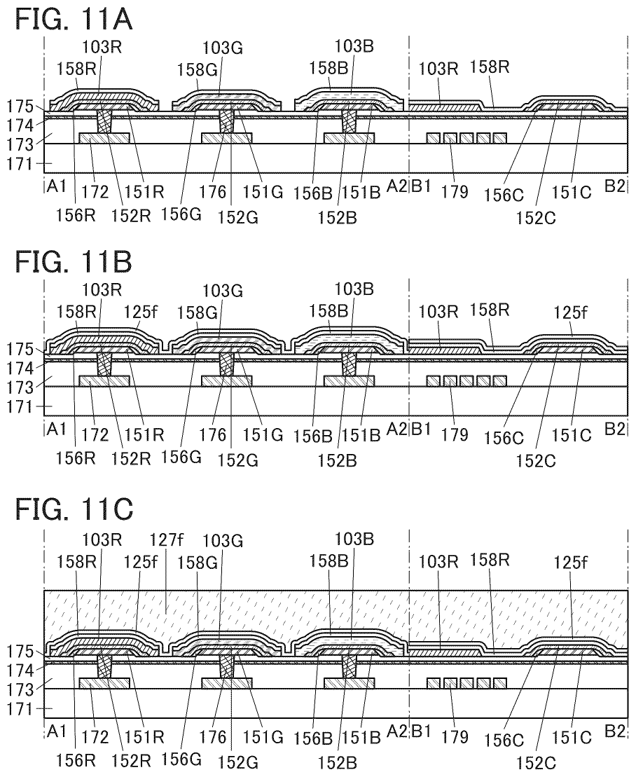

Next, the mask layer 159R, the mask layer 159G, and the mask layer 159B are preferably removed as illustrated in FIG. 11A. The sacrificial layer 158R, the sacrificial layer 158G, the sacrificial layer 158B, the mask layer 159R, the mask layer 159G, and the mask layer 159B might remain in the display device in some cases depending on the subsequent steps. Removing the mask layer 159R, the mask layer 159G, and the mask layer 159B at this stage can inhibit the mask layer 159R, the mask layer 159G, and the mask layer 159B from remaining in the display device. In the case where a conductive material is used for the mask layer 159R, the mask layer 159G, and the mask layer 159B, removing the mask layer 159R, the mask layer 159G, and the mask layer 159B in advance can inhibit generation of leakage current, formation of a capacitor, and the like due to the mask layer 159R, the mask layer 159G, and the mask layer 159B, for example.

Although this embodiment shows an example where the mask layer 159R, the mask layer 159G, and the mask layer 159B are removed, the mask layer 159R, the mask layer 159G, and the mask layer 159B are not necessarily removed. For example, in the case where the mask layer 159R, the mask layer 159G, and the mask layer 159B contain the material having a property of blocking ultraviolet rays, the procedure preferably proceeds to the next step without removing the mask layer 159R, the mask layer 159G, and the mask layer 159B, in which case the organic compound layer can be protected from ultraviolet rays.

The step of removing the mask layers can be performed by a method similar to that for the step of processing the mask layers. In particular, using a wet etching method can reduce damage to the organic compound layer 103R, the organic compound layer 103G, and the organic compound layer 103B in removing the mask layers, as compared to the case of using a dry etching method.

The mask layers may be removed by being dissolved in a solvent such as water or alcohol. Examples of alcohol include ethyl alcohol, methyl alcohol, isopropyl alcohol (IPA), and glycerin.

After the mask layers are removed, drying treatment may be performed in order to remove water contained in the organic compound layer 103R, the organic compound layer 103G, and the organic compound layer 103B and water adsorbed onto the surfaces of the organic compound layer 103R, the organic compound layer 103G, and the organic compound layer 103B. For example, heat treatment in an inert gas atmosphere or a reduced-pressure atmosphere can be performed. The heat treatment can be performed at a substrate temperature higher than or equal to 50° C. and lower than or equal to 200° C., preferably higher than or equal to 60° C. and lower than or equal to 150° C., further preferably higher than or equal to 70° C. and lower than or equal to 120° C. The heat treatment is preferably performed in a reduced-pressure atmosphere, in which case drying at a lower temperature is possible.

Next, as illustrated in FIG. 11B, the inorganic insulating film 125f to be the inorganic insulating layer 125 later is formed to cover the organic compound layer 103R, the organic compound layer 103G, and the organic compound layer 103B and the sacrificial layer 158R, the sacrificial layer 158G, and the sacrificial layer 158B.

As described later, an insulating film to be the insulating layer 127 later is formed in contact with the top surface of the inorganic insulating film 125f. Therefore, the top surface of the inorganic insulating film 125f preferably has high affinity for a material used for the insulating film (e.g., a photosensitive resin composition containing an acrylic resin). To improve the affinity, surface treatment is preferably performed so that the top surface of the inorganic insulating film 125f is made hydrophobic (or its hydrophobic properties are improved). For example, it is preferable to perform the treatment using a silylation agent such as hexamethyldisilazane (HMDS). By making the top surface of the inorganic insulating film 125f hydrophobic in this manner, the above insulating film can be formed with high adhesion. Note that the above-described hydrophobic treatment may be performed as the surface treatment.

Then, as illustrated in FIG. 11C, an insulating film 127f to be the insulating layer 127 later is formed over the inorganic insulating film 125f.

The inorganic insulating film 125f and the insulating film 127f are preferably formed by a formation method that causes less damage to the organic compound layer 103R, the organic compound layer 103G, and the organic compound layer 103B. The inorganic insulating film 125f, which is formed in contact with the side surfaces of the organic compound layer 103R, the organic compound layer 103G, and the organic compound layer 103B, is particularly preferably formed by a method that is less likely to damage the organic compound layer 103R, the organic compound layer 103G, and the organic compound layer 103B than the method of forming the insulating film 127f.

In addition, the inorganic insulating film 125f and the insulating film 127f are each formed at a temperature lower than the upper temperature limit of the organic compound layer 103R, the organic compound layer 103G, and the organic compound layer 103B. When the substrate temperature at the time when the inorganic insulating film 125f is formed is increased, the formed inorganic insulating film 125f, even with a small thickness, can have a low impurity concentration and a high barrier property against at least one of water and oxygen.

The substrate temperature at the time of forming the inorganic insulating film 125f and the insulating film 127f is preferably higher than or equal to 60° C., higher than or equal to 80° C., higher than or equal to 100° C., or higher than or equal to 120° C. and lower than or equal to 200° C., lower than or equal to 180° C., lower than or equal to 160° C., lower than or equal to 150° C., or lower than or equal to 140° C.

As the inorganic insulating film 125f, an insulating film is preferably formed within the above substrate temperature range to have a thickness greater than or equal to 3 nm, greater than or equal to 5 nm, or greater than or equal to 10 nm and less than or equal to 200 nm, less than or equal to 150 nm, less than or equal to 100 nm, or less than or equal to 50 nm.

The inorganic insulating film 125f is preferably formed by an ALD method, for example. The use of an ALD method is preferable, in which case damage by the deposition is reduced and a film with good coverage can be deposited. As the inorganic insulating film 125f, an aluminum oxide film is preferably formed by an ALD method, for example.

Alternatively, the inorganic insulating film 125f may be formed by a sputtering method, a CVD method, or a PECVD method, each of which has a higher deposition rate than an ALD method. In that case, a highly reliable display device can be manufactured with high productivity.

The insulating film 127f is preferably formed by the aforementioned wet film formation method. The insulating film 127f is preferably formed by spin coating using a photosensitive material, for example, and preferably formed using specifically a photosensitive resin composition containing an acrylic resin.

The insulating film 127f is preferably formed using a resin composition containing a polymer, an acid-generating agent, and a solvent, for example. The polymer is formed using one or more kinds of monomers and has a structure where one or more kinds of structural units (also referred to as building blocks) are repeated regularly or irregularly. As the acid-generating agent, one or both of a compound that generates an acid by light irradiation and a compound that generates an acid by heating can be used. The resin composition may also include one or more of a photosensitizing agent, a sensitizer, a catalyst, an adhesive aid, a surface-active agent, and an antioxidant.

Heat treatment (also referred to as prebaking) is preferably performed after the insulating film 127f is formed. The heat treatment is performed at a temperature lower than the upper temperature limit of the organic compound layer 103R, the organic compound layer 103G, and the organic compound layer 103B. The substrate temperature in the heat treatment is preferably higher than or equal to 50° C. and lower than or equal to 200° C., further preferably higher than or equal to 60° C. and lower than or equal to 150° C., still further preferably higher than or equal to 70° C. and lower than or equal to 120° C. Accordingly, a solvent contained in the insulating film 127f can be removed.

Then, part of the insulating film 127f is exposed to visible light or ultraviolet rays. Here, when a positive photosensitive resin composition containing an acrylic resin is used for the insulating film 127f, a region where the insulating layer 127 is not formed in a later step is irradiated with visible light or ultraviolet rays. The insulating layer 127 is formed in regions that are interposed between any two of the conductive layer 152R, the conductive layer 152G, and the conductive layer 152B and around the conductive layer 152C. Accordingly, irradiation with visible light or ultraviolet rays is performed over the conductive layer 152R, the conductive layer 152G, the conductive layer 152B, and the conductive layer 152C. Note that when a negative photosensitive material is used for the insulating film 127f, the region where the insulating layer 127 is to be formed is irradiated with visible light or ultraviolet rays.

The width of the insulating layer 127 formed later can be controlled in accordance with the exposed region of the insulating film 127f. In this embodiment, processing is performed such that the insulating layer 127 includes a portion overlapping with the top surface of the conductive layer 151.

Light used for the exposure preferably includes the i-line (wavelength: 365 nm). The light used for the exposure may include at least one of the g-line (wavelength: 436 nm) and the h-line (wavelength: 405 nm).

Here, when a barrier insulating layer against oxygen (such as an aluminum oxide film) is provided as one or both of the sacrificial layer 158 (the sacrificial layer 158R, the sacrificial layer 158G, and the sacrificial layer 158B) and the inorganic insulating film 125f, diffusion of oxygen into the organic compound layer 103R, the organic compound layer 103G, and the organic compound layer 103B can be inhibited. When the organic compound layer is irradiated with light (visible light or ultraviolet rays), an organic compound contained in the organic compound layer is brought into an excited state and a reaction between the organic compound and oxygen in the atmosphere is promoted in some cases. Specifically, when the organic compound layer is irradiated with light (visible light or ultraviolet rays) in an atmosphere containing oxygen, oxygen might be bonded to the organic compound contained in the organic compound layer. By providing the sacrificial layer 158 and the inorganic insulating film 125f over the island-shaped organic compound layer, bonding of oxygen in the atmosphere to the organic compound contained in the organic compound layer can be reduced.

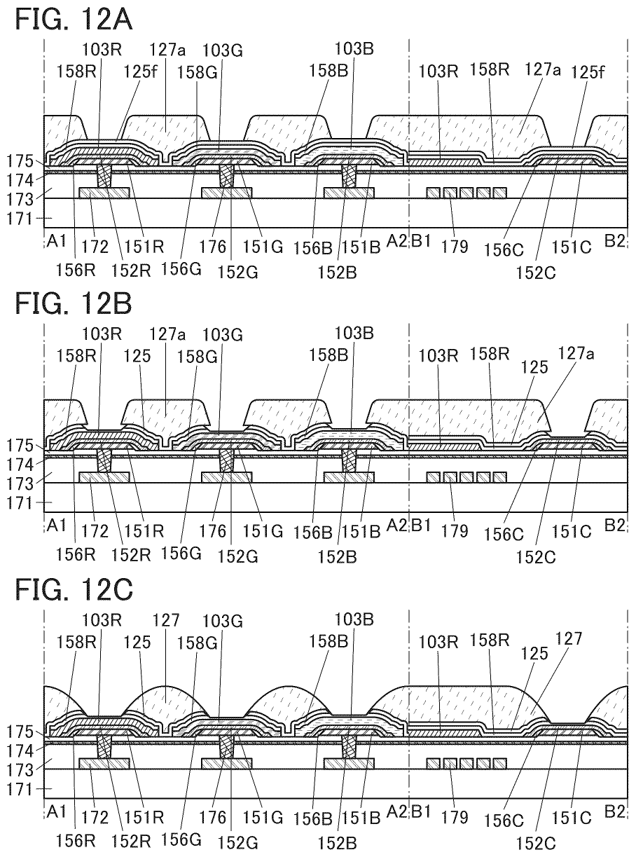

Next, as illustrated in FIG. 12A, development is performed to remove the exposed region of the insulating film 127f, so that an insulating layer 127a is formed. The insulating layer 127a is formed in regions that are interposed between any two of the conductive layer 152R, the conductive layer 152G, and the conductive layer 152B and a region surrounding the conductive layer 152C. Here, when an acrylic resin is used for the insulating film 127f, an alkaline solution, e.g., TMAH, can be used as a developer.

Then, a residue (scum) due to the development may be removed. For example, the residue can be removed by ashing using oxygen plasma.

Etching may be performed so that the surface level of the insulating layer 127a is adjusted. The insulating layer 127a may be processed by ashing using oxygen plasma, for example. In the case where a non-photosensitive material is used for the insulating film 127f, the surface level of the insulating film 127f can be adjusted by the ashing, for example.

Next, as illustrated in FIG. 12B, etching treatment is performed with the insulating layer 127a as a mask to remove part of the inorganic insulating film 125f and reduce the thickness of part of the sacrificial layer 158R, the sacrificial layer 158G, and the sacrificial layer 158B. Thus, the inorganic insulating layer 125 is formed under the insulating layer 127a. Moreover, the surfaces of the thin portions in the sacrificial layer 158R, the sacrificial layer 158G, and the sacrificial layer 158B are exposed. Note that the etching treatment using the insulating layer 127a as a mask may be hereinafter referred to as first etching treatment.

The first etching treatment can be performed by dry etching or wet etching. Note that the inorganic insulating film 125f is preferably formed using a material similar to that of the sacrificial layer 158R, the sacrificial layer 158G, and the sacrificial layer 158B, in which case the first etching treatment can be performed collectively.

By etching using the insulating layer 127a with a tapered side surface as a mask, the side surface of the inorganic insulating layer 125 and upper end portions of the side surfaces of the sacrificial layer 158R, the sacrificial layer 158G, and the sacrificial layer 158B can be made to have a tapered shape relatively easily.

In the case of performing dry etching, a chlorine-based gas is preferably used. As the chlorine-based gas, one of Cl₂, BCl₃, SiCl₄, CCl₄, and the like or a mixture of two or more of them can be used. Moreover, one of an oxygen gas, a hydrogen gas, a helium gas, an argon gas, and the like or a mixture of two or more of the gases can be added to the chlorine-based gas as appropriate. By the dry etching, the thin regions of the sacrificial layer 158R, the sacrificial layer 158G, and the sacrificial layer 158B can be formed with favorable in-plane uniformity.

As a dry etching apparatus, a dry etching apparatus including a high-density plasma source can be used. As the dry etching apparatus including a high-density plasma source, an inductively coupled plasma (ICP) etching apparatus can be used, for example. Alternatively, a capacitively coupled plasma (CCP) etching apparatus including parallel plate electrodes can be used. The capacitively coupled plasma etching apparatus including the parallel plate electrodes may have a structure in which a high-frequency voltage is applied to one of the parallel plate electrodes. Alternatively, a structure may be employed in which different high-frequency voltages are applied to one of the parallel plate electrodes. Alternatively, a structure may be employed in which high-frequency voltages with the same frequency are applied to the parallel plate electrodes. Alternatively, a structure may be employed in which high-frequency voltages with different frequencies are applied to the parallel plate electrodes.

In the case of performing dry etching, a by-product or the like generated by the dry etching might be deposited on the top surface and the side surface of the insulating layer 127a. Thus, a component contained in the etching gas, a component contained in the inorganic insulating film 125f, components contained in the sacrificial layer 158R, the sacrificial layer 158G, and the sacrificial layer 158B, or the like might be contained in the insulating layer 127 after the display device is completed.

The first etching treatment is preferably performed by wet etching. Using a wet etching method can reduce damage to the organic compound layer 103R, the organic compound layer 103G, and the organic compound layer 103B, as compared to the case of using a dry etching method. Wet etching can be performed using an alkaline solution, for example. For instance, TMAH, which is an alkaline solution, can be used for wet etching of an aluminum oxide film. In that case, paddle wet etching can be performed. Note that the inorganic insulating film 125f is preferably formed using a material similar to that of the sacrificial layer 158R, the sacrificial layer 158G, and the sacrificial layer 158B, in which case the etching treatment can be performed collectively.

In the first etching treatment, the etching treatment is stopped when the sacrificial layer 158R, the sacrificial layer 158G, and the sacrificial layer 158B are thinned before the sacrificial layers are completely removed. The sacrificial layers 158R, 158G, and 158B remain over the corresponding organic compound layers 103R, 103G, and 103B in this manner, whereby the organic compound layers 103R, 103G, and 103B can be prevented from being damaged by treatment in a later step.

Next, light exposure is preferably performed on the entire substrate so that the insulating layer 127a is irradiated with visible light or ultraviolet rays. The energy density for the light exposure is preferably greater than 0 mJ/cm² and less than or equal to 800 mJ/cm², further preferably greater than 0 mJ/cm² and less than or equal to 500 mJ/cm². Performing such light exposure after the development can sometimes increase the degree of transparency of the insulating layer 127a. In addition, it is sometimes possible to lower the substrate temperature required for subsequent heat treatment for changing the shape of the insulating layer 127a into a tapered shape.

Here, when a barrier insulating layer against oxygen (such as an aluminum oxide film) is provided as each of the sacrificial layer 158R, the sacrificial layer 158G, and the sacrificial layer 158B, diffusion of oxygen into the organic compound layer 103R, the organic compound layer 103G, and the organic compound layer 103B can be inhibited. When the organic compound layer is irradiated with light (visible light or ultraviolet rays), an organic compound contained in the organic compound layer is brought into an excited state and a reaction between the organic compound and oxygen in the atmosphere is promoted in some cases. Specifically, when the organic compound layer is irradiated with light (visible light or ultraviolet rays) in an atmosphere containing oxygen, oxygen might be bonded to the organic compound contained in the organic compound layer. By providing the sacrificial layer 158R, the sacrificial layer 158G, and the sacrificial layer 158B over the island-shaped organic compound layer, bonding of oxygen in the atmosphere to the organic compound contained in the organic compound layer can be reduced.

Then, heat treatment (also referred to as post-baking) is performed. The heat treatment can change the insulating layer 127a into the insulating layer 127 with a tapered side surface (FIG. 12C). The heat treatment is performed at a temperature lower than the upper temperature limit of the organic compound layer. The heat treatment can be performed at a substrate temperature higher than or equal to 50° C. and lower than or equal to 200° C., preferably higher than or equal to 60° C. and lower than or equal to 150° C., further preferably higher than or equal to 70° C. and lower than or equal to 130° C. The heating atmosphere may be an air atmosphere or an inert gas atmosphere. Moreover, the heating atmosphere may be an atmospheric-pressure atmosphere or a reduced-pressure atmosphere. The heat treatment in this step is preferably performed at a higher substrate temperature than the heat treatment (pre-baking) after the formation of the insulating film 127f. Accordingly, adhesion between the insulating layer 127 and the inorganic insulating layer 125 can be improved, and corrosion resistance of the insulating layer 127 can be increased.

When the sacrificial layer 158R, the sacrificial layer 158G, and the sacrificial layer 158B are not completely removed by the first etching treatment and the sacrificial layer 158R, the sacrificial layer 158G, and the sacrificial layer 158B with reduced thicknesses remain, the organic compound layer 103R, the organic compound layer 103G, and the organic compound layer 103B can be prevented from being damaged and deteriorating in the heat treatment Thus, the reliability of the light-emitting device can be increased.

The side surface of the insulating layer 127 might have a concave shape depending on the material of the insulating layer 127, and the temperature, time, and atmosphere of the post-baking. For example, the insulating layer 127 is more likely to be changed in shape to have a concave shape as the post-baking is performed at higher temperature or for a longer time.

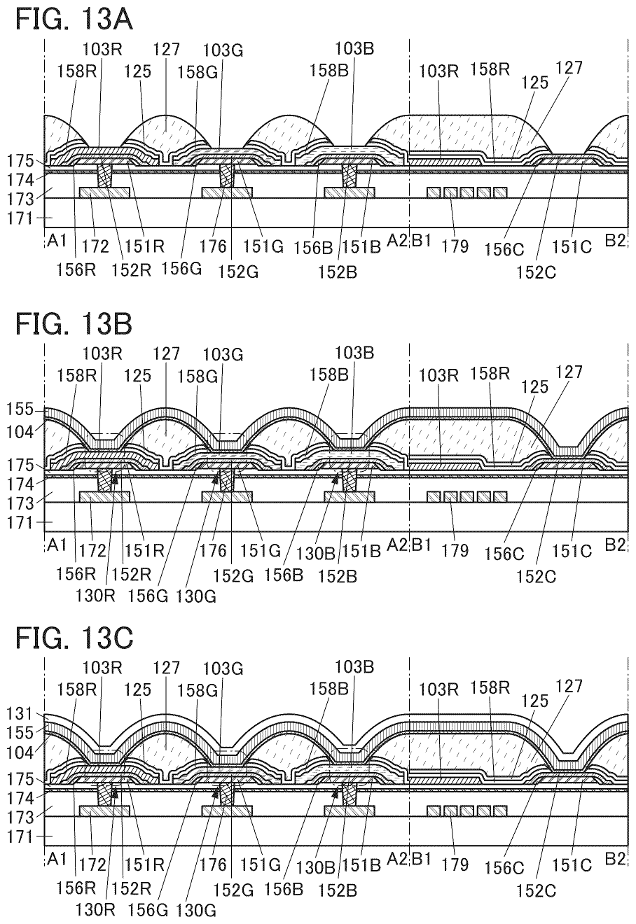

Next, as illustrated in FIG. 13A, etching treatment is performed with the insulating layer 127 as a mask to remove part of the sacrificial layer 158R, the sacrificial layer 158G, and the sacrificial layer 158B. Note that part of the inorganic insulating layer 125 is also removed in some cases. Thus, openings are formed in the sacrificial layer 158R, the sacrificial layer 158G, and the sacrificial layer 158B, and the top surfaces of the organic compound layer 103R, the organic compound layer 103G, and the organic compound layer 103B and the conductive layer 152C are exposed. Note that the etching treatment using the insulating layer 127 as a mask may be hereinafter referred to as second etching treatment.

The end portion of the inorganic insulating layer 125 is covered with the insulating layer 127. FIG. 13A illustrate an example where part of the end portion of the sacrificial layer 158G (specifically, a tapered portion formed by the first etching treatment) is covered with the insulating layer 127 and the tapered portion formed by the second etching treatment is exposed.

If the first etching treatment is not performed and the inorganic insulating layer 125 and the sacrificial layer are collectively etched after the post-baking, the inorganic insulating layer 125, the sacrificial layer 158R, the sacrificial layer 158G, and the sacrificial layer 158B under the end portion of the insulating layer 127 are eliminated by side etching and accordingly a cavity is formed in some cases. The cavity causes unevenness of the surface where the common electrode 155 is formed, so that step disconnection is likely to occur in the common electrode 155. Even when a cavity is formed owing to side etching of the inorganic insulating layer 125, the sacrificial layer 158R, the sacrificial layer 158G, and the sacrificial layer 158B by the first etching treatment, the post-baking performed subsequently can make the insulating layer 127 fill the cavity. After that, the sacrificial layer 158R, the sacrificial layer 158G, and the sacrificial layer 158B having a smaller thickness is etched by the second etching treatment; thus, the amount of side etching decreases, a cavity is less likely to be formed, and even if a cavity is formed, it can be extremely small. Therefore, the surface where the common electrode 155 is formed can be flatter.

Note that the insulating layer 127 may cover the entire end portion of the sacrificial layer 158G. For example, the end portion of the insulating layer 127 may sag and cover the end portion of the sacrificial layer 158G. As another example, the end portion of the insulating layer 127 may be in contact with the top surface of at least one of the organic compound layer 103R, the organic compound layer 103G, and the organic compound layer 103B. As described above, in the case where light exposure is not performed on the insulating layer 127a after development, the shape of the insulating layer 127 is likely to change in some cases.

The second etching treatment is performed by wet etching. Using a wet etching method can reduce damage to the organic compound layer 103R, the organic compound layer 103G, and the organic compound layer 103B, as compared to the case of using a dry etching method. The wet etching can be performed using an alkaline solution such as TMAH, for example.

Meanwhile, in the case where the second etching treatment is performed by a wet etching method and gaps due to, for example, poor adhesion between the organic compound layer 103 and another layer exist at the interface between the organic compound layer 103 and the sacrificial layer 158, the interface between the organic compound layer 103 and the inorganic insulating layer 125, and the interface between the organic compound layer 103 and the insulating layer 175, the chemical solution used in the second etching treatment sometimes enters the gaps to come into contact with the pixel electrode. Here, when the chemical solution comes into contact with both the conductive layer 151 and the conductive layer 152, one of the conductive layer 151 and the conductive layer 152 that has a lower spontaneous potential than the other suffers from galvanic corrosion in some cases. For example, when the conductive layer 151 is formed using aluminum and the conductive layer 152 is formed using indium tin oxide, the conductive layer 152 sometimes corrodes. This might decrease the yield of the display device and might degrade the reliability of the display device.

The conductive layer 152 is formed to cover the top surface and the side surface of the conductive layer 151 as described above; thus, even when gaps exist at the interface between the organic compound layer 103 and the sacrificial layer 158, the interface between the organic compound layer 103 and the inorganic insulating layer 125, and the interface between the organic compound layer 103 and the insulating layer 175, the chemical solution can be prevented from coming into contact with the conductive layer 151 in the second etching treatment. Thus, corrosion of the pixel electrode, e.g., the conductive layer 152, can be prevented.

Furthermore, when the insulating layer 156 is formed to include a region overlapping with the side surface of the conductive layer 151 and the conductive layer 152 is formed to cover the conductive layer 151 and the insulating layer 156, step disconnection in the conductive layer 152 can be prevented, whereby the chemical solution can be prevented from coming into contact with the conductive layer 151 in the second etching treatment, for example. Thus, corrosion of the pixel electrode, e.g., the conductive layer 152, can be prevented.

As described above, by providing the insulating layer 127, the inorganic insulating layer 125, the sacrificial layer 158R, the sacrificial layer 158G, and the sacrificial layer 158B, a connection defect due to a disconnected portion and an increase in electrical resistance due to a locally thinned portion can be inhibited from occurring in the common electrode 155 between the light-emitting devices. Thus, the display device of one embodiment of the present invention can have improved display quality.

Heat treatment is performed after part of the organic compound layer 103R, the organic compound layer 103G, and the organic compound layer 103B is exposed. The heat treatment can remove water included in the organic compound layers, water adsorbed onto surfaces of the organic compound layers, and the like. Furthermore, water included in the intermediate layer, which is an intermediate layer including an alkali metal or an alkali metal compound included in each of the organic compound layers can be removed. The shape of the insulating layer 127 may be changed by the heat treatment. Specifically, the insulating layer 127 may be extended to cover at least one of the end portion of the inorganic insulating layer 125, the end portions of the sacrificial layer 158R, the sacrificial layer 158G, and the sacrificial layer 158B, and the top surfaces of the organic compound layer 103R, the organic compound layer 103G, and the organic compound layer 103B.

When the temperature of the heat treatment is too low, water included in the organic compound layers, water adsorbed onto the surfaces of the organic compound layers, water included in the intermediate layer including an alkali metal or an alkali metal compound, and the like cannot be sufficiently removed. When the temperature of the heat treatment is too high, the organic compound layers 103 might deteriorate and the insulating layer 127 might change in shape excessively. Thus, the temperature of the heat treatment is preferably higher than the temperature at which water is released from the organic compound layers 103 and lower than the glass transition temperature of the organic compound included in the organic compound layers 103, further preferably lower than the glass transition temperature of the organic compound included in the top surfaces of the organic compound layers 103. Specifically, the heat treatment is preferably performed at a substrate temperature higher than or equal to 80° C. and lower than or equal to 130° C., preferably higher than or equal to 90° C. and lower than or equal to 120° C., further preferably higher than or equal to 100° C. and lower than or equal to 120° C., still further preferably higher than or equal to 100° C. and lower than or equal to 110° C. The heating atmosphere may be either an air atmosphere or an inert gas atmosphere. Although the heating atmosphere may be an atmospheric-pressure atmosphere or a reduced-pressure atmosphere, a reduced-pressure atmosphere is preferably employed to prevent re-adsorption of water released from the organic compound layers 103.

By the heat treatment, water included in the organic compound layer 103R, the organic compound layer 103G, and the organic compound layer 103B, water adsorbed onto the surfaces of the organic compound layers, water included in the intermediate layer including an alkali metal or an alkali metal compound, and the like can be sufficiently removed without causing deterioration of the organic compound layers and an excessive change in the shape of the insulating layer 127. This can prevent a significant increase in driving voltage and a significant decrease in current efficiency of the light-emitting device even when the intermediate layer, which is a layer including an alkali metal or an alkali metal compound, is exposed to a lithography process.

Then, as illustrated in FIG. 13B, the common the common layer 104 and the common electrode 155 is formed over the organic compound layer 103R, the organic compound layer 103G, the organic compound layer 103B, the conductive layer 152C, and the insulating layer 127. The common layer 104 and the common electrode 155 can be formed by a method such as a sputtering method or a vacuum evaporation method. The common layer 104 may be formed by an evaporation method while the common electrode 155 may be formed by a sputtering method.

Next, the protective layer 131 is formed over the common electrode 155, as illustrated in FIG. 13C. The protective layer 131 can be formed by a vacuum evaporation method, a sputtering method, a CVD method, an ALD method, or the like.

Subsequently, the substrate 120 is attached onto the protective layer 131 with the resin layer 122, whereby the display device can be manufactured. In the method of manufacturing the display device of one embodiment of the present invention, the insulating layer 156 is formed to include a region overlapping with the side surface of the conductive layer 151 and the conductive layer 152 is formed to cover the conductive layer 151 and the insulating layer 156 as described above. This can increase the yield of the display device and inhibit generation of a defect.

As described above, in the method of manufacturing a display device of one embodiment of the present invention, the island-shaped organic compound layer 103R, the island-shaped organic compound layer 103G, and the island-shaped organic compound layer 103B are formed not by using a fine metal mask but by processing a film formed over the entire surface; thus, the island-shaped layers can be formed to have a uniform thickness. Accordingly, a high-resolution display device or a display device with a high aperture ratio can be achieved. Furthermore, even when the resolution or the aperture ratio is high and the distance between the subpixels is extremely short, the organic compound layer 103R, the organic compound layer 103G, and the organic compound layer 103B can be inhibited from being in contact with each other in adjacent subpixels. As a result, generation of a leakage current between the subpixels can be inhibited. This can prevent crosstalk, so that the display device can achieve extremely high contrast. Moreover, even a display device that includes tandem light-emitting devices formed by a photolithography method can have favorable characteristics.

### Embodiment 4

In this embodiment, display devices of embodiments of the present invention are described.

The display device of this embodiment can be a high-resolution display device. Accordingly, the display device in this embodiment can be used for display portions of information terminals (wearable devices) such as watch-type and bracelet-type information terminals and display portions of wearable devices capable of being worn on a head, such as a VR device like a head-mounted display (HMD) and a glasses-type AR device.

The display device of this embodiment can be a high-definition display device or a large-sized display device. Accordingly, the display device of this embodiment can be used for display portions of electronic devices such as a digital camera, a digital video camera, a digital photo frame, a mobile phone, a portable game console, a portable information terminal, and an audio reproducing device, in addition to display portions of electronic devices with a relatively large screen, such as a television device, a desktop or notebook personal computer, a monitor of a computer and the like, digital signage, and a large game machine such as a pachinko machine.

### [Display Module]

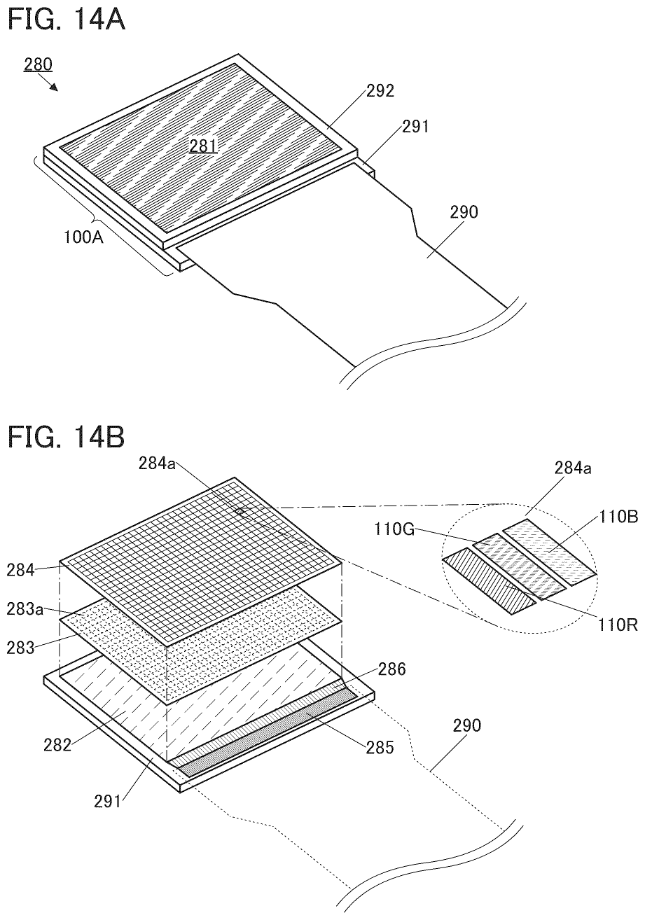

FIG. 14A is a perspective view of a display module 280. The display module 280 includes a display device 100A and an FPC 290.

The display module 280 includes a substrate 291 and a substrate 292. The display module 280 includes a display portion 281. The display portion 281 is a region of the display module 280 where an image is displayed, and is a region where light from pixels provided in a pixel portion 284 described later can be seen.

FIG. 14B is a perspective view schematically illustrating a structure on the substrate 291 side. Over the substrate 291, a circuit portion 282, a pixel circuit portion 283 over the circuit portion 282, and the pixel portion 284 over the pixel circuit portion 283 are stacked. A terminal portion 285 to be connected to the FPC 290 is provided in a portion over the substrate 291 that does not overlap with the pixel portion 284. The terminal portion 285 and the circuit portion 282 are electrically connected to each other through a wiring portion 286 formed of a plurality of wirings.

The pixel portion 284 includes a plurality of pixels 284a arranged periodically. An enlarged view of one pixel 284a is illustrated on the right side of FIG. 14B. The pixel 284a can employ any of the structures described in the above embodiments. FIG. 14B illustrates an example where the pixel 284a has a structure similar to that of the pixel 178 illustrated in FIG. 6.

The pixel circuit portion 283 includes a plurality of pixel circuits 283a arranged periodically.

One pixel circuit 283a is a circuit that controls driving of a plurality of devices included in one pixel 284a. One pixel circuit 283a can be provided with three circuits each controlling light emission of one light-emitting device. For example, the pixel circuit 283a can include at least one selection transistor, one current control transistor (driving transistor), and a capacitor for one light-emitting device. In this case, a gate signal is input to a gate of the selection transistor, and a source signal is input to a source or a drain of the selection transistor. Thus, an active-matrix display device is achieved.

The circuit portion 282 includes a circuit for driving the pixel circuits 283a in the pixel circuit portion 283. For example, one or both of a gate line driver circuit and a source line driver circuit are preferably included. In addition, at least one of an arithmetic circuit, a memory circuit, a power supply circuit, and the like may be included.

The FPC 290 functions as a wiring for supplying a video signal, a power supply potential, or the like to the circuit portion 282 from the outside. An IC may be mounted on the FPC 290.

The display module 280 can have a structure in which one or both of the pixel circuit portion 283 and the circuit portion 282 are stacked below the pixel portion 284; thus, the aperture ratio (the effective display area ratio) of the display portion 281 can be significantly high. For example, the aperture ratio of the display portion 281 can be higher than or equal to 40% and lower than 100%, preferably higher than or equal to 50% and lower than or equal to 95%, further preferably higher than or equal to 60% and lower than or equal to 95%. Furthermore, the pixels 284a can be arranged extremely densely and thus, the display portion 281 can have an extremely high resolution. For example, the pixels 284a are preferably arranged in the display portion 281 with a resolution higher than or equal to 2000 ppi, preferably higher than or equal to 3000 ppi, further preferably higher than or equal to 5000 ppi, still further preferably higher than or equal to 6000 ppi, and lower than or equal to 20000 ppi or lower than or equal to 30000 ppi.

Such a display module 280 has an extremely high resolution, and thus can be suitably used for a VR device such as an HMD or a glasses-type AR device. For example, even with a structure where the display portion of the display module 280 is seen through a lens, pixels of the extremely-high-resolution display portion 281 included in the display module 280 are prevented from being seen when the display portion is enlarged by the lens, so that display providing a high sense of immersion can be performed. Without being limited thereto, the display module 280 can be suitably used for electronic devices including a relatively small display portion. For example, the display module 280 can be favorably used in a display portion of a wearable electronic device, such as a watch.

### [Display Device 100A]

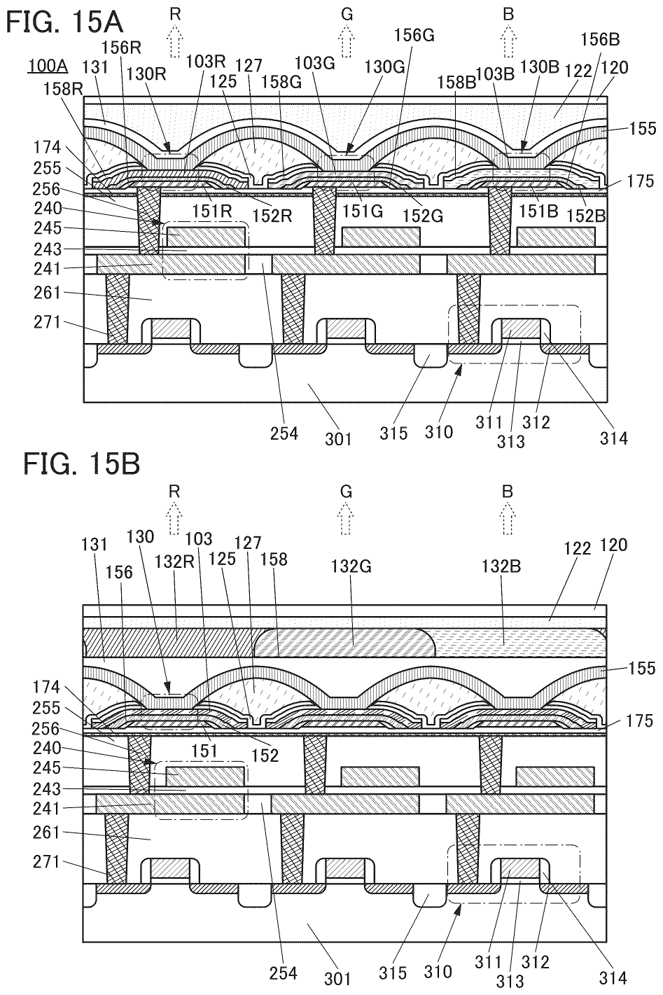

The display device 100A illustrated in FIG. 15A includes a substrate 301, the light-emitting device 130R, the light-emitting device 130G, the light-emitting device 130B, a capacitor 240, and a transistor 310.

The substrate 301 corresponds to the substrate 291 in FIG. 14A and FIG. 14B. The transistor 310 is a transistor including a channel formation region in the substrate 301. As the substrate 301, a semiconductor substrate such as a single crystal silicon substrate can be used, for example. The transistor 310 includes part of the substrate 301, a conductive layer 311, low-resistance regions 312, an insulating layer 313, and an insulating layer 314. The conductive layer 311 functions as a gate electrode. The insulating layer 313 is positioned between the substrate 301 and the conductive layer 311 and functions as a gate insulating layer. The low-resistance region 312 is a region where the substrate 301 is doped with an impurity, and functions as one of a source and a drain. The insulating layer 314 is provided to cover the side surface of the conductive layer 311.

An element isolation layer 315 is provided between two adjacent transistors 310 to be embedded in the substrate 301.

An insulating layer 261 is provided to cover the transistor 310, and the capacitor 240 is provided over the insulating layer 261.

The capacitor 240 includes a conductive layer 241, a conductive layer 245, and an insulating layer 243 positioned therebetween. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 261 and is embedded in an insulating layer 254. The conductive layer 241 is electrically connected to one of the source and the drain of the transistor 310 through a plug 271 embedded in the insulating layer 261. The insulating layer 243 is provided to cover the conductive layer 241. The conductive layer 245 is provided in a region overlapping with the conductive layer 241 with the insulating layer 243 therebetween.

An insulating layer 255 is provided to cover the capacitor 240, the insulating layer 174 is provided over the insulating layer 255, and the insulating layer 175 is provided over the insulating layer 174. The light-emitting device 130R, the light-emitting device 130G, and the light-emitting device 130B are provided over the insulating layer 175. FIG. 15A illustrates an example where the light-emitting device 130R, the light-emitting device 130G, and the light-emitting device 130B have a structure similar to the stacked-layer structure illustrated in FIG. 9A. An insulator is provided in a region between adjacent light-emitting devices. In FIG. 15A, for example, the inorganic insulating layer 125 and the insulating layer 127 over the inorganic insulating layer 125 are provided in this region.

The insulating layer 156R is provided to include a region overlapping with the side surface of the conductive layer 151R included in the light-emitting device 130R, the insulating layer 156G is provided to include a region overlapping with the side surface of the conductive layer 151G included in the light-emitting device 130G, and the insulating layer 156B is provided to include a region overlapping with the side surface of the conductive layer 151B included in the light-emitting device 130B. The conductive layer 152R is provided to cover the conductive layer 151R and the insulating layer 156R. The conductive layer 152G is provided to cover the conductive layer 151G and the insulating layer 156G. The conductive layer 152B is provided to cover the conductive layer 151B and the insulating layer 156B. The sacrificial layer 158R is positioned over the organic compound layer 103R included in the light-emitting device 130R, the sacrificial layer 158G is positioned over the organic compound layer 103G included in the light-emitting device 130G, and the sacrificial layer 158B is positioned over the organic compound layer 103B included in the light-emitting device 130B.

The conductive layer 151R, the conductive layer 151G, and the conductive layer 151B are each electrically connected to one of the source and the drain of the transistor 310 through a plug 256 embedded in the insulating layer 243, the insulating layer 255, the insulating layer 174, and the insulating layer 175, the conductive layer 241 embedded in the insulating layer 254, and the plug 271 embedded in the insulating layer 261. The level of the top surface of the insulating layer 175 is equal to or substantially equal to the level of the top surface of the plug 256. A variety of conductive materials can be used for the plugs.

The protective layer 131 is provided over the light-emitting device 130R, the light-emitting device 130G, and the light-emitting device 130B. The substrate 120 is attached to the protective layer 131 with the resin layer 122. Embodiment 3 can be referred to for details of the light-emitting devices 130 and the components thereover up to the substrate 120. The substrate 120 corresponds to the substrate 292 in FIG. 14A.

FIG. 15B illustrates a modification example of the display device 100A illustrated in FIG. 15A. The display device illustrated in FIG. 15B includes the coloring layer 132R, the coloring layer 132G, and the coloring layer 132B, and each of the light-emitting devices 130 includes a region overlapping with one of the coloring layer 132R, the coloring layer 132G, and the coloring layer 132B. In the display device illustrated in FIG. 15B, the light-emitting device 130 can emit white light, for example. For example, the coloring layer 132R can transmit red light, the coloring layer 132G can transmit green light, and the coloring layer 132B can transmit blue light. In the display device having such a structure in which the coloring layers are used, only light-emitting devices that emit white light are manufactured in the case of manufacturing a display device that is required to display a full-color image; thus, the above-described method for manufacturing the display device can be simplified.

This embodiment can be combined with the other embodiments or an example as appropriate. In this specification, in the case where a plurality of structure examples are described in one embodiment, the structure examples can be combined as appropriate.

### Embodiment 5

In this embodiment, electronic devices of one embodiment of the present invention will be described.

Electronic devices of this embodiment each include the display device of one embodiment of the present invention in a display portion. The display device of one embodiment of the present invention is highly reliable and can be easily increased in resolution and definition. Thus, the display device of one embodiment of the present invention can be used for a display portion of a variety of electronic devices.

Examples of the electronic devices include electronic devices with a relatively large screen, such as a television device, a desktop or notebook personal computer, a monitor of a computer or the like, digital signage, and a large game machine such as a pachinko machine; a digital camera; a digital video camera; a digital photo frame; a mobile phone; a portable game console; a portable information terminal; and an audio reproducing device.

In particular, the display device of one embodiment of the present invention can have a high resolution, and thus can be suitably used for an electronic device having a relatively small display portion. Examples of such an electronic device include a watch-type or a bracelet-type information terminal device (wearable device), and a wearable device worn on a head, such as a device for VR such as a head-mounted display, a glasses-type device for AR, and a device for MR.

The definition of the display device of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, a definition of 4K, 8K, or higher is preferable. The pixel density (resolution) of the display device of one embodiment of the present invention is preferably higher than or equal to 100 ppi, further preferably higher than or equal to 300 ppi, still further preferably higher than or equal to 500 ppi, yet still further preferably higher than or equal to 1000 ppi, yet still further preferably higher than or equal to 2000 ppi, yet still further preferably higher than or equal to 3000 ppi, yet still further preferably higher than or equal to 5000 ppi, yet still further preferably higher than or equal to 7000 ppi. With the use of such a display device having one or both of high definition and high resolution, the electronic device can provide higher realistic sensation, sense of depth, and the like in personal use such as portable use and home use. There is no particular limitation on the screen ratio (aspect ratio) of the display device of one embodiment of the present invention. For example, the display device is compatible with a variety of screen ratios such as 1:1 (a square), 4:3, 16:9, and 16:10.

The electronic device in this embodiment may include a sensor (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, odor, or infrared rays).

The electronic device in this embodiment can have a variety of functions. For example, the electronic device can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

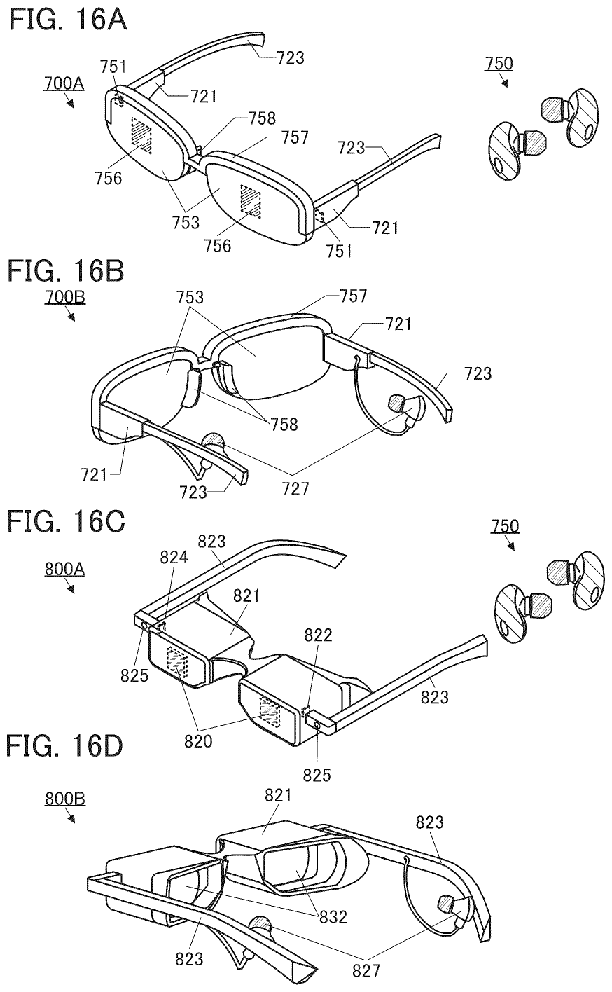

Examples of a wearable device that can be worn on a head are described with reference to FIG. 16A to FIG. 16D. These wearable devices have at least one of a function of displaying AR contents, a function of displaying VR contents, a function of displaying SR contents, and a function of displaying MR contents. The electronic device having a function of displaying contents of at least one of AR, VR, SR, MR, and the like enables the user to feel a higher sense of immersion.

An electronic device 700A illustrated in FIG. 16A and an electronic device 700B illustrated in FIG. 16B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display device of one embodiment of the present invention can be used for the display panel 751. Thus, a highly reliable electronic device is obtained.

The electronic device 700A and the electronic device 700B can each project images displayed on the display panels 751 onto display regions 756 of the optical members 753. Since the optical members 753 have a light-transmitting property, a user can see images displayed on the display regions, which are superimposed on transmission images seen through the optical members 753. Accordingly, the electronic device 700A and the electronic device 700B are electronic devices capable of AR display.

In the electronic device 700A and the electronic device 700B, a camera capable of capturing images of the front side may be provided as the image capturing portion. Furthermore, when the electronic device 700A and the electronic device 700B are provided with an acceleration sensor such as a gyroscope sensor, the orientation of the user's head can be sensed and an image corresponding to the orientation can be displayed on the display regions 756.

The communication portion includes a wireless communication device, and a picture signal, for example, can be supplied by the wireless communication device. Instead of or in addition to the wireless communication device, a connector that can be connected to a cable for supplying a video signal and a power supply potential may be provided.

The electronic device 700A and the electronic device 700B are provided with a battery so that they can be charged wirelessly and/or by wire.

A touch sensor module may be provided in the housing 721. The touch sensor module has a function of detecting a touch on the outer surface of the housing 721. Detecting a tap operation, a slide operation, or the like by the user with the touch sensor module enables executing various types of processing. For example, processing such as a pause or a restart of a moving image can be executed by a tap operation, and processing such as fast forward and fast rewind can be executed by a slide operation. When the touch sensor module is provided in each of the two housings 721, the range of the operation can be increased.

Any of various touch sensors can be applied to the touch sensor module. For example, any of touch sensors of the following types can be used: a capacitive type, a resistive type, an infrared type, an electromagnetic induction type, a surface acoustic wave type, and an optical type. In particular, a capacitive sensor or an optical sensor is preferably used for the touch sensor module.

In the case of using an optical touch sensor, a photoelectric conversion device (also referred to as a photoelectric conversion element) can be used as a light-receiving device. One or both of an inorganic semiconductor and an organic semiconductor can be used for an active layer of the photoelectric conversion device.

An electronic device 800A illustrated in FIG. 16C and an electronic device 800B illustrated in FIG. 16D each include a pair of display portions 820, a housing 821, a communication portion 822, a pair of wearing portions 823, a control portion 824, a pair of image capturing portions 825, and a pair of lenses 832.

A display device of one embodiment of the present invention can be used in the display portions 820. Thus, a highly reliable electronic device is obtained.

The display portions 820 are positioned inside the housing 821 so as to be seen through the lenses 832. When the pair of display portions 820 display different images, three-dimensional display using parallax can be performed.

The electronic device 800A and the electronic device 800B can be regarded as electronic devices for VR. The user who wears the electronic device 800A or the electronic device 800B can see images displayed on the display portions 820 through the lenses 832.

The electronic device 800A and the electronic device 800B preferably include a mechanism for adjusting the lateral positions of the lenses 832 and the display portions 820 so that the lenses 832 and the display portions 820 are positioned optimally in accordance with the positions of the user's eyes. Moreover, the electronic device 800A and the electronic device 800B preferably include a mechanism for adjusting focus by changing the distance between the lenses 832 and the display portions 820.

The electronic device 800A or the electronic device 800B can be mounted on the user's head with the wearing portions 823. Note that FIG. 16C illustrates an example in which the wearing portion 823 has a shape like a temple (also referred to as a joint or the like) of glasses; however, one embodiment of the present invention is not limited thereto. The wearing portion 823 can have any shape with which the user can wear the electronic device, for example, a shape of a helmet or a band.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to cover a plurality of fields of view, such as a telescope field of view and a wide field of view.

Although an example where the image capturing portions 825 are provided is described here, a range sensor capable of measuring a distance from an object (hereinafter also referred to as a sensing portion) just needs to be provided. In other words, the image capturing portion 825 is one embodiment of the sensing portion. As the sensing portion, an image sensor or a distance image sensor such as LIDAR (Light Detection and Ranging) can be used, for example. By using images obtained by the camera and images obtained by the range image sensor, more information can be obtained and a gesture operation with higher accuracy is possible.

The electronic device 800A may include a vibration mechanism that functions as bone-conduction earphones. For example, any one or more of the display portion 820, the housing 821, and the wearing portion 823 can employ a structure including the vibration mechanism. Thus, without additionally requiring an audio device such as headphones, earphones, or a speaker, the user can enjoy video and sound only by wearing the electronic device 800A.

The electronic device 800A and the electronic device 800B may each include an input terminal. To the input terminal, a cable for supplying, a video signal from a video output device or the like, power for charging a battery provided in the electronic device, and the like can be connected.

The electronic device of one embodiment of the present invention may have a function of performing wireless communication with earphones 750. The earphones 750 include a communication portion (not illustrated) and have a wireless communication function. The earphones 750 can receive information (e.g., audio data) from the electronic device with the wireless communication function. For example, the electronic device 700A in FIG. 16A has a function of transmitting information to the earphones 750 with the wireless communication function. For another example, the electronic device 800A illustrated in FIG. 16C has a function of transmitting information to the earphones 750 with the wireless communication function.

The electronic device may include an earphone portion. The electronic device 700B in FIG. 16B includes earphone portions 727. For example, the earphone portion 727 and the control portion can be connected to each other by wire. Part of a wiring that connects the earphone portion 727 and the control portion may be positioned inside the housing 721 or the wearing portion 723.

Similarly, the electronic device 800B illustrated in FIG. 16D includes earphone portions 827. For example, the earphone portion 827 and the control portion 824 can be connected to each other by wire. Part of a wiring that connects the earphone portion 827 and the control portion 824 may be positioned inside the housing 821 or the wearing portion 823. Alternatively, the earphone portions 827 and the wearing portions 823 may include magnets. This is preferable because the earphone portions 827 can be fixed to the wearing portions 823 with magnetic force and thus can be easily housed.

The electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of what is called a headset by including the audio input mechanism.

As described above, both the glasses-type device (e.g., the electronic device 700A and the electronic device 700B) and the goggles-type device (e.g., the electronic device 800A and the electronic device 800B) are preferable as the electronic device of one embodiment of the present invention.

The electronic device of one embodiment of the present invention can transmit information to earphones by wire or wirelessly.

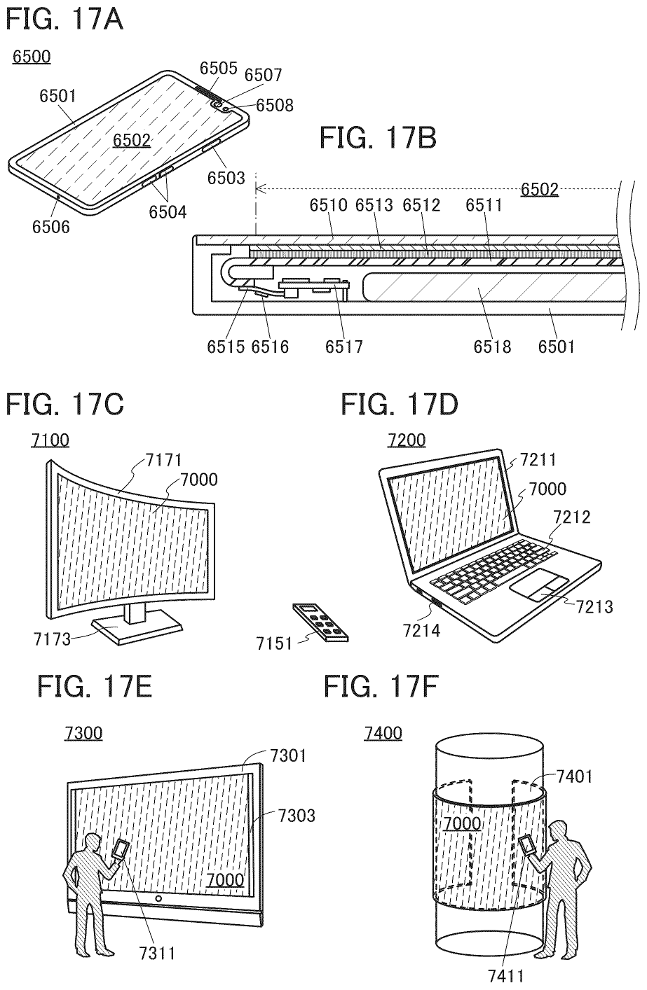

An electronic device 6500 illustrated in FIG. 17A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display device of one embodiment of the present invention can be used in the display portion 6502. Thus, a highly reliable electronic device is obtained.

FIG. 17B is a schematic cross-sectional view including an end portion of the housing 6501 on the microphone 6506 side.

A protection member 6510 having a light-transmitting property is provided on a display surface side of the housing 6501, and a display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A display device of one embodiment of the present invention can be used as the display panel 6511. Thus, an extremely lightweight electronic device can be achieved. Since the display panel 6511 is extremely thin, the battery 6518 with high capacity can be mounted without an increase in the thickness of the electronic device. Moreover, part of the display panel 6511 is folded back so that a connection portion with the FPC 6515 is provided on the back side of a pixel portion, whereby an electronic device with a narrow bezel can be achieved.

FIG. 17C illustrates an example of a television device. In a television device 7100, a display portion 7000 is incorporated in a housing 7171. Here, the housing 7171 is supported by a stand 7173.

The display device of one embodiment of the present invention can be used in the display portion 7000. Thus, a highly reliable electronic device is obtained.

Operation of the television device 7100 illustrated in FIG. 17C can be performed with an operation switch provided in the housing 7171 and a separate remote control 7151. Alternatively, the display portion 7000 may include a touch sensor, and the television device 7100 may be operated by touch on the display portion 7000 with a finger or the like. The remote control 7151 may be provided with a display portion for displaying information output from the remote control 7151. With operation keys or a touch panel provided in the remote control 7151, channels and volume can be controlled and videos displayed on the display portion 7000 can be operated.

Note that the television device 7100 has a structure in which a receiver, a modem, and the like are provided. A general television broadcast can be received with the receiver. When the television device is connected to a communication network by wire or wirelessly via the modem, one-way (from a transmitter to a receiver) or two-way (between a transmitter and a receiver or between receivers, for example) data communication can be performed.

FIG. 17D illustrates an example of a notebook personal computer. A notebook personal computer 7200 includes a housing 7211, a keyboard 7212, a pointing device 7213, an external connection port 7214, and the like. In the housing 7211, the display portion 7000 is incorporated.

The display device of one embodiment of the present invention can be used in the display portion 7000. Thus, a highly reliable electronic device is obtained.

FIG. 17E and FIG. 17F illustrate examples of digital signage.

Digital signage 7300 illustrated in FIG. 17E includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 17F is digital signage 7400 attached to a cylindrical pillar 7401. The digital signage 7400 includes the display portion 7000 provided along a curved surface of the pillar 7401.

The display device of one embodiment of the present invention can be used for the display portion 7000 illustrated in each of FIG. 17E and FIG. 17F. Thus, a highly reliable electronic device is obtained.

A larger area of the display portion 7000 can increase the amount of information that can be provided at a time. The larger display portion 7000 attracts more attention, so that the effectiveness of the advertisement can be increased, for example.

A touch panel is preferably used in the display portion 7000, in which case intuitive operation by a user is possible in addition to display of an image or a moving image on the display portion 7000. Moreover, for an application for providing information such as route information or traffic information, usability can be enhanced by intuitive operation.

As illustrated in FIG. 17E and FIG. 17F, it is preferable that the digital signage 7300 or the digital signage 7400 can work with an information terminal 7311 or an information terminal 7411 such as a smartphone a user has through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with the use of the screen of the information terminal 7311 or the information terminal 7411 as an operation means (controller). Thus, an unspecified number of users can join in and enjoy the game concurrently.

This embodiment can be combined with the other embodiments or an example as appropriate. In the case where a plurality of structure examples are described in one embodiment in this specification, the structure examples can be combined as appropriate.

### Example 1

In this example, the characteristics of a tandem light-emitting device obtained by the method for manufacturing a light-emitting device of one embodiment of the present invention are described in comparison between a light-emitting device 1 to a light-emitting device 4 and a comparative light-emitting device 5. Structural formulae of organic compounds used in this example are shown below.

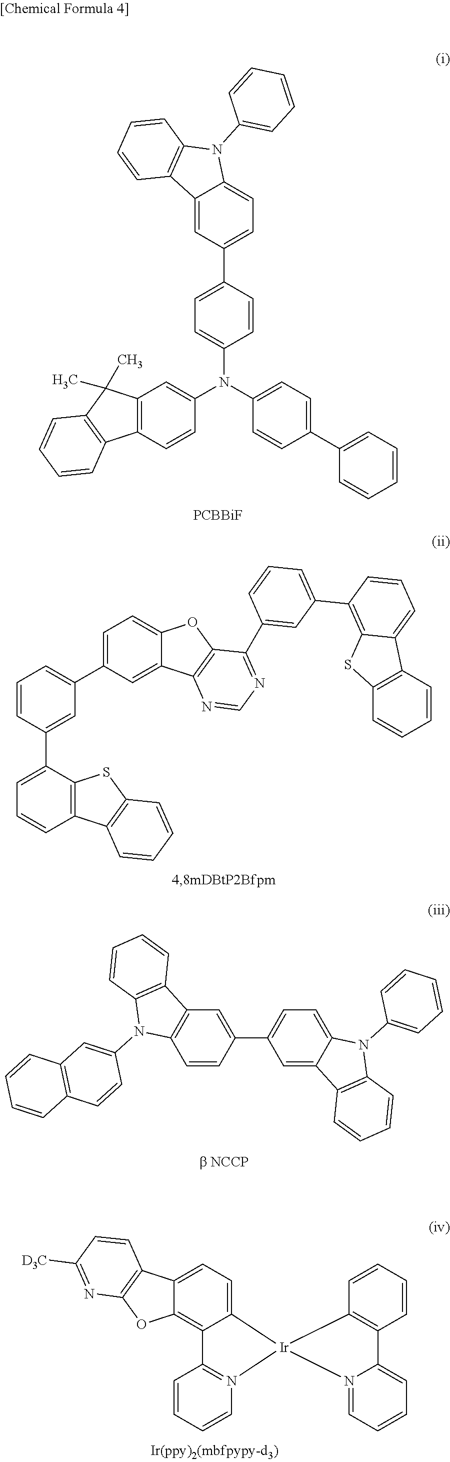

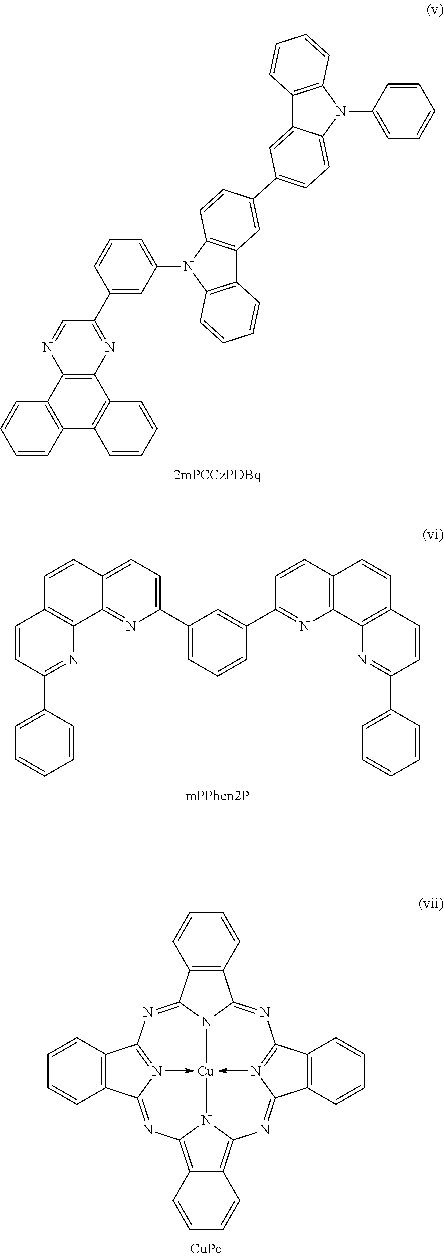

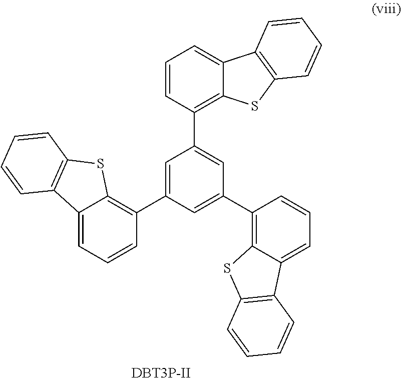 [SMILES: c1ccc2c(c1)sc1c(-c3cc(-c4cccc5c4sc4ccccc45)cc(-c4cccc5c4sc4ccccc45)c3)cccc12 ; "DBT3P-II"]

### (Method for Manufacturing Light-Emitting Device 1)

First, as a reflective electrode, an alloy containing silver (Ag), palladium (Pd), and copper (Cu) (abbreviation: APC) was formed over a glass substrate to a thickness of 100 nm by a sputtering method, and then, as a transparent electrode, indium tin oxide containing silicon oxide (ITSO) was formed to a thickness of 100 nm by a sputtering method, whereby the first electrode 101 was formed. The electrode area was set to 4 mm² (2 mm×2 mm). Note that the transparent electrode functions as an anode, and the transparent electrode and the reflective electrode can be collectively regarded as the first electrode 101.

Next, in pretreatment for forming the light-emitting device over the substrate, the surface of the substrate was washed with water and baked at 200° C. for 1 hour, and then UV ozone treatment was performed for 370 seconds.

After that, the substrate was transferred into a vacuum evaporation apparatus where the pressure was reduced to approximately 10⁻⁴ Pa, heat treatment was performed at 170° C. for 30 minutes in a heating chamber of the vacuum evaporation apparatus, and then the substrate was cooled down for approximately 30 minutes.

Then, the substrate provided with the first electrode 101 was fixed to a substrate holder provided in the vacuum evaporation apparatus such that the surface over which the first electrode 101 was formed faced downward. Over the first electrode 101, N-(biphenyl-4-yl)-N-[4-(9-phenyl-9H-carbazol-3-yl)phenyl]-9,9-dimethyl-9H-fluoren-2-amine (abbreviation: PCBBiF) represented by Structural Formula (i) above and a fluorine-containing electron-acceptor material with a molecular weight of 672 (OCHD-003) were deposited by co-evaporation to a thickness of 10 nm such that the weight ratio of PCBBiF to OCHD-003 was 1:0.03, whereby a hole-injection layer was formed.

Over the hole-injection layer, PCBBiF was deposited by evaporation to a thickness of 70 nm, whereby a first hole-transport layer was formed.

Then, over the first hole-transport layer, 4,8-bis[3-(dibenzothiophen-4-yl)phenyl]-[1]benzofuro[3,2-d]pyrimidine (abbreviation: 4,8mDBtP2Bfpm) represented by Structural Formula (ii) above, 9-(2-naphthyl)-9′-phenyl-9H,9′H-3,3′-bicarbazole (abbreviation: βNCCP) represented by Structural Formula (iii) above, and [2-d₃-methyl-(2-pyridinyl-KM)benzofuro[2,3-b]pyridine-κC]bis[2-(2-pyridinyl-κN)phenyl-κC]iridium(III) (abbreviation: Ir(ppy)₂(mbfpypy-d₃)) represented by Structural Formula (iv) above were deposited by co-evaporation to a thickness of 40 nm such that the weight ratio of 4,8mDBtP2Bfpm to βNCCP and Ir(ppy)₂(mbfpypy-d₃) was 0.5:0.5:0.1, whereby a first light-emitting layer was formed.

Next, 2-{3-[3-(N-phenyl-9H-carbazol-3-yl)-9H-carbazol-9-yl]phenyl}dibenzo[f,h]quinoxaline (abbreviation: 2mPCCzPDBq) represented by Structural Formula (v) above was deposited by evaporation to a thickness of 10 nm, whereby a first electron-transport layer was formed.

After the formation of the first electron-transport layer, 2,2′-(1,3-phenylene)bis(9-phenyl-1,10-phenanthroline) (abbreviation: mPPhen2P) represented by Structural Formula (vi) above was deposited by evaporation to a thickness of 20 nm, and then lithium oxide (Li₂O) was deposited by evaporation to a thickness of 0.3 nm, whereby an N-type layer was formed. Then, copper phthalocyanine (abbreviation: CuPc) represented by Structural Formula (vii) above was deposited to a thickness of 2 nm, whereby an electron-relay layer (ER layer) was formed. Furthermore, PCBBiF and OCHD-003 were deposited by co-evaporation to a thickness of 10 nm such that the weight ratio of PCBBiF to OCHD-003 was 1:0.15 to form a P-type layer, whereby an intermediate layer including the N-type layer, the ER layer, and the P-type layer was formed.

Over the intermediate layer, PCBBiF was deposited by evaporation to a thickness of 40 nm, whereby a second hole-transport layer was formed.

Over the second hole-transport layer, 4,8mDBtP2Bfpm, βNCCP, and Ir(ppy)₂(mbfpypy-d₃) were deposited by co-evaporation to a thickness of 40 nm such that the weight ratio of 4,8mDBtP2Bfpm to βNCCP and Ir(ppy)₂(mbfpypy-d₃) was 0.5:0.5:0.1, whereby a second light-emitting layer was formed.

After that, 2mPCCzPDBq was deposited by evaporation to a thickness of 20 nm and mPPhen2P was further deposited by evaporation to a thickness of 20 nm to form a second electron-transport layer, and then the organic compound layer formed up to this point (the hole-injection layer, the first hole-transport layer, the first light-emitting layer, the first electron-transport layer, the intermediate layer, the second hole-transport layer, the second light-emitting layer, and the second electron-transport layer) was processed by a photolithography method.

### <<Processing by Photolithography Method>>

First, the substrate was taken out from the vacuum evaporation apparatus and exposed to the air, and then aluminum oxide was formed to a thickness of 30 nm by an ALD method using trimethylaluminum (abbreviation: TMA) as a precursor and water vapor as an oxidizer, whereby a first sacrificial layer was formed.

Then, over the first sacrificial layer, a composite oxide containing indium, gallium, zinc, and oxygen (abbreviation: IGZO) was deposited to a thickness of 50 nm by a sputtering method, whereby a second sacrificial layer was formed.

Next, a resist was formed using a photoresist over the second sacrificial layer, and processing was performed by a lithography method to form a slit having a width of 3 μm in a position 3.5 μm away from an end portion of the first electrode.

Specifically, the second sacrificial layer was processed using a chemical solution containing a phosphoric acid with the use of the resist as a mask, and then the first sacrificial layer was processed using an etching gas containing fluoroform (CHF₃) and helium (He) at a flow rate ratio of CHF₃:He=1:9. Then, the second electron-transport layer, the second light-emitting layer, the second hole-transport layer, the intermediate layer, the first electron-transport layer, the first light-emitting layer, the first hole-transport layer, and the hole-injection layer were processed using an etching gas containing oxygen (O₂). The above are the processing steps by the photolithography method.

After the processing, the second sacrificial layer and the first sacrificial layer were removed using a chemical solution to expose the second electron-transport layer.

### <<Heat Treatment>>

After the second electron-transport layer was exposed, the substrate was transferred into a vacuum evaporation apparatus where the pressure was reduced to approximately 10⁻⁴ Pa and heat treatment was performed at 80° C. for 1 hour in a heating chamber of the vacuum evaporation apparatus.

After the cooling, the sample was transferred into the vacuum evaporation apparatus again. Over the second electron-transport layer, lithium fluoride (LiF) and ytterbium (Yb) were deposited by co-evaporation such that the volume ratio of LiF to Yb was 1:1 to form the electron-injection layer 115, and lastly silver (Ag) and magnesium (Mg) were deposited by co-evaporation to a thickness of 15 nm such that the volume ratio of Ag to Mg was 1:0.1 to form the second electrode 102, whereby the light-emitting device 1 was manufactured.

The second electrode 102 is a transflective electrode, which has a function of reflecting light and a function of transmitting light, and the light-emitting device of this example is a top-emission tandem device from which light is extracted through the second electrode 102. Over the second electrode 102, 4,4′,4″-(benzene-1,3,5-triyl)tri(dibenzothiophene) (abbreviation: DBT3P-II) represented by Structural Formula (viii) above was deposited by evaporation to a thickness of 70 nm as a cap layer so that light extraction efficiency can be improved.

### (Method for Manufacturing Light-Emitting Device 2 to Light-Emitting Device 4)

The temperature of the heat treatment performed after the second electron-transport layer was exposed after the processing steps by a photolithography method was set to 100° C. for the light-emitting device 2, 110° C. in the light-emitting device 3, and 120° C. in the light-emitting device 4. The light-emitting device 2 to the light-emitting device 4 were manufactured in a manner similar to that for the light-emitting device 1 except for the temperature of the heat treatment.

Note that in some cases, light-emitting devices in which the temperature of the heat treatment after the second sacrificial layer and the first sacrificial layer were removed and the second electron-transport layer was exposed was set to 80° C., 100° C., 110° C., and 120° C. are referred to as the light-emitting device 1 (80° C.), the light-emitting device 2 (100° C.), the light-emitting device 3 (110° C.), and the light-emitting device 4 (120° C.), respectively.

### (Method for Manufacturing Comparative Light-Emitting Device 5)

The comparative light-emitting device 5 is different from the light-emitting device 1 to the light-emitting device 4 in that the processing steps by a photolithography method in the manufacturing process of the light-emitting device 1 were omitted: the formation of the electron-injection layer to the formation of the cap layer were continuously performed after the formation of the second electron-transport layer. In other words, the comparative light-emitting device 5 was manufactured in a continuous vacuum process. The other layers were formed in a similar manner to that in the light-emitting device 1 to the light-emitting device 4.

The device structures of the light-emitting device 1 to the light-emitting device 4 and the comparative light-emitting device 5 are listed in the following table.

TABLE 1

| | | | | | |
|---|---|---|---|---|---|
| | Light-emitting | Light-emitting | Light-emitting | Light-emitting | Comparative |
| Thickness | device | device | device | device | light-emitting |
| (nm) | 1 (80° C.) | 2 (100° C.) | 3 (110° C.) | 4 (120° C.) | device 5 |

| | | |
|---|---|---|
| Cap layer | 70 | DBT3P-II |
| Second electrode | 15 | Ag:Mg (1:0.1) |
| Electron-injection layer | 2 | LiF:Yb (1:1) |

| | | | | | |
|---|---|---|---|---|---|
| Heat treatment | 80° C. | 100° C. | 110° C. | 120° C. | — |

| | | |
|---|---|---|
| Processing by photolithography method | Processing by photolithography method was performed | — |

| Second electron- | 2 | 20 | mPPhen2P |
|---|---|---|---|
| transport layer | 1 | 20 | 2mPCCzPDBq |
| Second light-emitting layer | | 40 | 4,8mDBtP2Bfpm:βNCCP:Ir(ppy)₂(mbfpypy-d₃) |
| | | | (0.5:0.5:0.1) |
| Second hole-transport layer | | 40 | PCBBiF |
| Intermediate layer | P-type layer | 10 | PCBBiF:OCHD-003 (1:0.15) |
| | ER layer | 2 | CuPc |
| | N-type layer | 0.3 | Li₂O |
| | | 20 | mPPhen2P |
| First electron-transport layer | | 10 | 2mPCCzPDBq |
| First light-emitting layer | | 40 | 4,8mDBtP2Bfpm:βNCCP:Ir(ppy)₂(mbfpypy-d₃) |
| | | | (0.5:0.5:0.1) |
| First hole-transport layer | | 70 | PCBBiF |
| Hole-injection layer | | 10 | PCBBiF:OCHD-003 (1:0.03) |
| First electrode | 2 | 100 | ITSO |
| | 1 | 100 | APC |

The light-emitting device 1 to the comparative light-emitting device 4 and the comparative light-emitting device 5 were sealed using a glass substrate in a glove box containing a nitrogen atmosphere so as not to be exposed to the air (a UV curable sealing material was applied to surround the devices, only the sealing material was irradiated with UV while the light-emitting devices were prevented from being irradiated with the UV, and heat treatment was performed at 80° C. under an atmospheric pressure for 1 hour). Then, the initial characteristics of each of the light-emitting devices were measured.

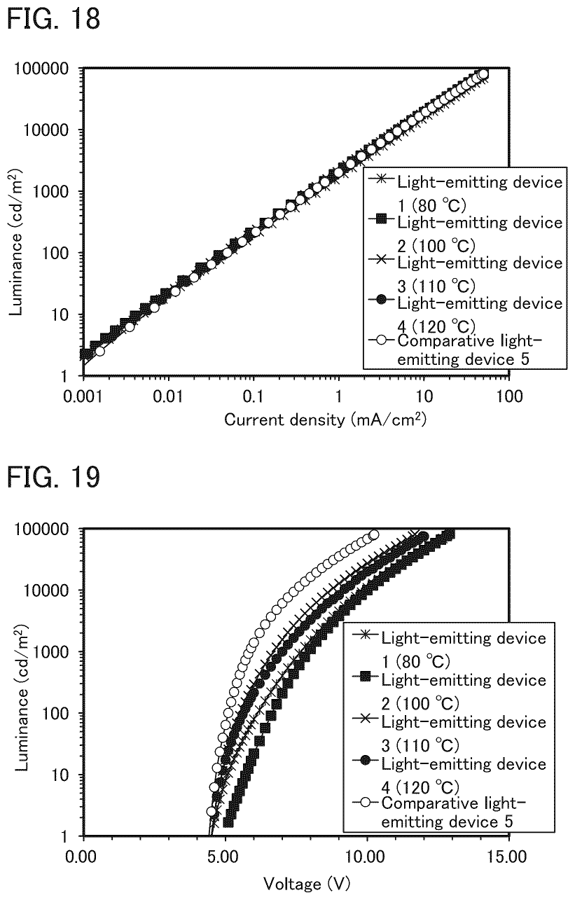

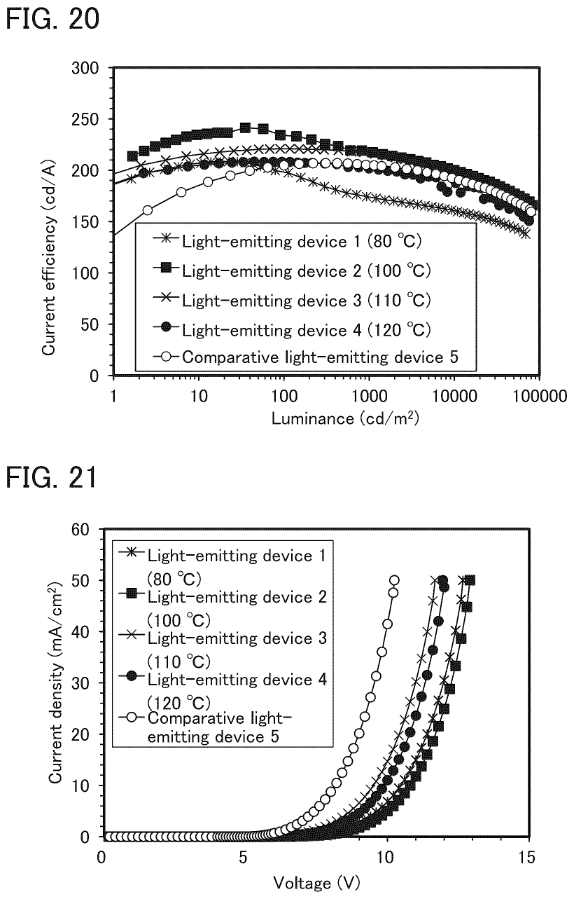

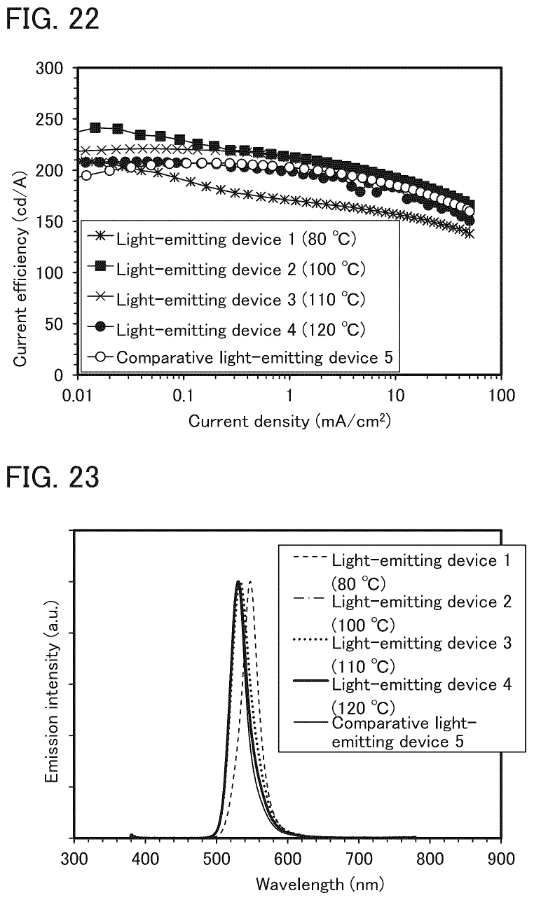

FIG. 18 shows the luminance-current density characteristics of the light-emitting device 1 to the light-emitting device 4 and the comparative light-emitting device 5. FIG. 19 shows the luminance-voltage characteristics thereof. FIG. 20 shows the current efficiency-luminance characteristics thereof. FIG. 21 shows the current density-voltage characteristics thereof. FIG. 22 shows the current efficiency-current density thereof. FIG. 23 shows the emission spectra thereof. The table below shows the main characteristics at a current density of 50 mA/cm². Note that the luminance, CIE chromaticity, and emission spectra were measured at normal temperature with a spectroradiometer (SR-UL 1R manufactured by TOPCON CORPORATION).

TABLE 2

| | | Current | | | | Current |
|---|---|---|---|---|---|---|
| | Voltage | density | Luminance | | | efficiency |
| | (V) | (mA/cm²) | (cd/m²) | Chromaticity x | Chromaticity y | (cd/A) |
| Light-emitting device 1 (80° C.) | 12.7 | 50 | 68930 | 0.313 | 0.672 | 137.9 |
| Light-emitting device 2 (100° C.) | 12.9 | 50 | 82910 | 0.244 | 0.720 | 165.8 |
| Light-emitting device 3 (110° C.) | 11.7 | 50 | 80320 | 0.258 | 0.710 | 160.6 |
| Light-emitting device 4 (120° C.) | 12.0 | 50 | 75290 | 0.240 | 0.723 | 150.6 |
| Comparative light-emitting device 5 | 10.2 | 50 | 79890 | 0.228 | 0.733 | 159.7 |

As shown in FIG. 18 to FIG. 23, the comparative light-emitting device 5, which is a light-emitting device manufactured through a continuous vacuum process without going through the processing steps by a photolithography method have favorable characteristics.

Meanwhile, FIG. 20, FIG. 22, and the above table show that the current efficiency of the light-emitting device 1 (80° C.), which is a light-emitting device that went through the processing steps by a photolithography method, is significantly decreased more than that of the comparative light-emitting device 5. In addition, the current efficiency of the light-emitting device 2 (100° C.), the light-emitting device 3 (110° C.), and the light-emitting device 4 (120° C.) is improved more than that of the light-emitting device 1 (80° C.). Accordingly, the temperature of the heat treatment after the second electron-transport layer is exposed is preferably higher than or equal to 100° C., further preferably higher than or equal to 100° C. and lower than or equal to 120° C.

In the heat treatment, the second electron-transport layer was exposed. Thus, in order to reduce damage to the organic compound included in the second electron-transport layer, the heat treatment was preferably performed at a temperature higher than or equal to 100° C. and lower than the glass transition temperature of the organic compound included in the second electron-transport layer. Note that the glass transition temperature of mPPhen2P, which is an organic compound included in the second electron-transport layer, was found to be 135° C. by differential scanning calorimetry using DSC8500 manufactured by PerkinElmer, Inc.

The low current efficiency of the light-emitting device 1 (80° C.) is due to, for example, water, oxygen, or the like that is caused by exposure of the organic compound layer including an alkali metal or a compound thereof to the air; meanwhile, when heat treatment was performed at 100° C. or higher for the light-emitting device 2 (100° C.), the light-emitting device 3 (110° C.), and the light-emitting device 4 (120° C.), water, oxygen, or the like in the organic compound layer including the alkali metal or the compound thereof was removed, whereby the current efficiency was improved.

Note that when the light-emitting device 2 (100° C.), the light-emitting device 3 (110° C.), and the light-emitting device 4 (120° C.) were compared, the light-emitting device 2 (100° C.) had the highest current efficiency and the light-emitting device 3 (110° C.) had the second highest current efficiency. Accordingly, it can be said that the temperature of the heat treatment after the second electron-transport layer is exposed is further preferably higher than or equal to 100° C. and lower than or equal to 110° C.

FIG. 19, FIG. 21, and the above table show that the driving voltage of the light-emitting device 1 (80° C.) and the light-emitting device 2 (100° C.), which are light-emitting devices manufactured with the use of the processing steps by a photolithography method, is significantly increased more than that of the comparative light-emitting device 5. Meanwhile, the driving voltage of the light-emitting device 3 (110° C.) and the light-emitting device 4 (120° C.) is decreased more than that of the light-emitting device 1 (80° C.) and the light-emitting device 2 (100° C.). Accordingly, it can be said that the temperature of the heat treatment after the second electron-transport layer is exposed is preferably higher than or equal to 110° C. and lower than or equal to 120° C.

The greater increase in the driving voltage of the light-emitting device 1 (80° C.) and the light-emitting device 2 (100° C.) than in the comparative light-emitting device 5 resulted from the influence of water, oxygen, or the like by exposure of the organic compound layer including an alkali metal or a compound thereof to the air and heating in the processing steps by a photolithography method. By contrast, the increase in the driving voltage of the light-emitting device 3 (110° C.) and the light-emitting device 4 (120° C.) was able to be inhibited by the removal of water, oxygen, or the like in the organic compound layer including the alkali metal or the compound thereof by performing heat treatment at a temperature higher than or equal to 110° C.

These results show that even in the method for manufacturing the light-emitting device of one embodiment of the present invention in which the processing by a photolithography method is performed, by performing heat treatment at a temperature higher than or equal to 100° C., preferably higher than or equal to 100° C. and lower than or equal to 120° C., further preferably higher than or equal to 100° C. and lower than or equal to 110° C. or higher than or equal to 110° C. and lower than or equal to 120° C., after the second sacrificial layer and the first sacrificial layer are removed and the second electron-transport layer is exposed, light-emitting devices which exhibit high current efficiency and in which the driving voltage is inhibited can be manufactured.

### Example 2J

In this example, characteristics of a reference light-emitting device 6 and a comparative device 7 each of which is a single light-emitting device manufactured to describe the manufacturing method of the light-emitting device of one embodiment of the present invention will be described. Structural formulae of organic compounds used in this example are shown below.

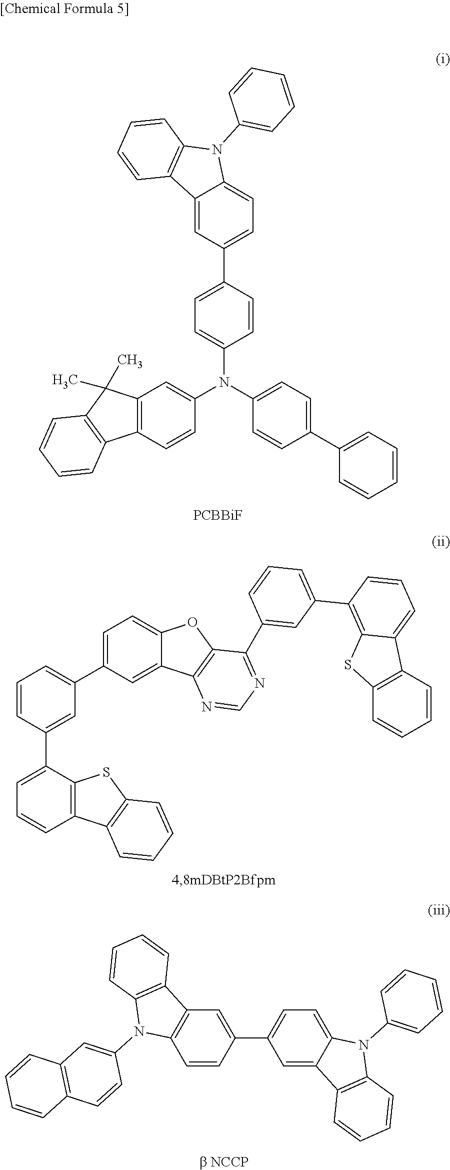

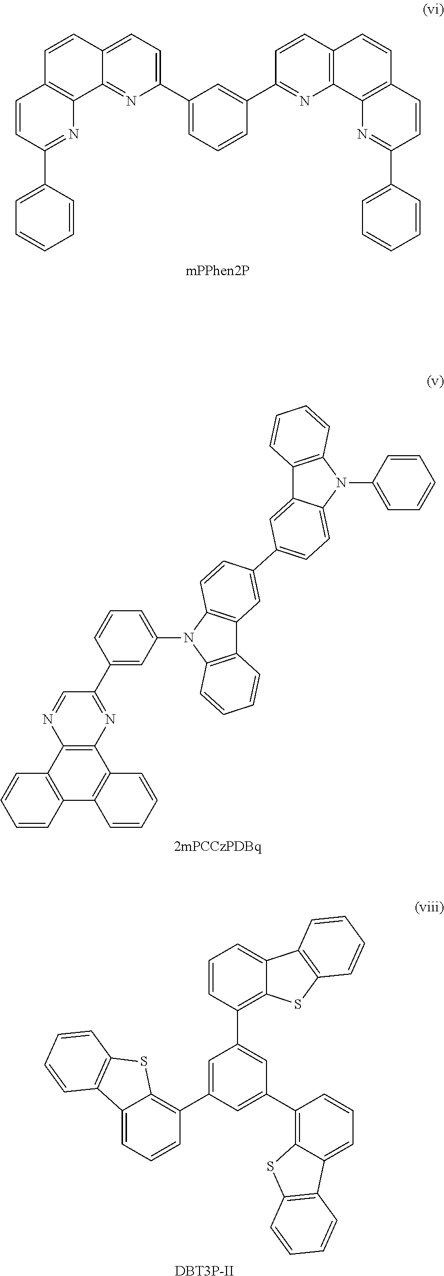 [SMILES: c1ccc(-c2ccc3ccc4ccc(-c5cccc(-c6ccc7ccc8ccc(-c9ccccc9)nc8c7n6)c5)nc4c3n2)cc1 ; c1ccc(-n2c3ccccc3c3cc(-c4ccc5c(c4)c4ccccc4n5-c4cccc(-c5cnc6c7ccccc7c7ccccc7c6n5)c4)ccc32)cc1 ; c1ccc2c(c1)sc1c(-c3cc(-c4cccc5c4sc4ccccc45)cc(-c4cccc5c4sc4ccccc45)c3)cccc12 ; "DBT3P-II"]

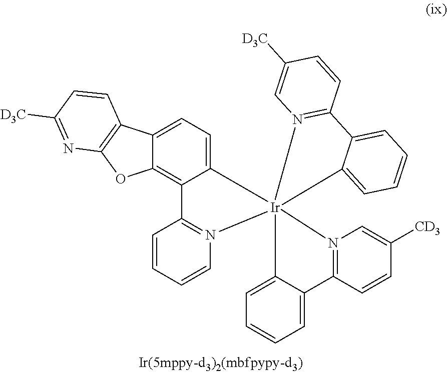

### (Method for Manufacturing Reference Light-Emitting Device 6)

The reference light-emitting device 6 includes a hole-transport layer (50 nm thick), a light-emitting layer, and an electron-transport layer (30 nm thick in total) instead of the first hole-transport layer (70 nm thick), the first light-emitting layer, and the second electron-transport layer (40 nm thick in total) in the light-emitting device 1, and is a single light-emitting device not including a first electron-transport layer, an intermediate layer, a second hole-transport layer, and a second light-emitting layer; furthermore, the reference light-emitting device 6 is a light-emitting device using [2-d₃-methyl-8-(2-pyridinyl-κN)benzofuro[2,3-b]pyridine-κC]bis[2-(5-d₃-methyl-2-pyridinyl-κ1N2)phenyl-κC]iridium(III) (abbreviation: Ir(5mppy-d₃)₂(mbfpypy-d₃)) represented by Structural Formula (ix) shown above for the light-emitting layer instead of Ir(ppy)₂(mbfpypy-d₃) used for the first light-emitting layer in the light-emitting device 1. The other layers were formed in a manner similar to that of the light-emitting device 1. Note that the temperature of the heat treatment after the second sacrificial layer and the first sacrificial layer were removed and the electron-transport layer was exposed was 80° C.

### (Method for Manufacturing Comparative Light-Emitting Device 7)

The comparative light-emitting device 7 is different from the reference light-emitting device 6 in that the processing steps by a photolithography method in the manufacturing process of the light-emitting device 6 were omitted and that the formation of the electron-injection layer to the formation of the cap layer were continuously performed after the formation of the electron-transport layer. In other words, the comparative light-emitting device 7 was manufactured in a continuous vacuum process. The other layers were formed in the similar manner to that of the reference light-emitting device 6.

The device structures of the reference light-emitting device 6 and the comparative light-emitting device 7 are listed in the following table.

TABLE 3

| | Reference | Comparative |
|---|---|---|
| | light-emitting | light-emitting |
| Thickness | device 6 (80° C.) | device 7 |

| | | | |
|---|---|---|---|
| Cap layer | 70 | nm | DBT3P-II |
| Second electrode | 15 | nm | Ag:Mg (1:0.1) |
| Electron-injection | 2 | nm | LiF:Yb (1:1) |
| layer | | | |

| | | |
|---|---|---|
| Heat treatment | 80° C. | — |
| Processing by | Processing by | — |
| photolithography method | photolithography | |
| | method was | |
| | performed | |

| Electron- | 2 | 20 | nm | mPPhen2P |
|---|---|---|---|---|
| transport layer | 1 | 10 | nm | 2mPCCzPDBq |
| Light-emitting layer | | 40 | nm | 4,8mDBtP2Bfpm:βNCCP:Ir(5mppy-d₃)₂(mbfpypy-d₃) |
| | | | | (0.5:0.5:0.1) |
| Hole-transport layer | | 50 | nm | PCBBiF |
| Hole-injection layer | | 10 | nm | PCBBiF:OCHD-003 (1:0.03) |
| First electrode | 2 | 100 | nm | ITSO |
| | 1 | 100 | nm | APC |

The reference light-emitting device 6 and the comparative light-emitting device 7 were sealed using a glass substrate in a glove box containing a nitrogen atmosphere so as not to be exposed to the air (a UV curable sealing material was applied to surround the devices, only the sealing material was irradiated with UV while the light-emitting devices were prevented from being irradiated with the UV, and heat treatment was performed at 80° C. under an atmospheric pressure for 1 hour). Then, the initial characteristics of each of the light-emitting devices were measured.

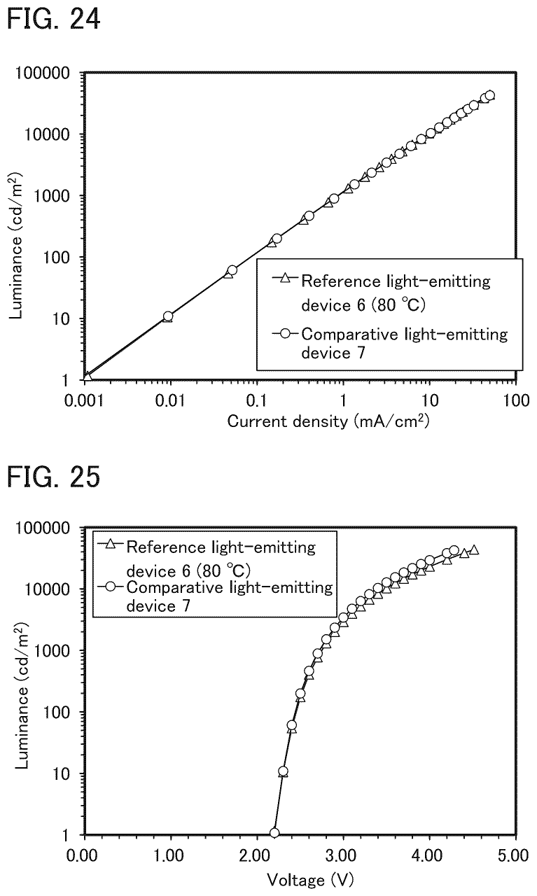

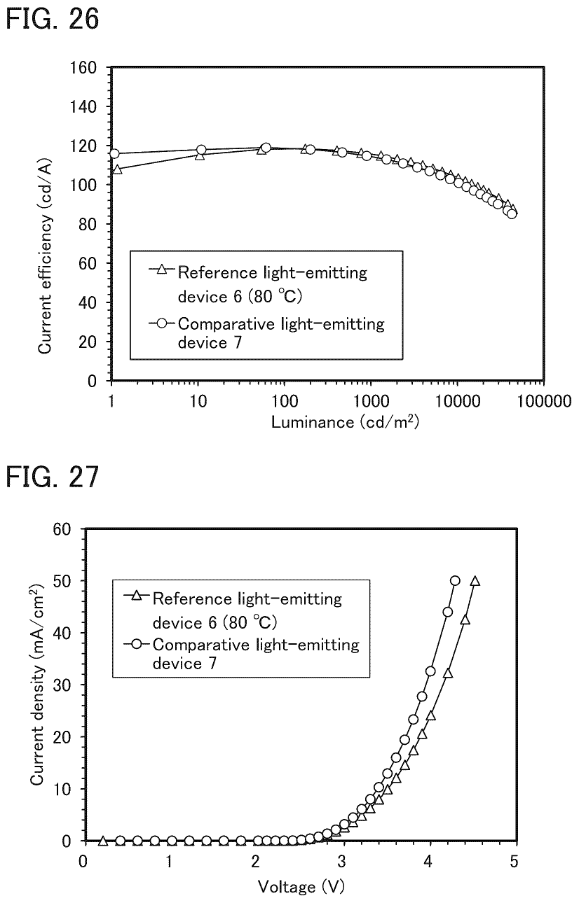

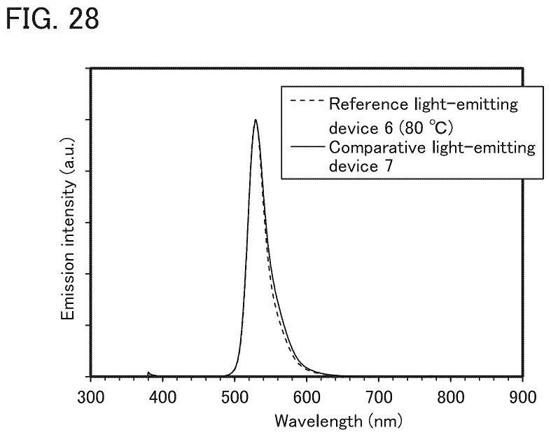

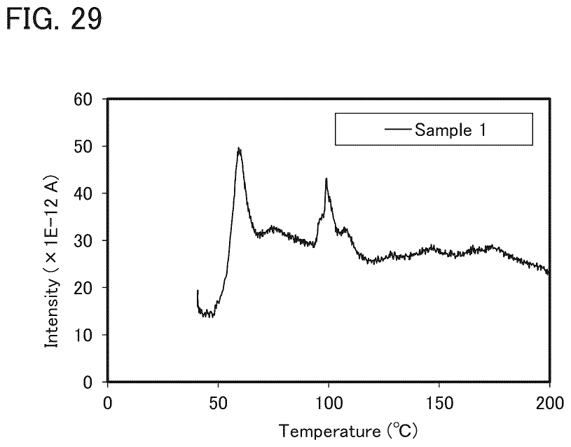

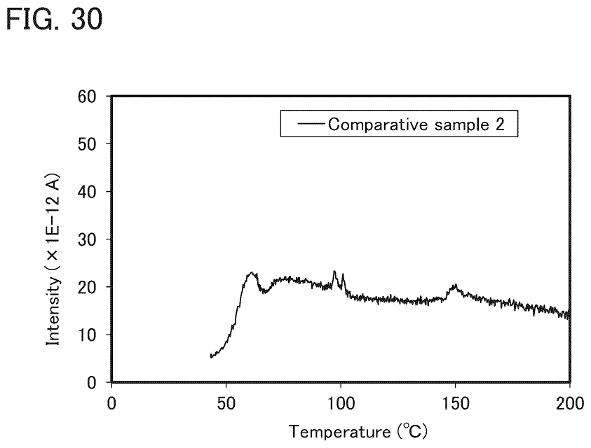

FIG. 24 shows the luminance-current density characteristics of the light-emitting device 6 and the comparative light-emitting device 7. FIG. 25 shows the luminance-voltage characteristics thereof. FIG. 26 shows the current efficiency-luminance characteristics thereof. FIG. 27 shows the current density-voltage characteristics thereof. FIG. 28 shows the emission spectra thereof. The table below shows the main characteristics at a current density of 50 mA/cm². Note that the luminance, CIE chromaticity, and emission spectra were measured at normal temperature with a spectroradiometer (SR-UL1R manufactured by TOPCON CORPORATION).

TABLE 4

| | | Current | | | | Current |
|---|---|---|---|---|---|---|
| | Voltage | density | Luminance | | | efficiency |
| | (V) | (mA/cm²) | (cd/m²) | Chromaticity x | Chromaticity y | (cd/A) |
| Reference light-emitting device 6 (80° C.) | 4.5 | 50 | 43870 | 0.243 | 0.718 | 87.7 |
| Comparative light-emitting device 7 | 4.3 | 50 | 42550 | 0.255 | 0.709 | 85.1 |

FIG. 24 to FIG. 28 and the table below show that both the reference light-emitting device 6 and the comparative light-emitting device 7 have favorable characteristics.

The light-emitting device 1 (80° C.), which is a tandem light-emitting device that went through the processing steps by a photolithography method described in Example 1, has poorer characteristics than the comparative light-emitting device 5, whereas the reference light-emitting device 6 (80° C.), which is a single light-emitting device that was manufactured in this example and went through the processing steps by a photolithography method, had no change in characteristics compared with the comparative light-emitting device 7. Thus, the influence of water, oxygen, or the like is small in a single light-emitting device not including a layer including an alkali metal or a compound as the intermediate layer; thus, characteristics of the device are less likely to be degraded even when heat treatment at a temperature higher than or equal to 100° C. is not performed after the electron-transport layer is exposed.

These results show that the step of performing heat treatment at a temperature higher than or equal to 100° C. after the processing by a photolithography method is performed and then exposing the electron-transport layer in the manufacturing method of the light-emitting device of one embodiment of the present invention is particularly effective for a tandem device.

### Example 3

This example describes the results of TDS (Thermal Desorption Spectroscopy) analysis tests performed on Sample 1, Comparative Sample 2, and Comparative Sample 3 in each of which an organic compound layer was formed over a glass substrate in order to describe a method for manufacturing a light-emitting device of one embodiment of the present invention.

Note that the organic compounds used for Sample 1, Comparative Sample 2, and Comparative Sample 3 in this example are the same as the organic compounds used for the light-emitting devices in Example 1; thus, structural formulae are omitted in this example.

### (Method for Manufacturing Sample 1)

Sample 1 is a sample in which an organic compound layer similar to that of the light-emitting device 1 is formed over a glass substrate, i.e., a sample resembling an organic compound layer of a tandem light-emitting device including an alkali metal or an alkali metal compound as an intermediate layer. Note that the thickness of some layers is different from that in the light-emitting device 1. The processing steps by a photolithography method were not performed for Sample 1.

### (Comparative Sample 2)

Comparative Sample 2 is a sample that does not include Li₂O, which is part of the N-type layer, and the ER layer, in Sample 1. The other layers were formed in the similar manner to that of Sample 1. That is, Comparative Sample 2 is a sample resembling the structure in which the layer including an alkali metal or an alkali metal compound is omitted from the organic compound layer of the tandem light-emitting device.

### (Method for Manufacturing Comparative Sample 3)

Comparative Sample 3 is a sample that does not include a first electron-transport layer, an intermediate layer, a second hole-transport layer, and a second light-emitting layer, in Sample 1, i.e., a sample resembling the organic compound layer of the single-type light-emitting device.

The structures of the organic compound layers of Sample 1, Comparative Sample 2, Sample 3, and Sample 4 are listed in the following table.

TABLE 5

| | | | | | Comparative | Comparative |
|---|---|---|---|---|---|---|
| | | Thickness | | Sample 1 | sample 2 | sample 3 |
| Second electron- | 2 | 20 | nm | mPPhen2P | | |
| transport layer | 1 | 20 | nm | 2mPCCzPDBq | | |
| Second light-emitting layer | | 40 | nm | 4,8mDBtP2Bfpm:βNCCP:Ir(ppy)₂(mbfpypy-d₃) | | — |
| | | | | (0.5:0.5:0.1) | | |
| Second hole-transport layer | | 40 | nm | PCBBiF | | — |
| Intermediate | P-type layer | 10 | nm | PCBBiF:OCHD-003 (1:0.15) | | — |
| layer | ER layer | 2 | nm | CuPc | — | — |
| | N-type layer | 0.3 | nm | Li₂O | — | — |

| | 20 | nm | mPPhen2P | — |
|---|---|---|---|---|
| First electron-transport layer | 10 | nm | 2mPCCzPDBq | — |

| | | | |
|---|---|---|---|
| First light-emitting layer | 40 | nm | 4,8mDBtP2Bfpm:βNCCP:Ir(ppy)₂(mbfpypy-d₃) |
| | | | (0.5: 0.5: 0.1) |
| First hole-transport layer | 30 | nm | PCBBiF |
| Hole-injection layer | 10 | nm | PCBBiF:OCHD-003 (1:0.03) |

The TDS analysis was performed on Sample 1, Comparative Sample 2, Sample 3, and Sample 4. The TDS is an analysis apparatus for detecting and identifying, using a quadrupole mass analyzer, a gas component discharged or generated when the sample is heated and the temperature thereof is increased in high vacuum; thus, a gas and a molecule discharged from surfaces and the inside of the sample can be observed. TDS (product name: EMD-WA1000S) manufactured by ESCO, Ltd. was used, and the measurement condition was approximately 5° C./minutes.

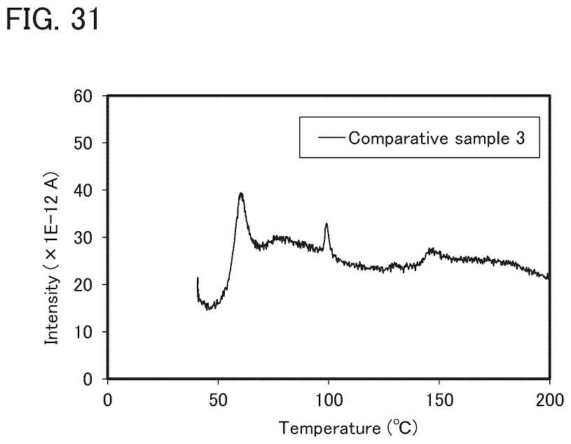

FIG. 29 to FIG. 31 show TDS analysis results of Sample 1, Comparative Sample 2, and Comparative Sample 3. FIG. 29 to FIG. 31 show results at a mass-to-charge ratio (M/z) of 18 which corresponds to hydrogen molecules. The horizontal axis represents substrate temperature and the vertical axis represents detection intensity.

FIG. 29 and FIG. 30 show that peaks of Sample 1 appear around 60° C. and 100° C., whereas the peaks of Comparative Sample 2 are low in the entire temperature range. These results show that the organic compound layer of Sample 1 including the layer including an alkali metal or an alkali metal compound adsorbs more water than the organic compound layer of Comparative Sample 2 not including the layer including an alkali metal or an alkali metal compound.

FIG. 29 and FIG. 31 show that while peaks of Comparative Sample 3 appear around 60° C. and 100° C., the detection intensity at these temperatures is higher in Sample 1. These results show that the organic compound layer of Sample 1 resembling the tandem light-emitting device including an alkali metal or an alkali metal compound as the intermediate layer adsorbs more water than the organic compound layer of Comparative Sample 3 resembling the single light-emitting device not including the intermediate layer.

These results show that the tandem organic compound layer including, as the intermediate layer, a layer including an alkali metal or a compound thereof is likely to adsorb water. Thus, it is revealed that the step of removing water from the organic compound layer according to the method for manufacturing a light-emitting device of one embodiment of the present invention is particularly effective for the tandem light-emitting device including a layer including an alkali metal or a compound thereof as the intermediate layer.

These results show that in the tandem light-emitting device, water can be removed by performing heat treatment at a temperature higher than or equal to 100° C. and lower than or equal to 120° C. after the second electron-transport layer is exposed. These results show that the temperature of the heat treatment after the second electron-transport layer is exposed is preferably higher than or equal to 100° C. and lower than or equal to 120° C.

### REFERENCE NUMERALS

100A: display device, 100: display device, 101: first electrode, 102: second electrode, 103: organic compound layer, 103f: organic compound film, 103B: organic compound layer, 103Bf: organic compound film, 103G: organic compound layer, 103Gf: organic compound film, 103R: organic compound layer, 103Rf: organic compound film, 104: common layer, 105: substrate, 110B: subpixel, 110G: subpixel, 110R: subpixel, 110: subpixel, 111: hole-injection layer, 112_1: first hole-transport layer, 112_2: second hole-transport layer, 113_1: first light-emitting layer, 113_2: second light-emitting layer, 113: light-emitting layer, 114_1: first electron-transport layer, 114_2: second electron-transport layer, 115: electron-injection layer, 116_1: first intermediate layer, 116_2: second intermediate layer, 116: intermediate layer, 117: P-type layer, 118: electron-relay layer, 119: N-type layer, 120: substrate, 122: resin layer, 125f: inorganic insulating film, 125: inorganic insulating layer, 127a: insulating layer, 127f: insulating film, 127: insulating layer, 130B: light-emitting device, 130G: light-emitting device, 130R: light-emitting device, 130: light-emitting device, 131: protective layer, 132B: coloring layer, 132G: coloring layer, 132R: coloring layer, 140: connection portion, 141: region, 151a: conductive layer, 151B: conductive layer, 151b: conductive layer, 151C: conductive layer, 151c: conductive layer, 151f: conductive film, 151G: conductive layer, 151R: conductive layer, 151: conductive layer, 152a: conductive layer, 152B: conductive layer, 152b: conductive layer, 152C: conductive layer, 152c: conductive layer, 152f: conductive film, 152G: conductive layer, 152R: conductive layer, 152: conductive layer, 155: common electrode, 156B: insulating layer, 156C: insulating layer, 156f: insulating film, 156G: insulating layer, 156R: insulating layer, 156: insulating layer, 158: sacrificial layer, 158f: sacrificial film, 158B: sacrificial layer, 158Bf: sacrificial film, 158G: sacrificial layer, 158Gf: sacrificial film, 158R: sacrificial layer, 158Rf: sacrificial film, 159: mask layer, 159f: mask film, 159B: mask layer, 159Bf: mask film, 159G: mask layer, 159Gf: mask film, 159R: mask layer, 159Rf: mask film, 171: insulating layer, 172: conductive layer, 173: insulating layer, 174: insulating layer, 175: insulating layer, 176: plug, 177: pixel portion, 178: pixel, 179: conductive layer, 190: resist mask, 190B: resist mask, 190G: resist mask, 190R: resist mask, 191: resist mask, 240: capacitor, 241: conductive layer, 243: insulating layer, 245: conductive layer, 254: insulating layer, 255: insulating layer, 256: plug, 261: insulating layer, 271: plug, 280: display module, 281: display portion, 282: circuit portion, 283a: pixel circuit, 283: pixel circuit portion, 284a: pixel, 284: pixel portion, 285: terminal portion, 286: wiring portion, 290: FPC, 291: substrate, 292: substrate, 301: substrate, 310: transistor, 311: conductive layer, 312: low-resistance region, 313: insulating layer, 314: insulating layer, 315: element isolation layer, 501: first light-emitting unit, 501f: organic compound film, 502b: organic compound layer, 502: second light-emitting unit, 502f: organic compound film, 503: third light-emitting unit, 700A: electronic device, 700B: electronic device, 721: housing, 723: wearing portion, 727: earphone portion, 750: earphone, 751: display panel, 753: optical member, 756: display region, 757: frame, 758: nose pad, 800A: electronic device, 800B: electronic device, 820: display portion, 821: housing, 822: communication portion, 823: wearing portion, 824: control portion, 825: image capturing portion, 827: earphone portion, 832: lens, 6500: electronic device, 6501: housing, 6502: display portion, 6503: power button, 6504: button, 6505: speaker, 6506: microphone, 6507: camera, 6508: light source, 6510: protection member, 6511: display panel, 6512: optical member, 6513: touch sensor panel, 6515: FPC, 6516: IC, 6517: printed circuit board, 6518: battery, 7000: display portion, 7100: television device, 7151: remote control, 7171: housing, 7173: stand, 7200: notebook personal computer, 7211: housing, 7212: keyboard, 7213: pointing device, 7214: external connection port, 7300: digital signage, 7301: housing, 7303: speaker, 7311: information terminal, 7400: digital signage, 7401: pillar, 7411: information terminal

1. A method for manufacturing a light-emitting device, comprising the steps of:
forming a first electrode;
forming an organic compound layer over the first electrode, the organic compound layer comprising an intermediate layer between a first light-emitting layer and a second light-emitting layer;
processing the organic compound layer by a lithography method;
performing heat treatment on the organic compound layer; and
forming a second electrode to cover the first electrode and the organic compound layer,
wherein the intermediate layer comprises one of an alkali metal and an alkali metal compound.

2. A method for manufacturing a light-emitting device, comprising the steps of:
forming a first electrode;
forming an organic compound layer over the first electrode, the organic compound layer comprising an intermediate layer between a first light-emitting layer and a second light-emitting layer;
forming a sacrificial layer over the organic compound layer;
forming a mask over the sacrificial layer using a resist;
processing the organic compound layer by a lithography method using the mask;
removing at least part of the sacrificial layer;
performing heat treatment; and
forming a second electrode to cover the first electrode and the organic compound layer,
wherein the intermediate layer comprises one of an alkali metal and an alkali metal compound.

3. A method for manufacturing a light-emitting device, comprising the steps of:
forming a first electrode;
forming an organic compound layer over the first electrode, the organic compound layer comprising:
a first light-emitting layer;
an intermediate layer over the first light-emitting layer; and
a second light-emitting layer over the intermediate layer;
forming a sacrificial layer over the organic compound layer;
forming a mask over the sacrificial layer using a resist;
processing the organic compound layer by a lithography method using the mask;
forming an insulating layer over the organic compound layer;
removing at least part of the sacrificial layer;
performing heat treatment; and
forming a second electrode over the insulating layer,
wherein the intermediate layer comprises at least one of an alkali metal and an alkali metal compound, and
wherein, in a cross-sectional view, the insulating layer covers at least a side surface of the organic compound layer.

4. The method for manufacturing a light-emitting device according to claim 1,
wherein the heat treatment is performed at a temperature higher than or equal to 100° C.

5. The method for manufacturing a light-emitting device according to claim 1,
wherein the heat treatment is performed at a temperature higher than or equal to 100° C. and lower than or equal to 120° C.

6. The method for manufacturing a light-emitting device according to claim 1,
wherein the heat treatment is performed at a temperature higher than or equal to 100° C. and lower than a glass transition temperature of an organic compound included in a top surface of the organic compound layer.

7. The method for manufacturing a light-emitting device according to claim 2,
wherein the heat treatment is performed at a temperature higher than or equal to 100° C.

8. The method for manufacturing a light-emitting device according to claim 2,
wherein the heat treatment is performed at a temperature higher than or equal to 100° C. and lower than or equal to 120° C.

9. The method for manufacturing a light-emitting device according to claim 2,
wherein the heat treatment is performed at a temperature higher than or equal to 100° C. and lower than a glass transition temperature of an organic compound included in a top surface of the organic compound layer.

10. The method for manufacturing a light-emitting device according to claim 3,
wherein the heat treatment is performed at a temperature higher than or equal to 100° C.

11. The method for manufacturing a light-emitting device according to claim 3,
wherein the heat treatment is performed at a temperature higher than or equal to 100° C. and lower than or equal to 120° C.

12. The method for manufacturing a light-emitting device according to claim 3,
wherein the heat treatment is performed at a temperature higher than or equal to 100° C. and lower than a glass transition temperature of an organic compound included in a top surface of the organic compound layer.
